(19) United States
(12) Patent Application Publication
(10) Pub. No.: US 2026/0023326 A1
(43) Pub. Date: Jan. 22, 2026

(54) IMAGING EUV OPTICAL UNIT FOR IMAGING AN OBJECT FIELD INTO AN IMAGE FIELD

(71) Applicant: Carl Zeiss SMT GmbH, Oberkochen (DE)

(72) Inventors: Michael BREHM, Sulzbach-Laufen (DE); Susanne BEDER, Aalen (DE); Christoph MENKE, Oberkochen (DE); Marco PRETORIUS, Oberkochen (DE); Martin PESCHKA, Aalen (DE)

(21) Appl. No.: 19/341,036

(22) Filed: Sep. 26, 2025

Related U.S. Application Data
(63) Continuation of application No. PCT/EP2024/058977, filed on Apr. 3, 2024.

(30) Foreign Application Priority Data
Apr. 6, 2023 (DE) 10 2023 203 223.6

(51) Int. Cl. G03F 7/00; G02B 17/06

(52) U.S. Cl. CPC G03F 7/70233; G02B 17/0663; G03F 7/70308; G03F 7/70358

(57) ABSTRACT

An imaging EUV optical unit serves for imaging an object field into an image field. The imaging optical unit has a plurality of mirrors for guiding EUV imaging light at a wavelength of shorter than 30 nm along an imaging beam path. The imaging EUV optical unit has an image-side numerical aperture of at least 0.3. An overall transmission of the plurality of mirrors is greater than 10%. An overall mirror surface, which represents the sum of all used mirror surfaces of the plurality of mirrors, is less than 1.5 m². This design can yield an imaging EUV optical unit with improved usability for an EUV projection exposure apparatus.

### CROSS-REFERENCE TO RELATED APPLICATIONS

The present application is a continuation of, and claims benefit under 35 USC 120 to, international application No. PCT/EP2024/058977, filed Apr. 3, 2024, which claims benefit under 35 USC 119 of German Application No. 10 2023 203 223.6, filed Apr. 4, 2023. The entire disclosure of each of these applications is incorporated by reference herein.

### FIELD

The disclosure relates to an imaging EUV optical unit for imaging an object field into an image field. Further, the disclosure relates to an optical system having such an imaging optical unit, a projection exposure apparatus having such an optical system, a method for producing a micro- or nanostructured component using such a projection exposure apparatus, and a micro- or nanostructured component produced by the method.

### BACKGROUND

Projection optical units are known from, for example, WO 2018/010 960 A1, DE 10 2015 221 984 A1, DE 10 2015 209 827 A1, DE 10 2012 212 753 A1, US 2010/0149509 A1 and U.S. Pat. No. 4,964,706.

### SUMMARY

The present disclosure seeks to develop an imaging EUV optical unit with improved usability for an EUV projection exposure apparatus.

In an aspect, the disclosure provides an Imaging EUV optical unit for imaging an object field into an image field. The imaging EUV optical unit has a plurality of mirrors for guiding EUV imaging light at a wavelength of shorter than 30 nm along an imaging beam path from the object field towards the image field. The imaging EUV optical unit has an image-side numerical aperture of at least 0.3. The imaging EUV optical unit has an overall transmission of the plurality of mirrors of greater than 10%. The imaging EUV optical unit has an overall mirror surface, which represents the sum of all used mirror surfaces of the plurality of mirrors, of less than 1.5 m².

According to the disclosure, it was recognised that it is possible to keep an overall mirror surface of the imaging EUV optical unit relatively small, specifically smaller than 1.5 m², while maintaining other desired boundary conditions placed on an imaging EUV optical unit, especially for use in a projection exposure apparatus for lithography. This can reduce the outlay involved in producing the mirror. Moreover, the installation space can be reduced. An image-side numerical aperture can be greater than 0.3 and can be 0.33, for example. The image-side numerical aperture is regularly no greater than 0.6. The overall transmission of the imaging EUV optical unit can be greater than 10.5%, can be greater than 11%, can be greater than 11.5%, can be greater than 12%, can be greater than 12.5%, can be greater than 13%, and can also be greater than 13.3%. On account of the number of mirrors and an individual EUV transmission of a mirror that guides the imaging light, which is regularly no more than 80%, the overall transmission is regularly less than 15%.

The overall mirror surface of all mirrors in the imaging EUV optical unit, which is less than 1.5 m², can be no more than 1.25 m², no more than 1.0 m², no more than 0.9 m², and no more than 0.8 m². The overall mirror surface can be smaller than 0.8 m², can be smaller than 0.75 m², can be smaller than 0.7 m², can be smaller than 0.65 m², can be smaller than 0.6 m², can be smaller than 0.55 m², can be smaller than 0.5 m² and can also be smaller than 0.48 m². This overall mirror surface is regularly larger than 0.4 m². The image field can be a ring field. The imaging EUV optical unit may comprise an entrance pupil accessible overall for the purpose of specifying an illumination angle distribution for the object field. An entrance pupil of the imaging EUV optical unit can be located upstream of the object field in the imaging beam path.

In some embodiments, a polishing overrun edge, which encloses a reflection mirror surface used in fact for reflection, is incorporated in the used mirror surfaces of the mirrors and, on the edge, projects beyond this reflection mirror surface by at least 10 mm along the entire circumference of the reflection surface. Taking account of such a polishing overrun edge in the area for the overall mirror surface can yield an EUV optical unit with desirable properties with regards to production and use. The used mirror surface might project beyond the reflection mirror surface by more than 10 mm and can be at least 15 mm or else at least 20 mm.

In some embodiments, a maximum extent of the image field is at least 26 mm along a maximum field extension direction, and/or a scanning extent of the image field is at least 2 mm along a scanning field extension direction. Such image field extents were found to be particularly suitable. The scanning extent of the image field along a scanning field extension direction, i.e. along a scanning direction of a projection exposure apparatus designed as a scanner in that case, within which the imaging EUV optical unit is usable, might also be 2.5 mm. In the image plane, the image field can have a maximum extent which is more than 30 mm, more than 35 mm, more than 40 mm, more than 45 mm and might be more than 50 mm. The maximum extent can also be of the order of 52 mm.

In some embodiments, a wavefront aberration RMS is less than 50 m² over the entire image field. Such wavefront aberration was found to be particularly suitable for using the imaging EUV optical unit in a projection exposure apparatus for lithography. The RMS wavefront aberration can be less than 25 mλ, can be less than 20 mλ, can be less than 15 mλ, can be less than 10 mλ and can also be less than 8 mλ. The RMS wavefront aberration is regularly greater than 3 mλ.

In some embodiments, an overall number of the mirrors leads to a maximum overall polarisation rotation of no more than 10° along the imaging beam path when linearly polarised EUV imaging light is used. Such a maximum overall polarisation rotation can help enable imaging of linearly polarised imaging light by the imaging EUV optical unit without the interference, used for imaging purposes, between different orders of the diffraction guided in the imaging beam path leading to unwanted losses of contrast. The overall polarisation rotation of the imaging EUV optical unit regularly varies from field point to field point and regularly also varies within a pupil of the imaging EUV optical unit. To determine the maximum overall polarisation rotation, the respective polarisation rotation is determined over all field points and over all pupil positions. The maximum overall polarisation rotation can be less than 10°, can be less than 8°, can be less than 7°, can be less than 6°, can be less than 5° and can also be less than 4.5°. An even smaller maximum overall polarisation rotation is also possible. The maximum overall polarisation rotation is regularly greater than 0.1°. The overall polarisation rotation describes the cumulative polarisation-rotating effect of all mirrors in the imaging EUV optical unit.

In some embodiments, the image field represents a first field region in the imaging beam path downstream of the object field, for at least one sectional plane. In such embodiments, the imaging EUV optical unit has no intermediate image in at least one sectional plane, i.e. for example in the sagittal plane. Thus, there is choristikonal-type imaging within the meaning of U.S. Pat. No. 10,656,400 B2. For example, there is an image flip in the sagittal plane perpendicular to the meridional plane in that case. This sectional plane without an intermediate image can be the meridional plane and/or the sagittal plane. An intermediate image, especially in the form of an intermediate field region, for example in the form of a caustic, can be present in the other sectional plane.

In some embodiments, the imaging EUV optical unit has at least five mirrors. In some embodiments, the imaging EUV optical unit has at least one grazing incidence (GI) mirror. In some embodiments, the imaging EUV optical unit has exactly four normal incidence (NI) mirrors. Such numbers of mirrors were found to be particularly suitable for the optical design.

The imaging EUV optical unit can comprise an accessible entrance pupil in a beam path of imaging light upstream of the object field at a distance ranging between 1 m and 4 m in front of the object field. In any case, the pose of such an entrance pupil can be virtually the same in a meridional plane and in a sagittal plane perpendicular thereto.

The imaging EUV optical unit may have a pupil plane in the beam path between the object field and the image field. The pupil plane or stop plane can be located on one of the mirrors in the imaging EUV optical unit, for example on an NI mirror.

In some embodiments, an optical system has an illumination optical unit for illuminating the object field with the imaging light, and an imaging optical unit according to the disclosure. In some embodiments, a projection exposure apparatus has such an optical system and an EUV light source. In some embodiments, a method for producing a structured component includes the following method steps: providing a reticle and a wafer; projecting a structure on the reticle onto a light-sensitive layer of the wafer using a projection exposure apparatus according to the disclosure; and generating a microstructure and/or nanostructure on the wafer. In some embodiments, the disclosure provides a structured component made by such a method. Features of such embodiments correspond to those which have already been explained above with reference to the imaging optical unit according to the disclosure.

The EUV light source of the projection exposure apparatus may be designed so as to result in a used wavelength of no more than 13.5 nm, of less than 13.5 nm, of less than 10 nm, of less than 8 nm, of less than 7 nm, and of 6.7 nm or 6.9 nm, for example. A used wavelength of less than 6.7 nm and, for example, of the order of 6 nm is also possible.

For example, a semiconductor component, for example a memory chip, can be produced using the projection exposure apparatus.

### BRIEF DESCRIPTION OF THE DRAWINGS

Below, at least one exemplary embodiment of the disclosure is described on the basis of the drawing, in which:

FIG. 1 schematically shows a meridional section of a projection exposure apparatus for EUV projection lithography;

FIGS. 2 to 10 show, in each case in a meridional section, embodiments of an imaging optical unit which is used as a projection lens in the projection exposure apparatus according to FIG. 1, wherein an imaging beam path for chief rays and for an upper coma ray and a lower coma ray of three selected field points is depicted.

### DETAILED DESCRIPTION

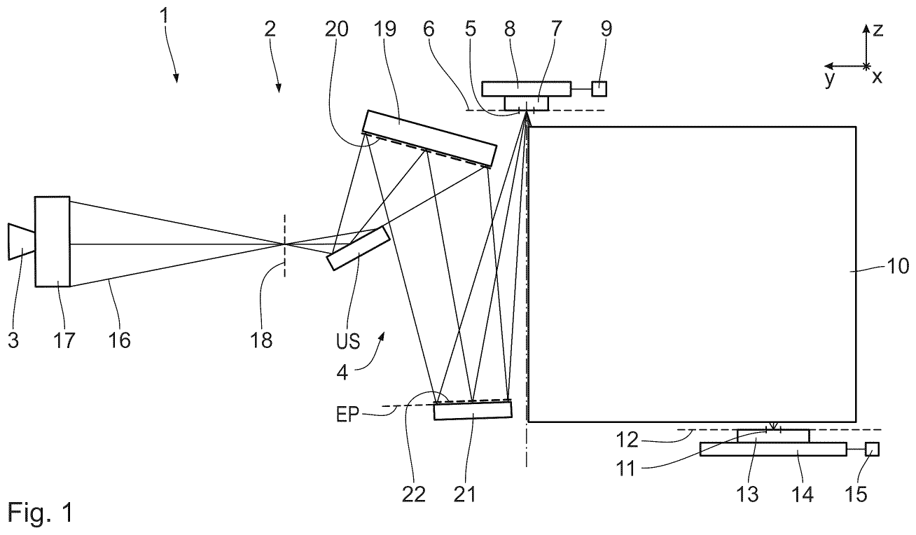

In the following text, certain components of a microlithographic projection exposure apparatus 1 are described first by way of example with reference to FIG. 1. The description of the basic structure of the projection exposure apparatus 1 and its components should not be construed as limiting here.

One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 can also be provided as a module separate from the rest of the illumination system. In this case, the illumination system does not comprise the light source 3.

A reticle 7 arranged in the object field 5 is exposed. The reticle 7 is held by a reticle holder 8. The reticle holder 8 is displaceable by way of a reticle displacement drive 9, for example in a scanning direction.

A Cartesian xyz-coordinate system is shown in FIG. 1 for explanation purposes. The x-direction runs perpendicular to the plane of the drawing into the latter. The y-direction runs horizontally and the z-direction runs vertically. The scanning direction runs in the y-direction in FIG. 1. The z-direction runs perpendicularly to the object plane 6.

The projection exposure apparatus 1 comprises a projection optical unit or imaging optical unit 10. The projection optical unit 10 serves for imaging the object field 5 into an image field 11 in an image plane 12. The image plane 12 extends parallel to the object plane 6. Alternatively, an angle that differs from 0° between the object plane 6 and the image plane 12 is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, for example in the y-direction. This y-displacement direction is also referred to as scanning direction when the projection exposure apparatus 1 is embodied as a scanner. The displacement, firstly, of the reticle 7 by way of the reticle displacement drive 9 and, secondly, of the wafer 13 by way of the wafer displacement drive 15 can be implemented so as to be synchronised with one another.

The radiation source 3 is an EUV radiation source. The radiation source 3 emits, for example, EUV radiation 16, which is also referred to below as used radiation, illumination radiation, imaging radiation, illumination light or imaging light. For example, the used radiation has a wavelength in the range of between 5 nm and 30 nm. The radiation source 3 can be a plasma source, for example an LPP (laser produced plasma) source or a GDPP (gas discharge produced plasma) source. It can also be a synchrotron-based radiation source. The radiation source 3 can be a free electron laser (FEL).

The illumination radiation 16 emerging from the radiation source 3 is focused by a collector 17. The collector 17 can be a collector with one or more ellipsoidal and/or hyperboloidal reflection surfaces. The illumination radiation 16 can be incident on the at least one reflection surface of the collector 17 with grazing incidence (GI), i.e. at angles of incidence of greater than 45°, or with normal incidence (NI), i.e. at angles of incidence of less than 45°. The collector 17 can be structured and/or coated on the one hand for optimising its reflectivity for the used radiation and on the other hand for suppressing stray light.

The illumination radiation 16 propagates through an intermediate focus in an intermediate focal plane 18 downstream of the collector 17. The intermediate focal plane 18 can represent a separation between a radiation source module, comprising the radiation source 3 and the collector 17, and the illumination optical unit 4.

The illumination optical unit 4 comprises a first facet mirror 19. If the first facet mirror 19 is arranged in a plane of the illumination optical unit 4 which is optically conjugate to the object plane 6, then this facet mirror is also referred to as a field facet mirror. The first facet mirror 19 comprises a multiplicity of individual first facets 20, which are also referred to below as field facets. Only a few of these facets are illustrated in FIG. 1 in exemplary fashion.

The first facets 20 may be embodied as macroscopic facets, for example as rectangular facets or as facets with an arcuate edge contour or an edge contour of part of a circle. The first facets 20 can be embodied as plane facets or alternatively as facets with convex or concave curvature.

As known for example from DE 10 2008 009 600 A1, the first facets 20 themselves can also be composed in each case of a multiplicity of individual mirrors, for example a multiplicity of micromirrors. The first facet mirror 19 may for example be formed as a microelectromechanical system (MEMS system). For details, reference is made to DE 10 2008 009 600 A1.

A deflection mirror US, which may be embodied as a plane mirror but which may alternatively also have a beam shaping effect, is located in the beam path of the illumination optical unit 4, between the intermediate focus in the intermediate focal plane 18 and the first facet mirror 19.

In the beam path of the illumination optical unit 4, a second facet mirror 21 is arranged downstream of the first facet mirror 19. If the second facet mirror 21 is arranged in a pupil plane of the illumination optical unit 4, it is also referred to as a pupil facet mirror.

The second facet mirror 21 can also be arranged at a distance from a pupil plane of the illumination optical unit 4. In this case, the combination of the first facet mirror 19 and the second facet mirror 21 is also referred to as a specular reflector. Specular reflectors are known from US 2006/0132747 A1, EP 1 614 008 B1, and U.S. Pat. No. 6,573,978.

The second facet mirror 21 comprises a plurality of second facets 22. In the case of a pupil facet mirror, the second facets 22 are also referred to as pupil facets.

The second facets 22 may likewise be macroscopic facets, which may for example have a round, rectangular or else hexagonal boundary, or may alternatively be facets composed of micromirrors. In this regard, reference is likewise made to DE 10 2008 009 600 A1. The second facets 22 may have plane reflection surfaces or alternatively reflection surfaces with convex or concave curvature.

The illumination optical unit 4 consequently forms a doubly faceted system. This fundamental principle is also referred to as a fly's eye condenser (fly's eye integrator).

It may be advantageous to arrange the second facet mirror 21 not exactly in a plane that is optically conjugate to a pupil plane of the projection optical unit 10. For example, the pupil facet mirror 22 can be arranged so as to be tilted relative to a pupil plane of the projection optical unit 10, as is described, for example, in DE 10 2017 220 586 A1.

The individual first facets 20 are imaged into the object field 5 with the aid of the second facet mirror 21 and optionally with the aid of an imaging optical assembly in the form of a transfer optical unit, which is not depicted in FIG. 1.

The transfer optical unit may have exactly one mirror, or alternatively have two or more mirrors, which are arranged one behind the other in the beam path of the illumination optical unit 4. The transfer optical unit may for example comprise one or two normal-incidence mirrors (NI mirrors) and/or one or two grazing-incidence mirrors (GI mirrors). The illumination optical unit 4 has exactly three mirrors in the embodiment shown in FIG. 1, that is to say downstream of the collector 17, specifically the deflection mirror US, the first facet mirror 19, and the second facet mirror 21.

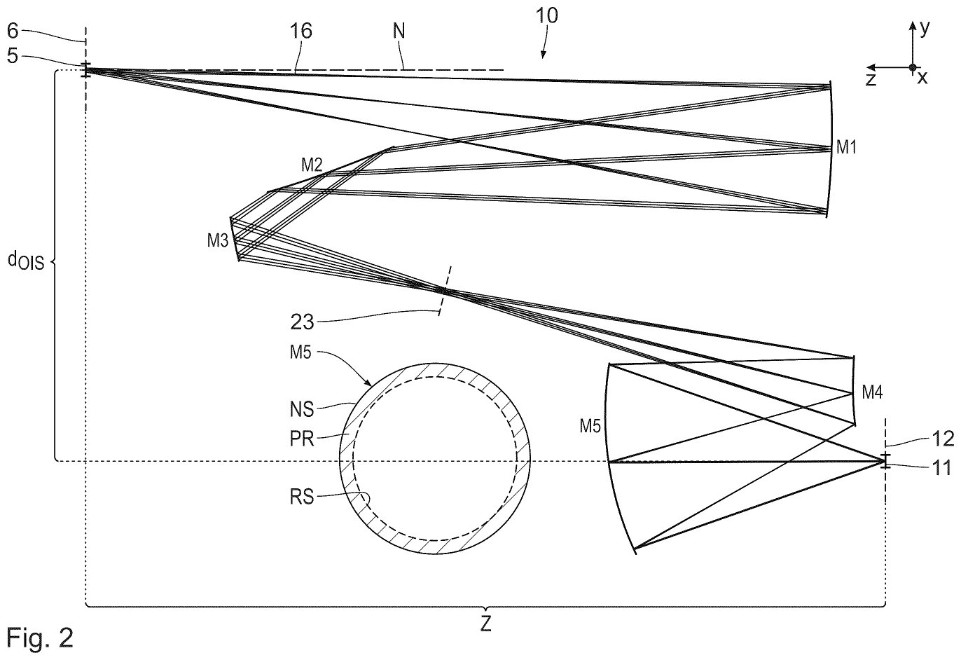

To the extent that the transfer optical unit downstream of the second facet mirror 21 is dispensed with, the second facet mirror 21 is the last beam shaping mirror or else indeed the last mirror for the illumination radiation 16 in the beam path upstream of the object field 5. An example of an illumination optical unit 4 without a transfer optical unit is disclosed in FIG. 2 of WO 2019/096654 A1.

The imaging of the first facets 20 into the object plane 6 via the second facets 22 or using the second facets 22 and a transfer optical unit is often only approximate imaging.

The projection optical unit 10 comprises a plurality of mirrors, namely five mirrors M1 to M5 (cf. FIG. 2), which are consecutively numbered in accordance with their order in the beam path of the projection exposure apparatus 1.

In the example illustrated in FIG. 2, the projection optical unit 10 comprises five mirrors M1 to M5. Alternatives with four, six or any other number of mirrors Mi are likewise possible, as will still become apparent, for example, from the following description of further exemplary embodiments.

The projection optical unit 10 is a non-obscured optical unit. None of the mirrors M1 to M5 includes a passage opening for the illumination radiation 16.

The projection optical unit 10 has an image-side numerical aperture of 0.33. Depending on the embodiment of the projection optical unit 10, the image-side numerical aperture may range between 0.25 and 0.4, for example. Depending on the embodiment, the image-side numerical aperture of the projection optical unit 10 may also adopt different values.

Reflection surfaces of the mirrors Mᵢ are embodied as free-form surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 4, the mirrors Mi may have highly reflective coatings for the illumination radiation 16. These coatings can be designed as multilayer coatings, for example with alternating layers of molybdenum and silicon. A ruthenium coating is also possible, for example for coating mirrors for grazing incidence (GI mirrors).

The projection optical unit 10 leads to an imaging reduction in size, with a ratio of 4:1 (β=4.00). The imaging scale β is positive; thus, the projection optical unit 10 does not generate an image flip within the scope of imaging. Alternatively, the projection optical unit 10 can also be designed such that it leads to an image flip.

Hereinbelow, the sign convention of the imaging scale β is such that there is no intermediate image, not even in the form of a caustic, in the case of a negative imaging scale between the object field 5 and the image field 11, whereas an intermediate image, optionally in the form of a caustic, is indeed present in the case of a positive imaging scale.

In the case of yet a further alternative design of the projection optical unit 10, the latter can lead to an image flip in for example the x-direction, i.e. in the direction perpendicular to the scanning direction y. Thus, an imaging scale βₓ in the x-direction is −4.00 in that case. In the scanning direction y, this embodiment of the projection optical unit may then lead to a reduction in size of 4:1, but without an image flip in this case (β_{y}=+4.00).

The projection optical unit 10 may also have an anamorphic design in a further embodiment. In that case, it has different imaging scales βₓ, β_{y} in the x- and y-directions. The two imaging scales βₓ, β_{y} of the projection optical unit 10 can be (Bx, By)=(+/−4, +/−8).

Other imaging scales are likewise possible. Imaging scales with the same sign are also possible in the x- and y-directions.

The image field 11 has an x-extent of 26 mm and a y-extent of 2.5 mm.

The image field may have a partial-ring-shaped embodiment.

Alternatively, the image field may also have a rectangular embodiment.

In each case one of the pupil facets 22 is assigned to exactly one of the field facets 20 for the purpose of forming a respective illumination channel for illuminating the object field 5. For example, this can yield illumination according to the Köhler principle. The far field is decomposed into a multiplicity of object fields 5 with the aid of the field facets 20. The field facets 20 generate a plurality of images of the intermediate focus on the pupil facets 22 respectively assigned thereto.

By way of an assigned pupil facet 22, the field facets 20 are imaged in each case onto the reticle 7 in a manner superposed on one another for the purposes of illuminating the object field 5. The illumination of the object field 5 is for example as homogeneous as possible. It can have a uniformity error of less than 2%. Field uniformity can be achieved by superposing different illumination channels.

The illumination of the entrance pupil of the projection optical unit 10 can be defined geometrically by way of an arrangement of the pupil facets. The intensity distribution in the entrance pupil of the projection optical unit 10 can be set by selecting the illumination channels, for example the subset of the pupil facets which guide light. This intensity distribution is also referred to as illumination setting or illumination pupil filling.

A likewise preferred pupil uniformity in the region of sections of an illumination pupil of the illumination optical unit 4 that are illuminated in a defined manner can be achieved by a redistribution of the illumination channels.

Further aspects and details of the illumination of the object field 5 and for example of the entrance pupil of the projection optical unit 10 are described below.

The projection optical unit 10 may have for example a homocentric entrance pupil. The latter can be accessible.

In the x-direction, the projection optical unit 10 is approximately telecentric on the object side. In the x-direction, an entrance pupil has a distance of more than 7 m from the object plane 6. In the y-direction, the entrance pupil EP is situated in the beam path approximately 750 mm upstream of the object field 5.

In one variant, the projection optical unit has an entrance pupil EP (cf. FIG. 1) which both in the x-direction and in the y-direction is located in the range between 1500 mm and 2000 mm upstream of the object field 5 in the beam path, and is for example located in the range between 1800 mm and 2200 mm. An arrangement plane of this entrance pupil is depicted at EP in FIG. 1. Thus, if the pupil facet mirror 21 is arranged approximately 2 m upstream of the object field 5 in the beam path of the illumination or imaging light 16, then the pupil facet mirror 21 satisfies the positional condition of “arrangement in the region of the entrance pupil of the projection optical unit”.

An arrangement plane of the pupil facet mirror 21 can be imaged into the entrance pupil with the aid of further components of the illumination optical unit 4 should the entrance pupil be inaccessible.

The entrance pupil of the projection optical unit 10 regularly cannot be exactly illuminated using the pupil facet mirror 21. In the case of imaging of the projection optical unit 10 which telecentrically images the centre of the pupil facet mirror 21 onto the wafer 13, the aperture rays often do not intersect at a single point. However, it is possible to find an area in which the distance of the aperture rays determined in pairs becomes minimal. This area represents the entrance pupil or an area in real space that is conjugate thereto. For example, this area has a finite curvature.

It may be the case that the projection optical unit 10 has different poses of the entrance pupil for the tangential beam path and for the sagittal beam path. In this case, an imaging element, for example an optical component part of the transfer optical unit, should be provided between the second facet mirror 21 and the reticle 7. With the aid of this optical element, the different poses of the tangential entrance pupil and sagittal entrance pupil can be taken into account.

In the arrangement of the components of the illumination optical unit 4 illustrated in FIG. 1, the pupil facet mirror 21 is arranged so as to be tilted with respect to the object plane 5. The second facet mirror 21 is furthermore arranged so as to be tilted with respect to an arrangement plane defined by the first facet mirror 19.

Further details relating to the projection optical unit 10 are described hereinafter on the basis of FIG. 2.

The projection optical unit 10 has four NI mirrors (mirrors for normal incidence; normal incidence mirrors), namely the first mirror M1 and the three last mirrors M3, M4 and M5 in the imaging beam path of the projection optical unit 10. The imaging light 16 is applied to these NI mirrors M1, M3, M4, M5 at angles of incidence of less than 45°. The maximum angle of incidence of the imaging light 16 incident on the respective NI mirror, can be less than 40°, can be less than 35°, can be less than 30°, can be less than 25°, can be less than 20°, can be less than 15° and can also be less than 10°.

The last remaining mirror M2 of the projection optical unit 10 is a GI mirror (mirror for grazing incidence, grazing incidence mirror). For this mirror M2, there are angles of incidence of the illumination light 16 on the mirrors greater than 45° in each case. The minimum angle of incidence, which is incident on the respective GI mirror, can be greater than 50°, can be greater than 55°, can be greater than 60°, can be greater than 65°, can be greater than 70°, can be greater than 75° and can also be greater than 80°.

More than two GI mirrors might also be present, depending on the embodiment of the projection optical unit 10.

Information concerning reflection at a GI mirror (grazing incidence mirror) can be found in WO 2012/126867 A. Further information concerning the reflectivity of NI mirrors (normal incidence mirrors) can be found in DE 101 55 711 A.

None of the mirrors M1 to M5 has a passage opening and the mirrors are used in a reflective manner in a continuous region without gaps in each case.

FIG. 2 illustrates the calculated reflection surfaces of the mirrors M1 to M5. The used reflection surfaces of the mirrors M1 to M5 are carried in a known manner by mirror bodies (not shown). The actual used mirror surfaces of the mirrors M1 to M5 comprise the reflection surfaces actually used for reflecting the imaging light 16 and a polishing overrun edge PR (cf. insert in FIG. 2) with an inner edging RS and an outer edging RS. Thus, the polishing overrun edge, which encloses the reflection mirror surface used in fact for reflection, is incorporated in the used mirror surfaces of the mirrors M1 to M5 and, on the edge, projects beyond this reflection mirror surface by at least 10 mm along the entire circumference of the reflection surface. Thus, an overhang in the form of the polishing overrun edge of at least 10 mm is present between the reflection mirror surface and a no longer polished region of the mirror surface.

The object plane 6 and the image plane 12 extend parallel to one another to a good approximation.

The projection optical unit 10 has an intermediate image 23 in the form of an intermediate field region, which may also have the form of a caustic, between the object field 5 and the image field 11. In the yz-section, the intermediate image 23 is located between mirrors M3 and M4 in the imaging beam path of the imaging light 16. There is no intermediate image present in the xz-section.

A distance Z between the object plane 6 and the image plane 12 is 1976.14 mm in the z-direction.

An object-image offset d_{OIS} is 966.26 mm. The object-image offset d_{OIS} is measured between a central field point of the object field 5 and a central field point of the image field 11 in a manner perpendicular to a normal N of the object plane 6. This object-image offset d_{OIS} is smaller than the distance Z, and so it is also smaller than the spatial distance between the object field 5 and the image field 11.

The two mirrors M3 and M4 and also the two mirrors M4 and M5 have a subtractive deflection effect for the chief ray of the central object field point. Thus, the chief ray of the central object field point is guided zigzag in the course of the beam path between the mirrors M3 and M5.

An overall transmission of the projection optical unit 10, which emerges as a product of the EUV reflectivities of the mirrors M1 to M5 for the illumination light 16 along the imaging beam path through the projection optical unit 10, has a value of 13.39% in the projection optical unit 10 according to FIG. 2. On average, each individual one of the mirrors M1 to M5 thus has a reflectivity of 67%.

Thus, the overall transmission of the mirrors M1 to M5, i.e. the overall transmission of the projection optical unit 10, is greater than 10%.

Downstream of the intermediate image in the yz-section 23, the projection optical unit 10 has a pupil plane in the region of a reflection at the penultimate mirror M4. An aperture can be limited in the case of the projection optical unit 10 by way of an aperture stop, which bounds the imaging beam path on the edge side, for example, and which may be attached to the mirror M4. If desired, an inner obscuration may also be defined on the mirror M4 with the aid of an appropriate stop portion.

A z-distance between the mirror M5 and the image field 11 is 75 mm.

The entire projection optical unit 10 can be accommodated in a cuboid with the xyz-edge lengths of 489 mm, 1152 mm and 1544 mm.

Between the object field 5 and the image field 11, the imaging beam path of the projection optical unit 10 does not contain a crossing region in which two imaging beam path sections of the imaging beam path would cross. Overall, the imaging beam path extends in zigzag fashion between the object field 5 and the image field 11.

The projection optical unit 10 is telecentric on the image side.

The mirrors M1 to M5 carry a coating that optimises the reflectivity of the mirrors M1 to M5 for the imaging light 16. For the GI mirrors for example, this may be a lanthanum coating, a boron coating or a boron coating with an uppermost layer of lanthanum, or else a ruthenium coating. Other coating materials may also be used, for example lanthanum nitride and/or B₄C. In mirror M2 for grazing incidence, use can be made of a coating with e.g. one ply of boron or lanthanum. The highly reflecting layers, for example of the mirrors M1, M3, M4 and M5 for normal incidence, can be configured as multi-ply layers, wherein successive layers can be manufactured from different materials. Alternating material layers can also be used. A typical multi-ply layer can have fifty bilayers, respectively made of a layer of boron and a layer of lanthanum. Layers containing lanthanum nitride and/or boron, for example B₄C, may also be used.

Table 1, below, summarises parameters of the projection optical unit 10. In addition to the data already explained above, Table 1 also specifies values for an angle of a chief ray of a central field point with respect to the z-axis) (6.04° and a usable étendue of the projection optical unit and a mean wavefront aberration RMS. A mean wavefront aberration RMS is 10.3 mλ in the projection optical unit 10. Thus, this mean wavefront aberration is less than 50 mλ, is less than 25 mλ, is less than 2 mλ and, for example, is less than 15 mλ over the entire used image field 11.

Table 1 for FIG. 2

| Wavelength | 13.5 | nm |
|---|---|---|
| Image-side numerical aperture | | |
| Image field size in the x- and y-directions | (26 × 2.5) mm | |
| βₓ | | |
| β_{y} | | |
| Chief ray angle | 6.04° | |
| Étendue | 7.08 | mm² |
| Mean wavefront aberration RMS | 10.3 | mλ |
| Overall transmission | 13.4% | |
| Position of the entrance pupil (x) | −7083 | mm |
| Position of the entrance pupil (y) | 745 | mm |
| Object-image offset in the y-direction | 966 | mm |
| Distance between M7 and image plane | 75 | mm |
| Distance between the object plane and image | 1976 | mm |

| | |
|---|---|
| plane | |
| Tilt between object plane and image plane | 0° |
| Installation space cuboid | (489 × 1152 × 1544) mm |

Tables 2a, 2b below summarise the parameters “maximum angle of incidence”. “extent of the reflection surface in the x-direction”. “extent of the reflection surface in the y-direction” and “maximum mirror diameter” for the mirrors M1 to M5 of the projection optical unit 10.

Table 2a for FIG. 2

| | M1 | M2 | M3 |
|---|---|---|---|
| Maximum angle of incidence [°] | 5.6 | 76.2 | 26.9 |
| Minimum angle of incidence [°] | 4.1 | 70.9 | 22.6 |
| Extent of the reflection surface in the | 437.4 | 431.8 | 422.8 |
| x-direction [mm] | | | |
| Extent of the reflection surface in the | 323.9 | 319.1 | 107.9 |
| y-direction [mm] | | | |
| Maximum mirror diameter [mm] | 438.5 | 434.9 | 422.9 |

Table 2b for FIG. 2

| | M4 | M5 |
|---|---|---|
| Maximum angle of incidence [°] | 24.1 | 12.0 |
| Minimum angle of incidence [°] | 5.1 | 5.1 |
| Extent of the reflection surface in the | 400.4 | 489.4 |
| x-direction [mm] | | |
| Extent of the reflection surface in the | 162.8 | 466.4 |
| y-direction [mm] | | |
| Maximum mirror diameter [mm] | 400.5 | 489.8 |

For the GI mirror M2, there is a minimum angle of incidence of the imaging light 16 of 70.9° and a maximum angle of incidence of 76.2°. For the NI mirrors M1 and M3 to M5, there is a minimum angle of incidence of 4.1° and a maximum angle of incidence of 26.9°. The maximum angle of incidence is 12.0° on the last mirror M5.

The mirror M5 is the mirror with the largest reflection surface.

Measuring approximately 400 mm, the mirror M4 is the mirror with the smallest extent of the reflection surface in the x-direction. Measuring approximately 490 mm, the mirror M5 is the mirror with the largest extent of the reflection surface in the x-direction. Measuring approximately 108 mm, the mirror M3 is the mirror with the smallest extent of the reflection surface in the y-direction. Measuring approximately 466 mm, the last mirror M5 yet again is the mirror with the largest extent of the reflection surface in the y-direction.

An overall mirror surface, which represents a sum of the used mirror surfaces of the mirrors M1 to M5, is less than 1.5 m². This overall mirror surface includes the polishing overrun edge with an edge width of 20 mm. This overall mirror surface is 0.63 m² in the projection optical unit 10 according to FIG. 2.

Table 2c, below, tabulates the size of the mirror surfaces of the individual mirrors M1 to M5 including this polishing overrun edge:

Table 2c for FIG. 2

20 mm offset

| | M1 | M2 | M3 | M4 | M5 |
|---|---|---|---|---|---|
| Area [cm²] | 1475 | 1407 | 584 | 713 | 2137 |

The overall number of mirrors M1 to M5 has an overall polarisation rotation of no more than 10° along the imaging beam path when linearly polarised imaging light 16 is used. This overall polarisation rotation can be less than 7°, can be less than 6°, can be less than 5° and can also be less than 4°.

The maximum overall polarisation rotation of linearly polarised imaging light 16 in the imaging beam path of the projection optical unit 10 between the object field 5 and the image field 11 is 3.13°.

The mirrors M1 to M5 are embodied as free-form surfaces which cannot be described by a rotationally symmetric function. Other embodiments of the projection optical unit 10, in which at least one of the mirrors M1 to M5 is embodied as a rotationally symmetric asphere, are also possible. It is also possible for all mirrors M1 to M5 to be embodied as such aspheres.

A free-form surface can be described by the following free-form surface equation (Equation 1):

$$Z = \frac{{c}_{x} {x}^{2} + {c}_{y} {y}^{2}}{1 + \sqrt{1 - ( 1 + {k}_{x} ) {( {c}_{x} x )}^{2} - ( 1 + {k}_{y} ) {( {c}_{y} y )}^{2}}} + {C}_{1} x + {C}_{2} y + {C}_{3} {x}^{2} + {C}_{4} x y + {C}_{5} {y}^{2} + {C}_{6} {x}^{3} + … + {C}_{9} {y}^{3} + {C}_{10} {x}^{4} + … + {C}_{12} {x}^{2} {y}^{2} + … + {C}_{14} {y}^{4} + {C}_{15} {x}^{5} + … + {C}_{20} {y}^{5} + {C}_{21} {x}^{6} + … + {C}_{24} {x}^{3} {y}^{3} + … + {C}_{27} {y}^{6} + … \qquad ( 1 )$$

The following applies to the parameters of this Equation (1):

Z is the sagittal height of the free-form surface at the point x, y, where x²+y²=r². Here, r is the distance from the reference axis of the free-form surface equation

(x=0;y=0).

In the free-form surface Equation (1), C₁, C₂, C₃ . . . denote the coefficients of the free-form surface series expansion in powers of x and y.

In the case of a conical base area, cₓ, c_{y} is a constant corresponding to the vertex curvature of a corresponding asphere. Thus, cₓ=1/Rₓ (1/RDX) and c_{y}=1/R_{y} (1/RDY) applies. kₓ and k_{y} (CCX, CCY) each correspond to a conic constant of a corresponding asphere. Thus, Equation (1) describes a biconical free-form surface.

An alternative possible free-form surface can be produced from a rotationally symmetric reference surface. Such free-form surfaces for reflection surfaces of the mirrors of projection optical units of microlithographic projection exposure apparatuses are known from US 2007 0 058 269 A1.

Alternatively, a free-form surface can be described by the following free-form surface equation (Equation 2):

$$Z = \frac{ρ \cdot {h}^{2}}{1 + \sqrt{1 - ( 1 + k ) \cdot {ρ}^{2} \cdot {h}^{2}}} + \frac{\sqrt{1 - k \cdot {ρ}^{2} \cdot {h}^{2}}}{\sqrt{1 - ( 1 + k ) \cdot {ρ}^{2} \cdot {h}^{2}}} \cdot [ {( \frac{h}{{h}_{0}} )}^{2} \cdot ( 1 - {( \frac{h}{{h}_{0}} )}^{2} ) \cdot {\sum }_{l = 0}^{L - 1} {c}_{l + 1} \cdot {Q}_{l}^{0} ( {( \frac{h}{{h}_{0}} )}^{2} ) + {\sum }_{m = 1}^{M} ( {( \frac{h}{{h}_{0}} )}^{m} \cdot s ( m \cdot φ ) \cdot {\sum }_{n = 0}^{N} {a}_{p} \cdot {Q}_{n}^{m} ( {( \frac{h}{{h}_{0}} )}^{2} ) ) ]$$

$$where s ( m \cdot φ ) = \{ \begin{matrix}sin ( m \cdot φ ) , if m odd \\ cos ( m \cdot φ ) , if m even\end{matrix}$$

In this case, Z denotes the sagittal height Z(h, φ) of the free-form surface at a point (h, φ), represented in polar coordinates.

ρ=1/R denotes the curvature of the reference sphere.

h₀ denotes the normalisation height in mm.

$${Q}_{l}^{0}$$

denotes the l-th degree Forbes polynomial for azimuthal order 0, cₗ₊₁ denotes the associated coefficient.

$${Q}_{n}^{m}$$

denotes the n-th degree Forbes polynomial for azimuthal order m, aₚ denotes the associated coefficient for meridionally symmetric terms. In this case,

$$p = ( m + n + 1 ) \cdot \frac{m + n}{2} - m + 1 = ( m + n - 1 ) \cdot \frac{m + n}{2} + n - 1$$

with azimuthal order m and radial order n.

Regarding the description of Forbes free-form surfaces and regarding the description of Forbes polynomials, additional reference is made to DE 10 2018 214 437 A1 and the citations mentioned therein.

The coordinates of the mirrors are specified with regard to a coordinate system defined in such a way that an origin of the xyz-coordinate system is located in a centre of the image field on the wafer, where a z-axis of this coordinate system is perpendicular to the image plane and points from the image field centre in the direction of the last, aperture-limiting mirror of the imaging optical unit, where the y-axis of the coordinate system is oriented such that the reticle is located at positive y-coordinates.

Alternatively, free-form surfaces can also be described with the aid of two-dimensional spline surfaces. Examples for this are Bezier curves or non-uniform rational basis splines (NURBS). By way of example, two-dimensional spline surfaces can be described by a grid of points in an xy-plane and associated z-values, or by these points and gradients associated therewith. Depending on the respective type of the spline surface, the complete surface is obtained by interpolation between the grid points using for example polynomials or functions which have specific properties in respect of the continuity and differentiability thereof. Examples for this are analytical functions.

The optical design data of the reflection surfaces of the mirrors M1 to M5 of the projection optical unit 10 can be gathered from the further tables below.

Table 3 (Table 3a) specifies coordinates of a surface origin of a respective mirror surface and of an area of the object field 5, in relation to a xyz-coordinate system of the image field 11.

The first column specifies the distance of the respective mirror or of the object field 5 from a coordinate origin in the centre of the image field 11 in the x-direction (first column), in the y-direction (second column) and in the z-direction (third column).

The additional columns of Table 3 (Table 3b) additionally specify tilt values of the respective surface of the mirror M1 to M5 or of the object field 5 in relation to the x-, y- and z-axis. In the embodiment according to FIG. 2, the object field 5 and the image field 11 extend parallel to one another.

Table 4 (Tables 4a/4b . . . ) tabulates, separately for the mirrors M1 to M5, the parameters RDX, RDY, CCX, CCY and, sorted according to the powers in x and y, the values of the coefficients C1, C2, C3 . . . of the free-form surface series expansion according to Equation (1) above.

Table 5 tabulates the reflectivities of the mirrors M1 to M5 and also the overall transmission of the projection optical unit 10, which is 13.4%.

Table 3a for FIG. 2

| | x-distance [mm] | y-distance [mm] | z-distance [mm] |
|---|---|---|---|
| Object field | 0.00 | 966.26 | 1976.14 |
| M1 | 0.00 | 769.02 | 133.06 |
| M2 | 0.00 | 708.13 | 1391.30 |
| M3 | 0.00 | 544.88 | 1608.94 |
| M4 | 0.00 | 172.69 | 79.90 |
| Stop (AS) | 0.00 | 172.69 | 79.90 |
| M5 | 0.00 | 0.00 | 684.79 |
| Image field | 0.00 | 0.00 | 0.00 |

Table 3b for FIG. 2

| | Tilt about the | Tilt about the | Tilt about the |
|---|---|---|---|
| | x-axis [degrees] | y-axis [degrees] | z-axis [degrees] |
| Object field | 0.00 | 0.00 | 180.00 |
| M1 | 178.33 | 0.00 | 0.00 |
| M2 | −70.18 | 0.00 | 180.00 |
| M3 | 11.60 | 0.00 | 0.00 |
| M4 | 1.13 | 180.00 | 0.00 |
| Stop (AS) | 1.13 | 180.00 | 0.00 |
| M5 | 7.97 | 0.00 | 0.00 |
| Image field | 0.00 | 0.00 | 0.00 |

Table 4a for FIG. 2

| | M1 | M2 | M3 |
|---|---|---|---|
| RDX | −4751.935114 | −8170.943383 | 38901.860285 |
| RDY | −1769.956860 | 2805.512812 | −1121.790168 |
| CCX | 0.000000 | 0.000000 | 0.000000 |
| CCY | 0.000000 | 0.000000 | 0.000000 |
| x**i * y**j | Coefficient | Coefficient | Coefficient |
| x**0 * y**1 | −2.953765E−05 | 7.968139E−06 | −3.631119E−04 |
| x**2 * y**0 | 0.000000E+00 | 0.000000E+00 | 0.000000E+00 |
| x**0 * y**2 | 0.000000E+00 | 0.000000E+00 | 0.000000E+00 |
| x**2 * y**1 | 1.392585E−08 | −5.373732E−08 | −4.479346E−08 |
| x**0 * y**3 | 1.541610E−08 | 3.398953E−07 | −1.387149E−06 |
| x**4 * y**0 | −2.886344E−12 | −2.503400E−12 | 1.153966E−11 |
| x**2 * y**2 | −1.307473E−11 | −1.052706E−11 | −3.787398E−10 |
| x**0 * y**4 | 2.342756E−12 | 7.376448E−10 | −5.744601E−09 |
| x**4 * y**1 | 2.238222E−15 | −8.649229E−15 | −4.740591E−14 |
| x**2 * y**3 | 1.014547E−15 | 6.559039E−14 | −2.110248E−12 |
| x**0 * y**5 | −1.597703E−14 | 1.802950E−12 | −3.249302E−11 |
| x**6 * y**0 | −3.092105E−19 | −1.561043E−17 | 4.397187E−18 |
| x**4 * y**2 | −6.369648E−18 | 2.225057E−17 | −4.042596E−16 |
| x**2 * y**4 | −3.123684E−18 | 1.718784E−16 | −1.242976E−14 |
| x**0 * y**6 | 4.248197E−16 | 3.739513E−15 | −1.360681E−13 |
| x**6 * y**1 | −8.385132E−21 | 3.692642E−19 | −4.577280E−19 |
| x**4 * y**3 | −3.878410E−20 | 7.845569E−19 | −7.197384E−18 |
| x**2 * y**5 | −2.704290E−19 | 1.255658E−18 | −8.075387E−17 |
| x**0 * y**7 | 1.775870E−18 | 6.034779E−18 | −1.152969E−15 |
| x**8 * y**0 | 3.805963E−23 | 5.006445E−22 | −1.677142E−22 |
| x**6 * y**2 | 3.370009E−22 | 1.735721E−21 | −5.359635E−21 |
| x**4 * y**4 | 8.329659E−22 | 7.933478E−21 | −1.017172E−19 |
| x**2 * y**6 | 8.340654E−22 | 1.498083E−20 | −1.855085E−18 |
| x**0 * y**8 | −3.225173E−20 | 1.061361E−19 | −5.985056E−17 |
| x**8 * y**1 | 3.551847E−25 | −2.640903E−23 | 3.249136E−23 |
| x**6 * y**3 | 1.746382E−24 | −5.577164E−23 | 5.504871E−22 |
| x**4 * y**5 | 1.012223E−23 | −6.466228E−23 | 2.581861E−21 |
| x**2 * y**7 | 3.590519E−23 | −1.586241E−23 | −4.688879E−20 |
| x**0 * y**9 | −6.955319E−23 | 7.633980E−22 | 1.201594E−19 |
| x**10 * y**0 | −2.504157E−27 | −1.229768E−26 | 4.034964E−27 |
| x**8 * y**2 | −1.824394E−26 | −1.325502E−25 | 4.510174E−25 |
| x**6 * y**4 | −4.676660E−26 | −1.037793E−24 | 1.480528E−23 |
| x**4 * y**6 | −1.029070E−25 | −1.342376E−24 | 8.359995E−23 |
| x**2 * y**8 | −1.622789E−25 | −7.596869E−25 | 9.558334E−22 |
| x**0 * y**10 | 1.396855E−24 | −3.112765E−24 | 2.616510E−20 |
| x**10 * y**1 | −1.172157E−29 | 1.158331E−27 | −1.516953E−27 |
| x**8 * y**3 | 2.363741E−29 | 1.985159E−27 | −2.583610E−26 |
| x**6 * y**5 | −6.417940E−28 | 3.578585E−27 | −3.690111E−25 |
| x**4 * y**7 | −1.322897E−27 | 3.217977E−28 | 2.046539E−24 |
| x**2 * y**9 | −2.887306E−27 | 2.697044E−27 | 3.250372E−23 |
| x**0 * y**11 | 3.286992E−27 | −4.880855E−26 | −1.506576E−22 |
| x**12 * y**0 | 7.247151E−32 | 2.950490E−31 | −1.041392E−31 |
| x**10 * y**2 | 5.522644E−31 | 4.108996E−30 | −1.634374E−29 |
| x**8 * y**4 | 1.304195E−30 | 5.665762E−29 | −9.973947E−28 |
| x**6 * y**6 | 3.526541E−30 | 1.376648E−28 | −1.079791E−26 |
| x**4 * y**8 | 6.810962E−30 | 8.585015E−29 | −4.898006E−26 |
| x**2 * y**10 | 1.019099E−29 | 3.550552E−29 | −5.315298E−25 |
| x**0 * y**12 | −3.425514E−29 | 9.905293E−30 | −8.269109E−24 |
| x**12 * y**1 | 3.443019E−34 | −2.980179E−32 | 4.088259E−32 |
| x**10 * y**3 | −3.818815E−33 | −2.646322E−32 | 4.799270E−31 |
| x**8 * y**5 | 1.498219E−32 | 2.443424E−32 | 1.164108E−29 |
| x**6 * y**7 | 6.766092E−32 | 1.692370E−31 | 2.028930E−30 |
| x**4 * y**9 | 8.403065E−32 | 1.823404E−31 | −2.338291E−27 |
| x**2 * y**11 | 1.407823E−31 | −2.378997E−31 | −1.086865E−26 |
| x**0 * y**13 | −1.119230E−31 | 1.997059E−30 | 5.158913E−26 |
| x**14 * y**0 | −1.017101E−36 | −5.317780E−36 | 2.063608E−36 |
| x**12 * y**2 | −9.156894E−36 | −4.505572E−35 | 2.410073E−34 |
| x**10 * y**4 | −1.768591E−35 | −1.277630E−33 | 2.608336E−32 |
| x**8 * y**6 | −5.143509E−35 | −4.756683E−33 | 4.713790E−31 |
| x**6 * y**8 | −1.405402E−34 | −6.597339E−33 | 3.403716E−30 |
| x**4 * y**10 | −2.278586E−34 | −1.894656E−33 | 1.492179E−29 |
| x**2 * y**12 | −2.964365E−34 | −2.030974E−33 | 1.574195E−28 |
| x**0 * y**14 | 4.317322E−34 | 6.323966E−33 | 1.461655E−27 |
| x**14 * y**1 | −6.263157E−39 | 4.093502E−37 | −5.938737E−37 |
| x**12 * y**3 | 9.429125E−38 | −3.094592E−39 | −1.779198E−36 |
| x**10 * y**5 | −8.499630E−38 | −3.984444E−36 | −4.967938E−35 |
| x**8 * y**7 | −1.320203E−36 | −1.400166E−35 | 1.404591E−37 |
| x**6 * y**9 | −2.843063E−36 | −2.047035E−35 | 5.018132E−32 |
| x**4 * y**11 | −2.466655E−36 | −2.908133E−36 | 6.864485E−31 |
| x**2 * y**13 | −3.818020E−36 | 4.909135E−36 | 1.272128E−30 |
| x**0 * y**15 | 1.808080E−36 | −2.531564E−35 | −1.072110E−29 |
| x**16 * y**0 | 5.386594E−42 | 4.735219E−41 | −1.929881E−41 |
| x**14 * y**2 | 6.805596E−41 | 1.172065E−41 | −1.035793E−39 |
| x**12 * y**4 | 9.383835E−41 | 1.002296E−38 | −2.305124E−37 |
| x**10 * y**6 | 2.743624E−40 | 5.113368E−38 | −6.216820E−36 |
| x**8 * y**8 | 9.079743E−40 | 1.177764E−37 | −6.471068E−35 |
| x**6 * y**10 | 2.260263E−39 | 8.041320E−38 | −4.338829E−34 |
| x**4 * y**12 | 2.909730E−39 | 3.402346E−38 | −1.955469E−33 |
| x**2 * y**14 | 3.351225E−39 | 6.404319E−38 | −2.001238E−32 |
| x**0 * y**16 | −1.941056E−39 | −1.785804E−37 | −1.227868E−31 |
| x**16 * y**1 | 4.735264E−44 | −2.363115E−42 | 3.683427E−42 |
| x**14 * y**3 | −7.240512E−43 | 1.841274E−42 | −2.488074E−41 |
| x**12 * y**5 | −7.730447E−43 | 5.165940E−41 | −1.419747E−39 |
| x**10 * y**7 | 8.652701E−42 | 2.352647E−40 | −2.564562E−38 |
| x**8 * y**9 | 2.811234E−41 | 4.662423E−40 | −4.836372E−37 |
| x**6 * y**11 | 4.223339E−41 | 2.947272E−40 | −8.418005E−36 |
| x**4 * y**13 | 2.608872E−41 | 8.570041E−41 | −6.778058E−35 |
| x**2 * y**15 | 4.393026E−41 | 1.260694E−40 | 1.616661E−35 |
| x**0 * y**17 | −7.739080E−42 | −2.832768E−40 | 1.165801E−33 |

Table 4b for FIG. 2

| | M4 | M5 |
|---|---|---|
| RDX | 13790.428852 | −1203.263752 |
| RDY | 1023.846577 | −809.009487 |
| CCX | 0.000000 | 0.000000 |
| CCY | 0.000000 | 0.000000 |
| x**i * y**j | Coefficient | Coefficient |
| x**0 * y**1 | −1.101374E−04 | −4.381856E−05 |
| x**2 * y**0 | 0.000000E+00 | 0.000000E+00 |
| x**0 * y**2 | 0.000000E+00 | 0.000000E+00 |
| x**2 * y**1 | 1.086247E−07 | 1.123640E−08 |
| x**0 * y**3 | 1.469447E−07 | 2.578546E−08 |
| x**4 * y**0 | 1.417616E−10 | −4.195734E−11 |
| x**2 * y**2 | 8.965010E−10 | −8.630438E−11 |
| x**0 * y**4 | 1.999564E−09 | −3.828098E−11 |
| x**4 * y**1 | 1.822194E−13 | 8.559445E−15 |
| x**2 * y**3 | 1.033642E−12 | 3.802261E−14 |
| x**0 * y**5 | 2.060071E−12 | 2.248746E−14 |
| x**6 * y**0 | 1.662058E−16 | −4.199163E−17 |
| x**4 * y**2 | 1.738212E−15 | −1.663738E−16 |
| x**2 * y**4 | 7.349952E−15 | −2.004171E−16 |
| x**0 * y**6 | 2.994876E−14 | −1.310683E−16 |
| x**6 * y**1 | 2.491877E−19 | 7.333783E−21 |
| x**4 * y**3 | 2.842887E−18 | 1.546329E−20 |
| x**2 * y**5 | 7.819286E−18 | 9.288425E−20 |
| x**0 * y**7 | −3.646347E−16 | 4.773434E−19 |
| x**8 * y**0 | 5.847838E−23 | 1.686115E−23 |
| x**6 * y**2 | −3.504727E−21 | 8.667319E−23 |
| x**4 * y**4 | −6.123578E−20 | 2.123752E−22 |
| x**2 * y**6 | −4.354384E−19 | 1.121868E−22 |
| x**0 * y**8 | −5.656429E−18 | 2.276626E−21 |
| x**8 * y**1 | 8.845954E−24 | −9.233470E−26 |
| x**6 * y**3 | 1.589147E−23 | 2.763302E−24 |
| x**4 * y**5 | 5.894720E−22 | 3.363865E−24 |
| x**2 * y**7 | 5.286632E−21 | −9.265166E−25 |
| x**0 * y**9 | 7.349421E−20 | −1.075074E−23 |
| x**10 * y**0 | 1.010144E−26 | −2.297610E−27 |
| x**8 * y**2 | 4.401328E−25 | −1.454156E−26 |
| x**6 * y**4 | 6.913456E−24 | −3.714008E−26 |
| x**4 * y**6 | 4.695190E−23 | −5.113578E−26 |
| x**2 * y**8 | 1.759220E−22 | −2.967476E−26 |
| x**0 * y**10 | 9.075133E−22 | −4.698277E−26 |
| x**10 * y**1 | −3.686577E−28 | 6.014334E−30 |
| x**8 * y**3 | −3.929147E−28 | −9.619393E−29 |
| x**6 * y**5 | 8.300522E−27 | −2.503863E−28 |
| x**4 * y**7 | −4.482520E−25 | −9.125598E−29 |
| x**2 * y**9 | −2.749564E−24 | 8.149288E−29 |
| x**0 * y**11 | −1.173180E−23 | 2.184609E−28 |
| x**12 * y**0 | −2.849210E−31 | 4.943587E−32 |
| x**10 * y**2 | −1.461308E−29 | 3.698436E−31 |
| x**8 * y**4 | −2.924260E−28 | 1.112992E−30 |
| x**6 * y**6 | −2.704952E−27 | 1.853322E−30 |
| x**4 * y**8 | −1.257360E−26 | 1.811216E−30 |
| x**2 * y**10 | −3.571307E−26 | 8.057332E−31 |
| x**0 * y**12 | −7.301618E−26 | 4.375294E−31 |
| x**12 * y**1 | 8.954784E−33 | −1.292283E−34 |
| x**10 * y**3 | 2.289255E−32 | 1.744647E−33 |
| x**8 * y**5 | −1.288119E−30 | 7.586972E−33 |
| x**6 * y**7 | 2.712254E−30 | 7.834242E−33 |
| x**4 * y**9 | 1.474364E−28 | 1.429146E−35 |
| x**2 * y**11 | 6.258088E−28 | −2.458181E−33 |
| x**0 * y**13 | 1.192011E−27 | −2.709955E−33 |
| x**14 * y**0 | 4.290454E−36 | −5.523592E−37 |
| x**12 * y**2 | 2.511124E−34 | −4.858276E−36 |
| x**10 * y**4 | 6.060615E−33 | −1.721875E−35 |
| x**8 * y**6 | 7.265973E−32 | −3.381402E−35 |
| x**6 * y**8 | 4.490381E−31 | −4.125494E−35 |
| x**4 * y**10 | 1.606712E−30 | −3.101961E−35 |
| x**2 * y**12 | 3.800317E−30 | −1.106161E−35 |
| x**0 * y**14 | 2.436123E−30 | −1.027477E−36 |
| x**14 * y**1 | −1.069597E−37 | 1.180058E−39 |
| x**12 * y**3 | −4.777949E−37 | −1.566870E−38 |
| x**10 * y**5 | 3.329357E−35 | −1.008603E−37 |
| x**8 * y**7 | 2.720281E−34 | −1.761896E−37 |
| x**6 * y**9 | −1.603556E−33 | −8.747127E−38 |
| x**4 * y**11 | −2.099868E−32 | 3.492588E−38 |
| x**2 * y**13 | −6.744216E−32 | 3.552680E−38 |
| x**0 * y**15 | −6.034454E−32 | 1.566174E−38 |
| x**16 * y**0 | −2.580009E−41 | 2.471323E−42 |
| x**14 * y**2 | −1.708623E−39 | 2.515980E−41 |
| x**12 * y**4 | −4.815612E−38 | 1.037881E−40 |
| x**10 * y**6 | −7.178489E−37 | 2.393511E−40 |
| x**8 * y**8 | −5.728295E−36 | 3.421311E−40 |
| x**6 * y**10 | −2.656357E−35 | 3.326554E−40 |
| x**4 * y**12 | −7.904064E−35 | 2.021345E−40 |
| x**2 * y**14 | −1.623512E−34 | 5.947296E−41 |
| x**0 * y**16 | 5.206993E−38 | −7.528312E−42 |
| x**16 * y**1 | 4.877633E−43 | −3.606604E−45 |
| x**14 * y**3 | 3.126421E−42 | 5.495009E−44 |
| x**12 * y**5 | −2.790958E−40 | 5.000932E−43 |
| x**10 * y**7 | −4.371146E−39 | 1.222369E−42 |
| x**8 * y**9 | −1.079413E−38 | 1.208808E−42 |
| x**6 * y**11 | 1.553155E−37 | 1.896100E−43 |
| x**4 * y**13 | 1.092951E−36 | −3.767557E−43 |
| x**2 * y**15 | 2.821191E−36 | −1.985740E−43 |
| x**0 * y**17 | 8.851794E−37 | −1.682135E−44 |

Table 5 for FIG. 2

| Mirrors | Reflectivity |
|---|---|
| M1 | 67.6 |
| M2 | 75.9 |
| M3 | 59.7 |
| M4 | 65.2 |
| M5 | 67.0 |
| Overall | 13.4 |

Mirrors with different signs for the values RDX and RDY have a saddle point-type or minimax basic shape.

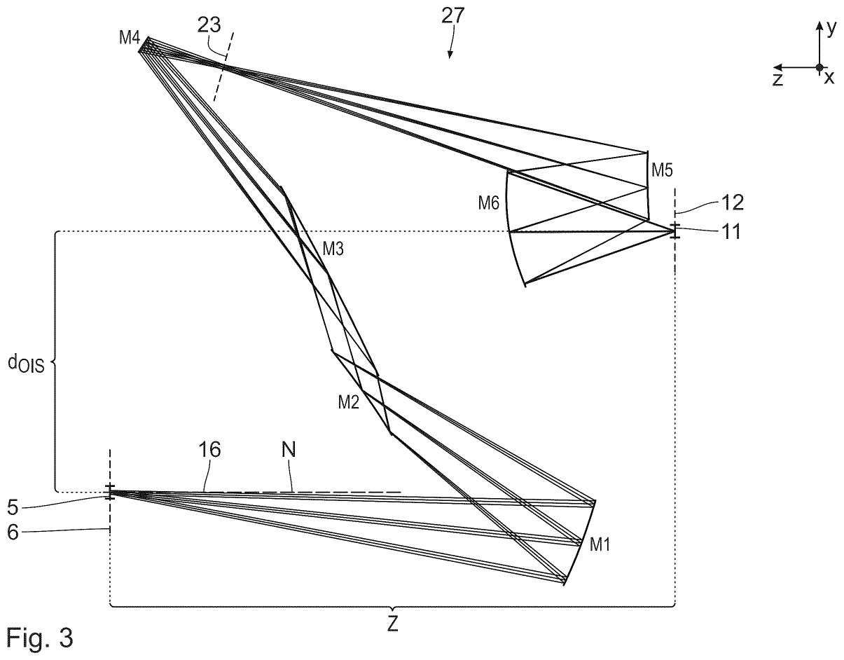

FIG. 3 shows a further embodiment of a projection optical unit or imaging optical unit 27, which can be used in the projection exposure apparatus 1 instead of the projection optical unit 10 of the embodiment according to FIG. 2. Components and functions corresponding to those which have already been explained above in conjunction with FIGS. 1 and 2, and for example in conjunction with FIG. 2, are denoted by the same reference signs and are not discussed in detail again.

The projection optical unit 27 has a total of six mirrors M1 to M6 in the imaging beam path between the object field 5 and the image field 11. The mirrors M1, M4, M5 and M6 are NI mirrors and the mirrors M2 and M3 are GI mirrors.

The two GI mirrors M2 and M3 have a subtractive deflection effect for the chief ray of the central object field point.

The two NI mirrors M4 and M5 add in terms of their deflection effect for the chief ray of the central object field point. The two last mirrors M5 and M6 in turn have a subtractive deflection effect for the chief ray of the central object field point. These deflection effects, especially of the mirrors M4 to M6 but also the deflection effects of the other mirrors M1 to M3, lead to the imaging beam path after the reflection at the mirror M1 being guided around a back side of the last mirror M6 such that, between mirrors M4 and M5, a component imaging beam passes the mirror M6 on the side distant from the mirror M1.

The number of intermediate image planes in the x-direction and in the y-direction in the beam path between the object field 5 and the image field 11 differ in the case of the projection optical unit 27. With an imaging scale β_{y}=+4.00 in the yz-plane, the projection optical unit 27 has an intermediate image 23, which may have the form of a caustic for example, as shown by the meridional section according to FIG. 2. In the imaging direction perpendicular thereto with the imaging scale βₓ=−4.00, the projection optical unit 10 has no intermediate image. The intermediate image 23 is present in the meridional plane of the projection optical unit 27, i.e. in a plane containing a chief ray of a central field point of the projection optical unit 27.

Examples of projection optical units with different numbers of such intermediate images in the x- and y-directions or in mutually perpendicular imaging light planes are known from U.S. Pat. No. 10,656,400 B2. Alternatively, the projection optical unit 27 may also be designed without an intermediate image or with the same number of intermediate images in the x- and y-directions.

The image plane 12 is the first field plane after the object plane 6 in the xz-main plane (sagittal plane) of the projection optical unit 27 perpendicular to the meridional plane, i.e. in the imaging beam path of the projection optical unit 27 perpendicular to the yz-meridional plane. Thus, the projection optical unit 27 does not have an intermediate image perpendicular to the meridional plane. Thus, there is an image flip perpendicular to the meridional plane.

In the projection optical unit 27, the chief ray angle of the central field point with respect to the normal N of the object plane 6 extends exactly counter to the case of the projection optical unit 10 and is 6.13° in the projection optical unit 27. A possible course of an input coupling illumination beam 16 of the illumination optical unit 4 is also indicated in FIG. 3.

The following tables summarise parameters and the optical design of the projection optical unit 27. In terms of their structure, these tables correspond to those already explained above in conjunction with FIG. 2.

Table 1 for FIG. 3

| Wavelength | 13.5 | nm |
|---|---|---|
| Image-side numerical aperture | | |
| Image field size in the x- and y-directions | (26 × 2.5) mm | |
| Image field radius | 40 | mm |
| βx | −4 (without | |
| | intermediate image) | |
| βy | 4 (with | |
| | intermediate image) | |
| Chief ray angle | 6.13° | |
| Étendue | 7.08 | mm² |
| Mean wavefront aberration RMS | 11 | mλ |
| Overall transmission | 11.1% | |
| Position of the entrance pupil (x) | −1760 | mm |
| Position of the entrance pupil (y) | −1468 | mm |
| Object-image offset in the y-direction | 762 | mm |
| Distance between M7 and image plane | 76 | mm |
| Distance between the object plane and image | 1650 | mm |

| | |
|---|---|
| plane | |
| Tilt between object plane and image plane | 0° |
| Installation space cuboid | (419 × 1594 × 1496) mm |

Table 2a for FIG. 3

| | M1 | M2 | M3 |
|---|---|---|---|
| Maximum angle of incidence [°] | 14.9 | 72.0 | 79.2 |
| Minimum angle of incidence [°] | 13.8 | 67.0 | 76.4 |
| Extent of the reflection surface in | 416.8 | 418.8 | 417.7 |
| the x-direction [mm] | | | |
| Extent of the reflection surface in | 264.1 | 292.1 | 590.9 |
| the y-direction [mm] | | | |
| Maximum mirror diameter [mm] | 417.4 | 419.0 | 600.3 |

Table 2b for FIG. 3

| | M4 | M5 | M6 |
|---|---|---|---|
| Maximum angle of incidence [°] | 21.1 | 23.8 | 13.9 |
| Minimum angle of incidence [°] | 14.3 | 9.3 | 3.8 |
| Extent of the reflection surface | 403.5 | 293.8 | 342.4 |
| in the x-direction [mm] | | | |
| Extent of the reflection surface | 61.8 | 193.8 | 327.9 |
| in the y-direction [mm] | | | |
| Maximum mirror diameter [mm] | 403.5 | 293.9 | 342.7 |

Table 3a for FIG. 3

| | x-distance [mm] | y-distance [mm] | z-distance [mm] |
|---|---|---|---|
| Object field | 0.00 | 762.07 | 1650.00 |
| M1 | 0.00 | 1080.56 | 349.60 |
| M2 | 0.00 | 475.21 | 906.14 |
| M3 | 0.00 | 113.19 | 1018.15 |
| M4 | 0.00 | −683.06 | 1450.52 |
| M5 | 0.00 | −266.53 | 77.95 |
| Stop (AS) | 0.00 | −149.03 | 257.03 |
| M6 | 0.00 | 0.00 | 484.19 |
| Image field | 0.00 | 0.00 | 0.00 |

Table 3b for FIG. 3

| | Tilt about the | Tilt about the | Tilt about the |
|---|---|---|---|
| | x-axis [degrees] | y-axis [degrees] | z-axis [degrees] |
| Object field | 0.00 | 0.00 | 0.00 |
| M1 | 35.45 | 180.00 | 0.00 |
| M2 | −29.89 | 0.00 | 0.00 |
| M3 | −22.85 | 180.00 | 0.00 |
| M4 | 39.19 | 0.00 | 0.00 |
| M5 | −8.19 | 180.00 | 0.00 |
| Stop (AS) | −33.27 | 180.00 | 0.00 |
| M6 | −16.63 | 0.00 | 0.00 |
| Image field | 0.00 | 0.00 | 0.00 |

Table 4a for FIG. 3

| | M1 | M2 | M3 |
|---|---|---|---|
| RDX | −3492.479898 | −65568.800526 | −11845.617313 |
| RDY | −1141.372463 | 2548.418838 | −8333.433699 |
| CCX | 0.000000 | 0.000000 | 0.000000 |
| CCY | 0.000000 | 0.000000 | 0.000000 |
| x**i * y**j | Coefficient | Coefficient | Coefficient |
| x**0 * y**1 | 1.172621E−01 | −9.726536E−02 | 8.600586E−02 |
| x**2 * y**0 | 0.000000E+00 | 0.000000E+00 | 0.000000E+00 |
| x**0 * y**2 | 0.000000E+00 | 0.000000E+00 | 0.000000E+00 |
| x**2 * y**1 | −2.258838E−08 | 5.214452E−08 | −1.880538E−08 |
| x**0 * y**3 | −1.624537E−07 | 2.099306E−07 | −2.913367E−08 |
| x**4 * y**0 | −3.983458E−12 | 1.416423E−11 | −1.037313E−11 |
| x**2 * y**2 | −8.785212E−11 | 1.794040E−10 | −4.238905E−12 |
| x**0 * y**4 | −8.730010E−11 | 6.320737E−10 | −3.559360E−11 |
| x**4 * y**1 | 9.483242E−14 | 1.341435E−13 | −6.717698E−14 |
| x**2 * y**3 | −4.691692E−13 | 5.937101E−13 | −3.381884E−14 |
| x**0 * y**5 | 4.304202E−13 | 1.603844E−12 | −3.410041E−14 |
| x**6 * y**0 | −5.266829E−17 | 1.351240E−18 | 3.262072E−17 |
| x**4 * y**2 | 1.935496E−15 | 4.671899E−16 | −2.909919E−17 |
| x**2 * y**4 | −2.833571E−15 | 2.206755E−15 | −4.053576E−17 |
| x**0 * y**6 | 1.857629E−15 | 4.866747E−15 | −4.359605E−17 |
| x**6 * y**1 | −2.016008E−18 | 6.832438E−21 | 5.113087E−20 |
| x**4 * y**3 | 1.819088E−17 | 1.881001E−18 | −8.948915E−20 |
| x**2 * y**5 | −1.273437E−17 | 8.067443E−18 | −8.155639E−20 |
| x**0 * y**7 | 5.888571E−18 | 1.624600E−17 | −6.033754E−20 |
| x**8 * y**0 | −1.573352E−21 | 3.062670E−22 | −5.620073E−22 |
| x**6 * y**2 | −3.167753E−20 | −1.133926E−21 | 3.233518E−22 |
| x**4 * y**4 | 1.009303E−19 | 4.832781E−21 | 7.821694E−23 |
| x**2 * y**6 | −3.380068E−20 | 2.797577E−20 | 5.925423E−23 |
| x**0 * y**8 | 1.735289E−20 | 5.583330E−20 | −6.658983E−23 |
| x**8 * y**1 | −4.099558E−23 | 3.276557E−24 | −1.856042E−24 |
| x**6 * y**3 | −2.510376E−22 | 4.469185E−24 | 1.300835E−24 |
| x**4 * y**5 | 3.548160E−22 | 1.330830E−23 | 1.049843E−24 |
| x**2 * y**7 | −3.005887E−23 | 1.107166E−22 | 9.258213E−26 |
| x**0 * y**9 | 3.305981E−23 | 1.324543E−22 | 1.308427E−25 |
| x**10 * y**0 | 4.347707E−26 | 7.589769E−27 | −4.165528E−27 |
| x**8 * y**2 | −4.071492E−25 | 1.391619E−25 | −1.440312E−26 |
| x**6 * y**4 | −9.851974E−25 | 3.433490E−25 | −7.151941E−27 |
| x**4 * y**6 | 8.251763E−25 | 4.050397E−25 | −6.826771E−27 |
| x**2 * y**8 | 9.128192E−26 | 5.894767E−25 | −5.056130E−27 |
| x**0 * y**10 | 3.185967E−26 | 6.105195E−25 | −6.469568E−28 |
| x**10 * y**1 | 1.230251E−27 | 9.462778E−29 | −3.254387E−29 |
| x**8 * y**3 | −1.768079E−27 | 6.400489E−28 | −1.453098E−28 |
| x**6 * y**5 | −1.390313E−27 | 2.176603E−27 | −8.623521E−29 |
| x**4 * y**7 | 1.295324E−27 | 1.852077E−27 | −1.708629E−29 |
| x**2 * y**9 | 2.797787E−28 | 1.692328E−27 | 2.021789E−30 |
| x**0 * y**11 | 2.114495E−29 | 4.307777E−27 | −2.249753E−30 |
| x**12 * y**0 | −8.721729E−32 | −4.978116E−31 | 5.820396E−31 |
| x**10 * y**2 | 1.404501E−29 | −3.832574E−30 | 2.093893E−31 |
| x**8 * y**4 | −3.564045E−30 | −1.167419E−29 | 2.264255E−31 |
| x**6 * y**6 | 9.736924E−31 | −1.378559E−29 | 6.314477E−32 |
| x**4 * y**8 | 1.296253E−30 | −1.287228E−29 | 1.823401E−31 |
| x**2 * y**10 | 2.015531E−31 | 5.387405E−30 | 6.540367E−32 |
| x**0 * y**12 | 2.137449E−32 | 8.130322E−30 | 6.969260E−33 |
| x**12 * y**1 | −1.985339E−33 | −4.475195E−33 | 1.446919E−33 |
| x**10 * y**3 | 7.890495E−32 | −3.146426E−32 | 4.850609E−33 |
| x**8 * y**5 | −1.015680E−32 | −7.029614E−32 | 2.701291E−33 |
| x**6 * y**7 | −1.549317E−33 | −1.042682E−31 | 7.886155E−34 |
| x**4 * y**9 | 1.228952E−33 | −3.811152E−32 | −1.586202E−34 |
| x**2 * y**11 | 9.693594E−35 | 6.260468E−32 | −9.671312E−35 |
| x**0 * y**13 | −2.229516E−35 | −2.923720E−32 | 2.137938E−36 |
| x**14 * y**0 | −4.329440E−37 | 4.350579E−36 | −5.765559E−36 |
| x**12 * y**2 | −1.129840E−35 | 3.038555E−35 | 1.848036E−36 |
| x**10 * y**4 | 2.172121E−34 | 1.415601E−34 | −3.104452E−36 |
| x**8 * y**6 | −4.887341E−35 | 2.250907E−34 | 1.726284E−36 |
| x**6 * y**8 | −2.193582E−35 | 4.375969E−34 | −2.454820E−36 |
| x**4 * y**10 | 3.439716E−36 | 1.731000E−34 | −1.307576E−36 |
| x**2 * y**12 | 8.207561E−37 | 1.823359E−34 | −3.115499E−37 |
| x**0 * y**14 | 1.098521E−38 | 2.598231E−34 | −3.244616E−38 |
| x**14 * y**1 | −7.168862E−40 | 2.456828E−38 | −2.193850E−39 |
| x**12 * y**3 | −1.990930E−38 | 4.248259E−37 | −5.245290E−38 |
| x**10 * y**5 | 2.342354E−37 | 7.647854E−37 | −3.111320E−38 |
| x**8 * y**7 | −8.276622E−38 | 2.156567E−36 | −1.459694E−38 |
| x**6 * y**9 | −2.590559E−38 | 2.134534E−36 | 3.116435E−39 |
| x**4 * y**11 | 4.907680E−39 | 5.101079E−38 | 2.596545E−39 |
| x**2 * y**13 | 1.103137E−39 | −6.238565E−38 | 6.065952E−40 |
| x**0 * y**15 | 1.492529E−40 | 2.007197E−36 | 2.918703E−41 |

Table 4b for FIG. 3

| | M4 | M5 | M6 |
|---|---|---|---|
| RDX | −10573.684249 | 3841.518449 | −844.066328 |
| RDY | −713.869041 | 1104.771169 | −644.663336 |
| CCX | 0.000000 | 0.000000 | 0.000000 |
| CCY | 0.000000 | 0.000000 | 0.000000 |
| x**i * y**j | Coefficient | Coefficient | Coefficient |
| x**0 * y**1 | 1.393927E−02 | −2.047523E−01 | 1.346420E−01 |
| x**2 * y**0 | 0.000000E+00 | 0.000000E+00 | 0.000000E+00 |
| x**0 * y**2 | 0.000000E+00 | 0.000000E+00 | 0.000000E+00 |
| x**2 * y**1 | −5.892004E−07 | −6.708079E−07 | 7.925402E−08 |
| x**0 * y**3 | 4.251578E−06 | −1.325913E−06 | 7.892985E−08 |
| x**4 * y**0 | 1.615188E−09 | 5.841371E−10 | −1.316390E−10 |
| x**2 * y**2 | 1.539902E−08 | 3.795565E−09 | −2.623218E−10 |
| x**0 * y**4 | −5.122217E−09 | 4.955862E−09 | −1.363905E−10 |
| x**4 * y**1 | −7.481125E−11 | −2.774229E−12 | 1.309650E−13 |
| x**2 * y**3 | −1.500470E−10 | −1.541840E−11 | 3.297199E−13 |
| x**0 * y**5 | −1.742862E−10 | −2.130967E−11 | 1.780356E−13 |
| x**6 * y**0 | 1.708495E−14 | 1.734085E−15 | −2.558243E−16 |
| x**4 * y**2 | 1.449238E−12 | 1.227645E−14 | −9.341920E−16 |
| x**2 * y**4 | 4.270767E−13 | 7.123274E−14 | −1.123320E−15 |
| x**0 * y**6 | 7.062170E−13 | 1.061990E−13 | −4.491882E−16 |
| x**6 * y**1 | −4.852992E−16 | −1.130204E−17 | 2.398177E−19 |
| x**4 * y**3 | −1.524642E−14 | 4.113586E−17 | 9.504782E−19 |
| x**2 * y**5 | 4.874997E−15 | −2.940176E−16 | 1.281588E−18 |
| x**0 * y**7 | 6.377261E−15 | −3.319659E−16 | 3.450794E−19 |
| x**8 * y**0 | −1.598280E−19 | −1.378997E−20 | −4.813780E−22 |
| x**6 * y**2 | 5.769159E−18 | −5.594761E−20 | −2.449307E−21 |
| x**4 * y**4 | 9.357292E−17 | −8.622406E−19 | −4.666231E−21 |
| x**2 * y**6 | −5.542492E−17 | 1.032341E−18 | −3.159244E−21 |
| x**0 * y**8 | −6.997922E−17 | −1.787261E−19 | 1.346950E−21 |
| x**8 * y**1 | 3.198121E−21 | 1.372002E−21 | 1.834207E−24 |
| x**6 * y**3 | −3.837774E−20 | 3.388009E−21 | 8.556639E−24 |
| x**4 * y**5 | −3.264982E−19 | 3.928432E−21 | 9.706705E−24 |
| x**2 * y**7 | 2.352314E−19 | −1.851515E−21 | 2.729817E−24 |
| x**0 * y**9 | 2.632688E−19 | 7.882432E−21 | 1.434048E−23 |
| x**10 * y**0 | −2.970194E−24 | −8.485961E−25 | 4.289557E−28 |
| x**8 * y**2 | −1.376908E−23 | −3.983028E−23 | −1.021114E−26 |
| x**6 * y**4 | 1.610027E−22 | −4.658511E−23 | 1.121302E−26 |
| x**4 * y**6 | 5.362498E−22 | 1.168720E−23 | −3.531260E−26 |
| x**2 * y**8 | −3.934518E−22 | −1.003389E−23 | −6.907308E−26 |
| x**0 * y**10 | −3.442594E−22 | −3.923980E−23 | −3.192263E−26 |
| x**10 * y**1 | 6.555523E−26 | 3.960773E−26 | −6.993785E−29 |
| x**8 * y**3 | −9.642922E−26 | 5.763156E−25 | −3.852437E−28 |
| x**6 * y**5 | −4.061678E−25 | 3.086882E−25 | −5.849289E−28 |
| x**4 * y**7 | −3.640819E−26 | −2.054777E−25 | −2.671676E−28 |
| x**2 * y**9 | −1.428296E−25 | 1.097925E−25 | −8.990092E−29 |
| x**0 * y**11 | −3.493922E−25 | 6.877965E−26 | −4.828444E−28 |
| x**12 * y**0 | −2.230243E−29 | −1.096228E−29 | −5.073341E−32 |
| x**10 * y**2 | −4.860186E−28 | −6.723850E−28 | 2.713599E−31 |
| x**8 * y**4 | 7.083943E−28 | −4.622253E−27 | −1.279653E−30 |
| x**6 * y**6 | 2.366986E−28 | −8.342184E−28 | −2.278601E−30 |
| x**4 * y**8 | −5.065507E−28 | 9.016615E−28 | 9.347688E−31 |
| x**2 * y**10 | 6.617444E−28 | −4.377642E−28 | 1.222782E−30 |
| x**0 * y**12 | 6.872104E−28 | 2.036867E−28 | −1.582958E−31 |
| x**12 * y**1 | 3.477707E−31 | 2.545019E−31 | 2.045623E−33 |
| x**10 * y**3 | 1.120271E−30 | 5.350094E−30 | 1.287130E−32 |
| x**8 * y**5 | 1.649245E−30 | 2.076254E−29 | 2.627023E−32 |
| x**6 * y**7 | 1.485322E−30 | −1.016151E−30 | 2.584046E−32 |
| x**4 * y**9 | −6.136376E−31 | −1.499209E−30 | 1.180677E−32 |
| x**2 * y**11 | 1.152978E−30 | 6.427984E−31 | 3.737042E−33 |
| x**0 * y**13 | 2.073601E−30 | −1.397118E−30 | 6.431531E−33 |
| x**14 * y**0 | −2.320333E−36 | 5.745196E−36 | 5.900540E−37 |
| x**12 * y**2 | −1.786699E−33 | −1.916076E−33 | −5.300158E−36 |
| x**10 * y**4 | 1.715998E−33 | −2.018930E−32 | 1.290697E−35 |
| x**8 * y**6 | −2.082846E−32 | −4.851319E−32 | 5.876712E−35 |
| x**6 * y**8 | −8.545628E−34 | 1.069548E−32 | 4.086872E−35 |
| x**4 * y**10 | −3.798504E−33 | −4.168513E−34 | −1.874188E−35 |
| x**2 * y**12 | 1.516204E−33 | 5.809067E−34 | −4.123241E−36 |
| x**0 * y**14 | −1.988233E−33 | 2.934395E−33 | 3.200627E−36 |
| x**14 * y**1 | 1.485805E−38 | −8.829868E−38 | −2.323882E−38 |
| x**12 * y**3 | 3.011516E−36 | 4.860767E−36 | −1.676973E−37 |
| x**10 * y**5 | −7.503251E−36 | 2.894485E−35 | −3.910606E−37 |
| x**8 * y**7 | 4.015884E−35 | 4.546528E−35 | −5.264830E−37 |
| x**6 * y**9 | −6.591914E−36 | −1.687195E−35 | −4.219271E−37 |
| x**4 * y**11 | 1.292724E−35 | 2.987660E−36 | −1.979838E−37 |
| x**2 * y**13 | −1.032328E−35 | −2.016314E−36 | −1.482393E−39 |
| x**0 * y**15 | −4.643113E−36 | −2.189770E−36 | −3.228704E−38 |

Table 5 for FIG. 3

| Mirrors | Reflectivity |
|---|---|
| M1 | 65.8 |
| M2 | 73.2 |
| M3 | 83.3 |
| M4 | 64.5 |
| M5 | 64.6 |
| M6 | 66.8 |
| Overall | 11.2 |

In the projection optical unit 27, none of the mirrors M1 to M6 has an extent in the x-direction of more than 420 mm. Thus, this x-extent is less than 500 mm, less than 450 mm and less than 425 mm for all mirrors in the projection optical unit 27 for example.

None of the mirrors of the projection optical unit 27 has a y-extent of more than 600 mm. Apart from the GI mirror M3, none of the other mirrors has a y-extent of more than 350 mm.

Five of the six mirrors of the projection optical unit 27, specifically the mirrors M1, M2, M4, M5 and M6, have a maximum mirror diameter which is less than 420 mm.

In the projection optical unit 27 according to FIG. 3, the overall mirror area including a polishing overrun of 20 mm is 0.70 m².

The overall polarisation rotation of linearly polarised imaging light 16 in the imaging beam path of the projection optical unit 27 between the object field 5 and the image field 11 is no more than 3.16°.

In the projection optical unit 27, an image-side pupil plane is located in the imaging beam path between the mirrors M5 and M6.

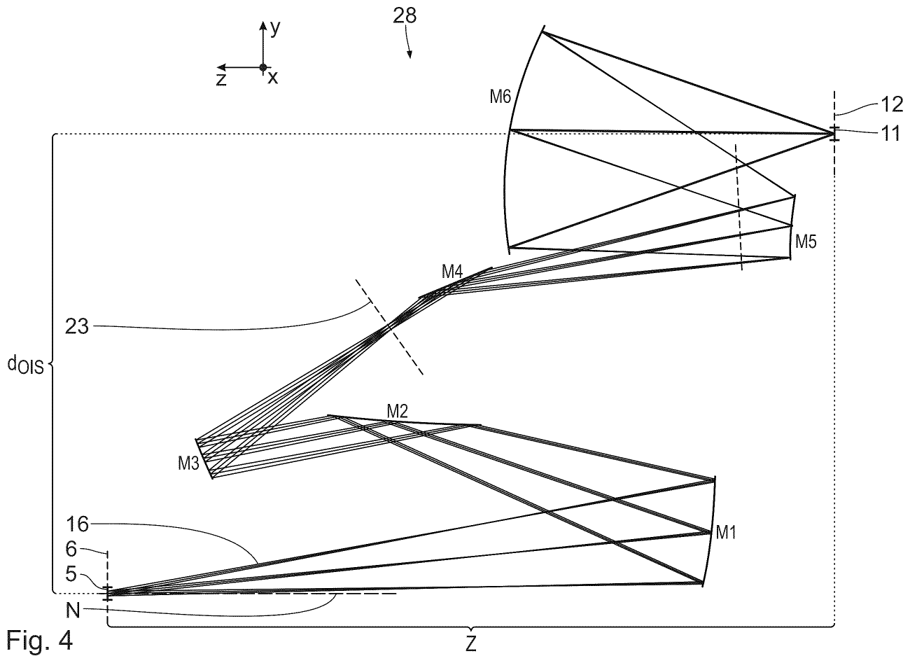

FIG. 4 shows a further embodiment of a projection optical unit or imaging optical unit 28, which can be used in the projection exposure apparatus 1 instead of the projection optical unit 10 of the embodiment according to FIG. 2. Components and functions corresponding to those which have already been explained above in conjunction with FIGS. 1 to 3, and for example in conjunction with FIGS. 2 and 3, are denoted by the same reference signs and are not discussed in detail again.

In terms of basic design, the projection optical unit 28 according to FIG. 4 is similar to the projection optical unit 10 according to FIG. 2, apart from a representation mirrored about the xz-plane. A difference is that the projection optical unit 28 has a total of six mirrors, two of which are GI mirrors, specifically a first GI mirror M2 between the NI mirrors M1 and M3 and a second GI mirror M4 between the NI mirrors M3 and M5.

The mirrors M4, M5 and M6 each have a subtractive deflection effect for the chief ray of the central object field point, with the result that the imaging beam path is guided zigzag over these mirrors M4 to M6.

The following tables summarise parameters and the optical design of the projection optical unit 28. In terms of their structure, these tables correspond to those already explained above in conjunction with FIG. 2. Table 4 (Tables 4a/4b) describes the free-form surfaces of the mirrors M1 to M6 on the basis of the aforementioned Forbes free-form surface equation (2).

Table 1 for FIG. 4

| Wavelength | 13.5 | nm |
|---|---|---|
| Image-side numerical aperture | 0.33 | |
| Image field size in the x- and y-directions | (26 × 2.5) mm | |
| βx | −4 (without | |
| | intermediate image) | |
| βy | 4 (with | |
| | intermediate image) | |
| Chief ray angle | 5.75° | |
| Étendue | 7.08 | mm² |
| Mean wavefront aberration RMS | 19.4 | mλ |
| Overall transmission | 12.3% | |
| Position of the entrance pupil (x) | −1486 | mm |
| Position of the entrance pupil (y) | 801 | mm |
| Object-image offset in the y-direction | 985 | mm |
| Distance between M7 and image plane | 85 | mm |
| Distance between the object plane and image | 1558 | mm |

| | |
|---|---|
| plane | |
| Tilt between object plane and image plane | 0° |
| Installation space cuboid | (492 × 1188 × 1284) mm |

Table 2a for FIG. 4

| | M1 | M2 | M3 |
|---|---|---|---|
| Maximum angle of incidence [°] | 13.0 | 78.5 | 14.6 |
| Minimum angle of incidence [°] | 11.5 | 71.8 | 9.9 |
| Extent of the reflection surface in | 409.9 | 339.7 | 267.6 |
| the x-direction [mm] | | | |
| Extent of the reflection surface in | 229.1 | 315.5 | 88.8 |
| the y-direction [mm] | | | |
| Maximum mirror diameter [mm] | 410.2 | 366.9 | 267.8 |

Table 2b for FIG. 4

| | M4 | M5 | M6 |
|---|---|---|---|
| Maximum angle of incidence [°] | 81.6 | 23.8 | 11.6 |
| Minimum angle of incidence [°] | 72.9 | 3.6 | 6.9 |
| Extent of the reflection surface | 286.0 | 315.1 | 492.3 |
| in the x-direction [mm] | | | |
| Extent of the reflection surface | 153.7 | 131.8 | 472.8 |
| in the y-direction [mm] | | | |
| Maximum mirror diameter [mm] | 290.1 | 315.1 | 493.0 |

Table 3a for FIG. 4

| | x-distance [mm] | y-distance [mm] | z-distance [mm] |
|---|---|---|---|
| Object field | 0.00 | 984.99 | 1557.89 |
| M1 | 0.00 | 854.13 | 263.68 |
| M2 | 0.00 | 616.11 | 953.00 |
| M3 | 0.00 | 692.63 | 1353.82 |
| M4 | 0.00 | 334.46 | 845.86 |
| M5 | 0.00 | 201.98 | 93.15 |
| Stop (AS) | 0.00 | 161.65 | 205.03 |
| M6 | 0.00 | −0.89 | 697.09 |
| Image field | 0.00 | 0.00 | 0.00 |

Table 3b for FIG. 4

| | Tilt about the x- | Tilt about the y- | Tilt about the z- |
|---|---|---|---|
| | axis [degrees] | axis [degrees] | axis [degrees] |
| Object field | 0.00 | 0.00 | 0.00 |
| M1 | 6.15 | 180.00 | 0.00 |
| M2 | 94.02 | 0.00 | 0.00 |
| M3 | −23.58 | 0.00 | 180.00 |
| M4 | 65.81 | 0.00 | 0.00 |
| M5 | 3.27 | 180.00 | 0.00 |
| Stop (AS) | −2.95 | 180.00 | 0.00 |
| M6 | 9.14 | 0.00 | 0.00 |
| Image field | 0.00 | 0.00 | 0.00 |

Table 4a for FIG. 4

| | M1 | M2 | M3 |
|---|---|---|---|
| RDY | −1587.395509 | −39015.686951 | −3110.219318 |
| CCY | 0.000000 | 0.000000 | 0.000000 |
| c_1/a_p | Coefficient | Coefficient | Coefficient |
| c_1 | 0.160490 | −0.038386 | 0.244205 |
| c_2 | −0.004227146 | 0.001011123 | −0.00915486 |
| c_3 | −2.375613E−03 | −2.788054E−04 | −7.431302E−03 |
| c_4 | 9.338199E−04 | 1.776730E−04 | 6.847988E−03 |
| c_5 | −1.797503E−04 | −9.714825E−05 | −2.791048E−03 |
| c_6 | −1.513861E−05 | 4.514590E−05 | 5.094074E−04 |
| c_7 | 4.738457E−05 | −1.786425E−05 | −3.155753E−05 |
| c_8 | −4.107973E−05 | 5.484656E−06 | −4.002286E−06 |
| c_9 | 2.933589E−05 | −9.822163E−07 | 5.798950E−06 |
| c_10 | −1.887481E−05 | 2.065305E−08 | −4.800953E−06 |
| c_11 | 1.093345E−05 | 4.587078E−07 | 3.516150E−06 |
| c_12 | −5.630776E−06 | −5.469951E−08 | −2.280692E−06 |
| c_13 | 2.279253E−06 | −1.500304E−07 | 1.069253E−06 |
| c_14 | −6.757832E−07 | −3.028118E−08 | −3.991284E−07 |
| a_1 | −1.078075E+00 | 6.374705E−01 | −2.947869E+00 |
| a_2 | 6.579849E+00 | −8.735414E+00 | 9.169302E+00 |
| a_3 | −7.031354E−01 | −2.526542E−01 | 1.543228E+00 |
| a_4 | −2.144510E−01 | −6.304092E−01 | 6.100605E−01 |
| a_5 | −1.511342E−01 | 3.834761E−02 | −2.428511E−01 |
| a_6 | 4.781508E−02 | 5.938422E−03 | −8.402541E−02 |
| a_7 | −1.036421E−01 | 4.647351E−02 | −1.585948E−01 |
| a_8 | 4.405286E−02 | 4.101562E−03 | −9.057167E−02 |
| a_9 | 5.431767E−03 | −1.249140E−03 | 2.205962E−02 |
| a_10 | −1.620657E−03 | −5.828595E−04 | −2.199785E−04 |
| a_11 | 2.868225E−02 | 2.264967E−03 | −6.901446E−02 |
| a_12 | 5.701333E−03 | −7.156688E−04 | 4.542610E−02 |
| a_13 | −1.685198E−03 | −3.965570E−04 | 8.005386E−03 |
| a_14 | 2.987075E−03 | 4.164395E−04 | 4.229982E−03 |
| a_15 | −1.017473E−03 | 3.467400E−04 | 1.065715E−02 |
| a_16 | 3.890692E−03 | 1.964416E−04 | 3.990927E−02 |
| a_17 | −2.095731E−03 | −1.222328E−04 | 1.920176E−02 |
| a_18 | 2.105844E−03 | 1.276530E−04 | −7.990153E−03 |
| a_19 | −6.702652E−04 | 2.284270E−04 | 5.332805E−03 |
| a_20 | −1.203653E−03 | −2.518068E−04 | −6.838430E−03 |
| a_21 | 3.884941E−04 | −1.962857E−04 | −5.814942E−03 |
| a_22 | −1.519140E−03 | 1.516305E−04 | 1.469963E−02 |
| a_23 | 1.616977E−03 | 5.084573E−05 | −1.739647E−02 |
| a_24 | −3.248530E−04 | 5.688056E−05 | −5.317544E−04 |
| a_25 | −7.482264E−04 | −7.640762E−05 | −1.309311E−03 |
| a_26 | 2.332171E−04 | −1.193602E−04 | −3.682281E−03 |
| a_27 | 2.834264E−04 | 1.221822E−04 | 3.040144E−03 |
| a_28 | −1.141567E−04 | 9.493474E−05 | 1.318963E−03 |
| a_29 | 9.567307E−04 | −1.078502E−04 | −1.102276E−02 |
| a_30 | −1.593119E−04 | 1.918896E−05 | −3.514421E−03 |
| a_31 | −4.297400E−04 | −3.801559E−05 | 2.380316E−03 |
| a_32 | 8.532692E−05 | −2.538719E−05 | −1.362849E−03 |
| a_33 | 1.334822E−04 | 3.568310E−05 | 1.312469E−03 |
| a_34 | −6.137905E−05 | 5.105098E−05 | 8.556518E−04 |
| a_35 | −5.328699E−05 | −5.124543E−05 | −5.581193E−04 |
| a_36 | 2.676486E−05 | −3.937156E−05 | −9.012457E−05 |
| a_37 | −6.043507E−05 | −6.909736E−05 | −1.698646E−03 |
| a_38 | −3.022691E−04 | 1.241596E−05 | 3.032754E−03 |
| a_39 | 2.176065E−05 | −1.265005E−05 | −7.369365E−05 |
| a_40 | 4.644191E−05 | 9.907729E−06 | 1.469911E−04 |
| a_41 | −1.502252E−05 | 7.729339E−06 | 3.585125E−04 |
| a_42 | −1.675579E−05 | −1.200697E−05 | −2.462881E−04 |
| a_43 | 1.288838E−05 | −1.710447E−05 | −5.445706E−05 |
| a_44 | 7.160408E−06 | 1.706747E−05 | 3.602114E−05 |
| a_45 | −3.937581E−06 | 1.233012E−05 | −1.649567E−06 |
| a_46 | −1.789671E−04 | 2.445358E−05 | 1.140277E−03 |
| a_47 | 1.464436E−06 | 7.837531E−06 | 1.435983E−04 |
| a_48 | 1.228655E−05 | 1.064123E−06 | −1.418980E−04 |
| a_49 | −1.390257E−06 | 2.322678E−06 | 7.919570E−05 |
| a_50 | −2.685772E−06 | −1.558182E−06 | −5.494367E−05 |
| a_51 | 1.843802E−06 | −1.267549E−06 | −1.468050E−05 |
| a_52 | 9.002581E−07 | 2.657841E−06 | 8.511879E−06 |
| a_53 | −1.593004E−06 | 3.753508E−06 | 6.533883E−07 |
| a_54 | −6.409007E−07 | −3.562252E−06 | −1.949237E−06 |
| a_55 | 1.390494E−07 | −2.263292E−06 | 9.785085E−07 |

Table 4b for FIG. 4

| | M4 | M5 | M6 |
|---|---|---|---|
| RDY | 29927.581955 | 1023.045445 | −880.852295 |
| CCY | 0.000000 | 0.000000 | 0.000000 |
| c_1/a_p | Coefficient | Coefficient | Coefficient |
| c_1 | −0.033610 | −1.641973 | 0.167068 |
| c_2 | 0.011333385 | 0.055000203 | −0.002838942 |
| c_3 | −1.274647E−02 | 5.557845E−03 | 2.177546E−05 |
| c_4 | 8.723962E−03 | −2.497708E−04 | 3.709566E−05 |
| c_5 | −3.354651E−03 | −1.635059E−03 | −2.766623E−05 |
| c_6 | 7.311364E−04 | 7.031197E−04 | 1.831172E−05 |
| c_7 | −1.341952E−04 | −1.164288E−04 | −1.047022E−05 |
| c_8 | 2.835357E−05 | 5.735409E−06 | 6.727944E−06 |
| c_9 | −3.252749E−06 | 1.005219E−06 | −2.997906E−06 |
| c_10 | 2.502908E−06 | −7.675099E−08 | 2.880028E−06 |
| c_11 | −3.544447E−06 | −5.459824E−07 | −6.806353E−07 |
| c_12 | 3.341691E−06 | 8.550315E−07 | 1.697809E−06 |
| c_13 | −2.429838E−06 | −7.315329E−07 | −1.399791E−06 |
| c_14 | 1.278914E−06 | 1.227571E−07 | 1.005870E−06 |
| a_1 | 4.295191E+00 | 2.200570E−01 | 8.505054E−01 |
| a_2 | 6.269825E−01 | −1.374981E+01 | 6.170340E+00 |
| a_3 | −5.685144E−02 | −2.940245E+00 | −1.581080E−01 |
| a_4 | 1.035558E−03 | −1.187043E+00 | 4.194220E−02 |
| a_5 | 9.144158E−03 | 1.305045E+00 | −5.771301E−02 |
| a_6 | 1.574678E−02 | 2.361584E−01 | 3.373641E−03 |
| a_7 | 1.905921E−02 | 7.232849E−01 | −2.609541E−02 |
| a_8 | 1.234281E−02 | 1.590576E−01 | 1.774589E−03 |
| a_9 | −1.243458E−02 | −6.312187E−02 | 1.402393E−03 |
| a_10 | −1.650445E−02 | −3.803985E−02 | −3.485321E−05 |
| a_11 | 1.048332E−02 | 5.823763E−02 | 2.433036E−06 |
| a_12 | −7.936969E−03 | −5.579220E−02 | 6.576873E−04 |
| a_13 | −9.645433E−03 | −2.129601E−02 | −2.607553E−05 |
| a_14 | 1.371574E−02 | −8.700951E−03 | −6.714017E−06 |
| a_15 | 1.516744E−02 | 1.651860E−02 | −4.966518E−05 |
| a_16 | −6.829747E−03 | −4.783951E−02 | 1.084167E−04 |
| a_17 | −3.609321E−03 | −6.009502E−03 | −8.762465E−06 |
| a_18 | 6.026140E−03 | −7.747879E−03 | −1.224351E−05 |
| a_19 | 9.101377E−03 | 8.981264E−03 | −1.522865E−05 |
| a_20 | −9.648005E−03 | 1.578948E−03 | −2.854312E−05 |
| a_21 | −7.871624E−03 | −7.367225E−03 | 3.694145E−05 |
| a_22 | −3.597976E−03 | −6.008559E−04 | 8.165169E−07 |
| a_23 | 1.058434E−03 | −7.208330E−04 | −7.269956E−06 |
| a_24 | 2.767920E−03 | 1.686961E−03 | −2.438946E−06 |
| a_25 | −4.666019E−03 | 3.016700E−03 | −4.248169E−06 |
| a_26 | −4.813806E−03 | −4.241205E−03 | 9.536821E−06 |
| a_27 | 3.621351E−03 | 1.448641E−03 | 2.004375E−05 |
| a_28 | 2.218909E−03 | 1.989954E−03 | −2.269828E−05 |
| a_29 | 1.895573E−03 | 8.019460E−03 | −2.556763E−06 |
| a_30 | −1.432528E−04 | −1.247956E−03 | −2.037375E−06 |
| a_31 | −8.521711E−04 | 2.155459E−03 | 5.435141E−07 |
| a_32 | −1.793042E−03 | −1.237520E−03 | 4.953581E−07 |
| a_33 | 1.797674E−03 | 1.158377E−04 | 3.063720E−06 |
| a_34 | 1.245134E−03 | 1.146446E−03 | −5.037355E−06 |
| a_35 | −6.957436E−04 | −6.919177E−04 | −1.194782E−05 |
| a_36 | −3.840304E−04 | −2.318345E−04 | 1.393429E−05 |
| a_37 | 6.806564E−04 | 7.964203E−05 | −1.492623E−06 |
| a_38 | 1.589624E−04 | −1.094315E−04 | 4.056755E−07 |
| a_39 | −1.063256E−04 | 1.222431E−04 | −1.143172E−07 |
| a_40 | 4.541510E−04 | −3.171058E−04 | 3.124449E−08 |
| a_41 | 4.759828E−04 | 3.867294E−04 | −1.340452E−07 |
| a_42 | −2.872895E−04 | −2.132842E−04 | −1.489624E−06 |
| a_43 | −1.375795E−04 | −1.141371E−04 | 2.043425E−06 |
| a_44 | 8.932195E−05 | 1.083683E−04 | 5.735251E−06 |
| a_45 | 7.398526E−05 | 9.515177E−06 | −5.224281E−06 |
| a_46 | −2.299267E−04 | −1.402667E−03 | 6.306268E−07 |
| a_47 | 7.544080E−05 | 2.898743E−04 | −2.107562E−08 |
| a_48 | −4.456269E−06 | −1.508430E−04 | 1.818783E−07 |
| a_49 | 5.882472E−05 | 6.321985E−05 | −5.442250E−09 |
| a_50 | −6.444107E−05 | −1.797940E−05 | −3.356079E−08 |
| a_51 | −3.746317E−05 | −2.378743E−05 | 5.295676E−08 |
| a_52 | 1.257818E−05 | 2.447388E−05 | 6.018017E−07 |
| a_53 | 8.757415E−06 | 3.737633E−06 | −5.708476E−07 |
| a_54 | −1.439402E−05 | −5.381328E−06 | −2.602985E−06 |
| a_55 | −1.141143E−05 | 6.896025E−07 | 2.625430E−06 |

Table 5 for FIG. 4

| Mirrors | Reflectivity |
|---|---|
| M1 | 66.4 |
| M2 | 78.4 |
| M3 | 66.4 |
| M4 | 81.7 |
| M5 | 65.3 |
| M6 | 67.0 |
| Overall | 12.3 |

In the case of the projection optical unit 28, an intermediate image 23 is present in the meridional plane in the imaging beam path between the mirrors M3 and M4 near the reflection at the mirror M4, which allows a relatively small y-extent of this GI mirror M4.

All mirrors of the projection optical unit 28 have both an x-axis extent and a y-axis extent of less than 500 mm in each case.

Apart from the mirror M6 specifying the image-side numerical aperture, all other mirrors M1 to M5 of the projection optical unit 28 have an extent of less than 320 mm in the y-direction.

In the projection optical unit 28 according to FIG. 4, the overall mirror area including a 20 mm polishing overrun is 0.58 m².

The maximum overall polarisation rotation of linearly polarised imaging light 16 in the imaging beam path of the projection optical unit 28 between the object field 5 and the image field 11 is 6.0°.

In the projection optical unit 28, an image-side pupil plane is located in the imaging beam path between the mirrors M5 and M6.

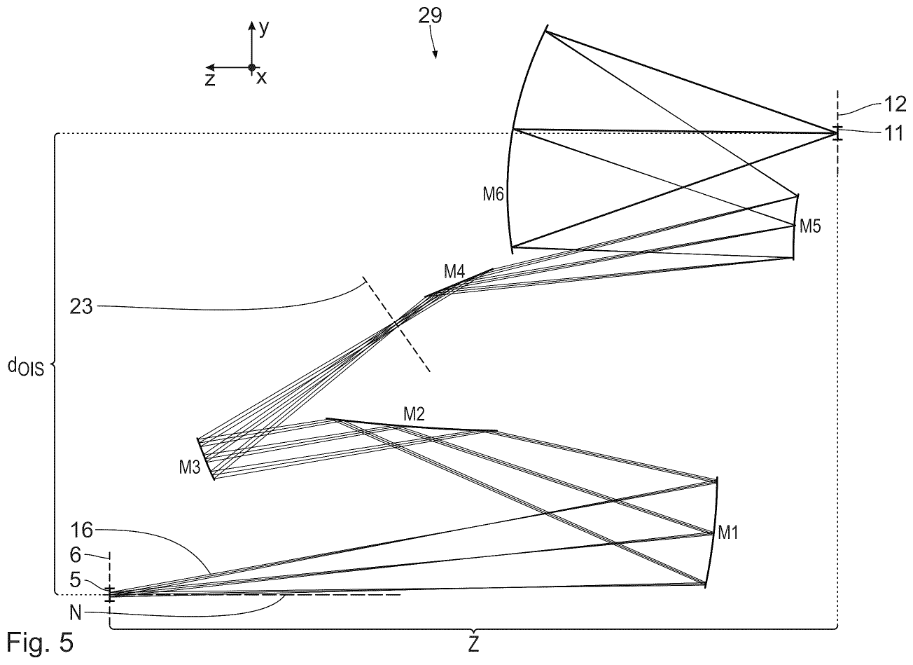

FIG. 5 shows a further embodiment of a projection optical unit or imaging optical unit 29, which can be used in the projection exposure apparatus 1 instead of the projection optical unit 10 of the embodiment according to FIG. 2. Components and functions corresponding to those which have already been explained above in conjunction with FIGS. 1 to 4, and for example in conjunction with FIGS. 2 to 4, are denoted by the same reference signs and are not discussed in detail again.

In terms of basic structure, the projection optical unit 29 according to FIG. 5 is similar to the projection optical unit 28 according to FIG. 4.

The following tables summarise parameters and the optical design of the projection optical unit 29. In terms of their structure, these tables correspond to those already explained above in conjunction with FIGS. 2 and 4.

Table 1 for FIG. 5

| Wavelength | 13.5 | nm |
|---|---|---|
| Image-side numerical aperture | 0.33 | |
| Image field size in the x- and y-directions | (26 × 2.5) mm | |
| βx | −4 (without | |
| | intermediate image) | |
| βy | 4 (with | |
| | intermediate image) | |
| Chief ray angle | 5.77° | |
| Étendue | 7.08 | mm² |
| Mean wavefront aberration RMS | 8.5 | mλ |
| Overall transmission | 12.5% | |
| Position of the entrance pupil (x) | −1404 | mm |
| Position of the entrance pupil (y) | 783 | mm |
| Object-image offset in the y-direction | 988 | mm |
| Distance between M7 and image plane | 85 | mm |
| Distance between the object plane and image | 1560 | mm |

| | |
|---|---|
| plane | |
| Tilt between object plane and image plane | 0° |
| Installation space cuboid | (492 × 1190 × 1287) mm |

Table 2a for FIG. 5

| | M1 | M2 | M3 |
|---|---|---|---|
| Maximum angle of incidence [°] | 12.8 | 79.4 | 15.3 |
| Minimum angle of incidence [°] | 11.3 | 72.8 | 10.5 |
| Extent of the reflection surface in | 415.3 | 338.7 | 262.1 |
| the x-direction [mm] | | | |
| Extent of the reflection surface in | 229.1 | 351.4 | 92.2 |
| the y-direction [mm] | | | |
| Maximum mirror diameter [mm] | 415.5 | 391.9 | 262.3 |

Table 2b for FIG. 5

| | M4 | M5 | M6 |
|---|---|---|---|
| Maximum angle of incidence [°] | 81.7 | 23.8 | 11.6 |
| Minimum angle of incidence [°] | 72.8 | 3.6 | 6.9 |
| Extent of the reflection surface | 283.8 | 316.0 | 492.3 |
| in the x-direction [mm] | | | |
| Extent of the reflection surface | 150.2 | 133.2 | 472.8 |
| in the y-direction [mm] | | | |
| Maximum mirror diameter [mm] | 287.7 | 316.0 | 493.0 |

Table 3a for FIG. 5

| | x-distance [mm] | y-distance [mm] | z-distance [mm] |
|---|---|---|---|
| Object field | 0.00 | 987.89 | 1559.65 |
| M1 | 0.00 | 856.78 | 265.35 |
| M2 | 0.00 | 626.04 | 950.23 |
| M3 | 0.00 | 693.19 | 1356.84 |
| M4 | 0.00 | 333.85 | 843.56 |
| M5 | 0.00 | 202.35 | 93.27 |
| Stop (AS) | 0.00 | 163.38 | 205.49 |
| M6 | 0.00 | −3.99 | 696.56 |
| Image field | 0.00 | 0.00 | 0.00 |

Table 3b for FIG. 5

| | Tilt about the | Tilt about the | Tilt about the |
|---|---|---|---|
| | x-axis [degrees] | y-axis [degrees] | z-axis [degrees] |
| Object field | 0.00 | 0.00 | 0.00 |
| M1 | 5.50 | 180.00 | 0.00 |
| M2 | 96.63 | 0.00 | 0.00 |
| M3 | −23.83 | 0.00 | 180.00 |
| M4 | 62.31 | 0.00 | 0.00 |
| M5 | 4.11 | 180.00 | 0.00 |
| Stop (AS) | −2.49 | 180.00 | 0.00 |
| M6 | 9.41 | 0.00 | 0.00 |
| Image field | 0.00 | 0.00 | 0.00 |

Table 4a for FIG. 5

| | M1 | M2 | M3 |
|---|---|---|---|
| RDY | −1572.839046 | −19721.928986 | −3032.216067 |
| CCY | 0.000000 | 0.000000 | 0.000000 |
| c_1/a_p | Coefficient | Coefficient | Coefficient |
| c_1 | 0.258986 | −0.035944 | 1.082406 |
| c_2 | −0.02758466 | 0.000659185 | −0.228428032 |
| c_3 | 5.152010E−03 | 2.564744E−06 | 5.236165E−03 |
| c_4 | −1.130365E−03 | −6.193054E−07 | 3.245700E−02 |
| c_5 | 2.347278E−04 | 2.015745E−06 | −1.378783E−02 |
| c_6 | −3.601116E−05 | −2.527295E−06 | 2.017319E−03 |
| c_7 | 7.931850E−06 | 7.764663E−07 | −1.910031E−05 |
| c_8 | −4.914730E−06 | 3.135302E−07 | 6.020141E−06 |
| c_9 | 2.687280E−06 | −1.901329E−07 | −6.623308E−06 |
| c_10 | −1.456123E−06 | 5.340059E−08 | 3.300028E−06 |
| c_11 | 1.016283E−06 | 5.001728E−08 | −1.693470E−06 |
| c_12 | −6.892998E−07 | 2.147418E−08 | 7.750417E−07 |
| c_13 | 3.994633E−07 | 3.982121E−09 | −2.568884E−07 |
| c_14 | −1.184982E−07 | 2.729936E−10 | 3.390916E−08 |
| a_1 | −2.564811E+00 | −5.959923E+00 | −6.295738E+00 |
| a_2 | 6.453036E+00 | −8.441088E+00 | 1.028706E+01 |
| a_3 | −8.266386E−01 | −2.146355E−01 | 2.876119E+00 |
| a_4 | −3.073779E−01 | −6.294734E−01 | 1.698262E+00 |
| a_5 | −2.580549E−01 | 3.822589E−02 | −1.238470E+00 |
| a_6 | 9.391893E−02 | 4.974993E−03 | −6.429131E−01 |
| a_7 | −1.767979E−01 | 5.292527E−02 | −9.942818E−01 |
| a_8 | 8.920617E−02 | 4.142993E−03 | −8.120304E−01 |
| a_9 | 3.656104E−02 | −6.930938E−04 | 3.530427E−01 |
| a_10 | −1.305232E−02 | −8.771947E−05 | 8.104850E−02 |
| a_11 | 5.983621E−02 | 4.068962E−03 | −7.786710E−01 |
| a_12 | 3.565597E−02 | −6.985829E−04 | 4.931961E−01 |
| a_13 | −1.204110E−02 | −7.170582E−05 | 1.587811E−01 |
| a_14 | −6.737914E−03 | 8.305438E−06 | −2.746172E−02 |
| a_15 | 1.184952E−03 | 1.787540E−06 | 7.859837E−02 |
| a_16 | 2.261669E−02 | −2.091067E−04 | 4.522749E−01 |
| a_17 | −1.288338E−02 | −4.301891E−05 | 3.186237E−01 |
| a_18 | −5.832063E−03 | −8.800877E−06 | −7.913754E−02 |
| a_19 | 1.228700E−03 | −7.985031E−07 | 3.370887E−02 |
| a_20 | 1.480576E−03 | −2.416565E−06 | −3.613970E−02 |
| a_21 | 1.180971E−04 | 1.833481E−06 | −5.564428E−02 |
| a_22 | −9.168028E−03 | 2.156372E−05 | 3.223719E−01 |
| a_23 | −5.271669E−03 | −6.316385E−06 | −1.527331E−01 |
| a_24 | 1.357569E−03 | −7.709604E−06 | −2.666796E−02 |
| a_25 | 1.216876E−03 | 7.213346E−06 | −1.389895E−02 |
| a_26 | 4.025929E−05 | 6.913733E−06 | −3.684501E−02 |
| a_27 | −2.978245E−04 | −8.247045E−06 | 1.658644E−02 |
| a_28 | −6.560152E−05 | −5.263626E−06 | 1.614370E−02 |
| a_29 | −2.758072E−03 | −5.718628E−05 | −1.354725E−01 |
| a_30 | 1.624710E−03 | 1.809190E−05 | −8.341766E−02 |
| a_31 | 9.050102E−04 | −1.089647E−05 | 9.104087E−03 |
| a_32 | −3.798005E−05 | 9.818713E−07 | −1.429416E−02 |
| a_33 | −2.334259E−04 | −5.644811E−06 | 1.034041E−02 |
| a_34 | −3.956128E−05 | −8.559366E−06 | 1.109570E−02 |
| a_35 | 3.883804E−05 | 5.773357E−06 | −2.440869E−03 |
| a_36 | 4.948774E−06 | 2.539790E−06 | −2.224062E−03 |
| a_37 | 1.272025E−03 | −8.333326E−05 | −7.778531E−02 |
| a_38 | 6.151768E−04 | 5.594617E−06 | 2.619753E−02 |
| a_39 | −7.787225E−05 | −8.278409E−06 | 1.886354E−03 |
| a_40 | −1.604528E−04 | 2.090358E−06 | 4.121230E−03 |
| a_41 | −1.644850E−05 | −1.207740E−06 | 5.372837E−03 |
| a_42 | 2.539680E−05 | 4.672985E−06 | −1.608104E−03 |
| a_43 | 2.034355E−06 | 4.452354E−06 | −1.441880E−03 |
| a_44 | −3.765641E−06 | −2.125168E−06 | 3.245103E−06 |
| a_45 | 2.705392E−06 | −5.460495E−07 | 1.349651E−04 |
| a_46 | 1.867028E−04 | 4.731643E−05 | 1.829680E−02 |
| a_47 | −1.264527E−04 | 1.752980E−05 | 9.916044E−03 |
| a_48 | −7.992742E−05 | −2.821460E−07 | −3.825210E−05 |
| a_49 | −8.888396E−06 | 5.881743E−07 | 1.605034E−03 |
| a_50 | 1.764440E−05 | −5.467822E−07 | −8.101376E−04 |
| a_51 | −4.975091E−07 | 1.120446E−06 | −5.978284E−04 |
| a_52 | 6.788503E−07 | −2.046222E−06 | −3.627069E−06 |
| a_53 | 1.305104E−06 | −1.462185E−06 | 8.051511E−05 |
| a_54 | 1.848456E−06 | 5.549710E−07 | 3.841427E−06 |
| a_55 | −1.071333E−06 | −2.379766E−07 | 2.759620E−06 |
| a_56 | −1.106678E−04 | 5.118005E−06 | 7.713607E−03 |
| a_57 | −2.721688E−05 | −6.431815E−06 | −1.391741E−03 |
| a_58 | −4.350323E−06 | −2.228977E−06 | 1.867144E−04 |
| a_59 | 6.632451E−06 | 9.190401E−07 | −2.490509E−04 |
| a_60 | −3.898762E−08 | 1.662792E−07 | −1.211134E−04 |
| a_61 | −9.120631E−09 | −1.232986E−07 | −4.498538E−07 |
| a_62 | 5.795213E−07 | −3.341869E−07 | 2.426117E−05 |
| a_63 | −2.024878E−07 | 4.263335E−07 | 2.636383E−06 |
| a_64 | −2.527164E−07 | 2.731908E−07 | 8.328761E−07 |
| a_65 | −5.832526E−07 | −4.569992E−09 | 8.321531E−07 |
| a_66 | 1.974794E−07 | 6.302297E−08 | −2.242014E−07 |
| a_67 | 1.117518E−13 | −4.318183E−13 | 5.061814E−13 |
| a_68 | 8.934626E−14 | −2.731535E−13 | −7.632092E−14 |
| a_69 | −9.285278E−13 | −3.140974E−12 | 1.298727E−12 |
| a_70 | 5.252704E−13 | 7.400134E−12 | 1.931944E−12 |
| a_71 | −1.481191E−12 | 1.348774E−11 | −3.376056E−12 |
| a_72 | −1.154464E−12 | −2.514737E−11 | 6.670905E−13 |
| a_73 | −4.261750E−12 | −1.194545E−11 | −1.456343E−12 |
| a_74 | −5.347766E−12 | −2.624573E−11 | −4.485308E−13 |
| a_75 | −5.435283E−12 | 2.924291E−11 | 1.378562E−12 |
| a_76 | −1.116143E−11 | 2.988288E−12 | −5.193921E−13 |
| a_77 | −3.542033E−12 | 1.800786E−12 | 1.943507E−12 |
| a_78 | −1.471935E−11 | 5.904225E−13 | 7.336690E−13 |

Table 4b for FIG. 5

| | M4 | M5 | M6 |
|---|---|---|---|
| RDY | 23066.867187 | 1045.168467 | −882.160839 |
| CCY | 0.000000 | 0.000000 | 0.000000 |
| c_1/a_p | Coefficient | Coefficient | Coefficient |
| c_1 | −0.618319 | −1.833896 | 0.165051 |
| c_2 | 0.328077069 | 0.155306207 | −0.002807592 |
| c_3 | −2.342025E−01 | −2.298731E−02 | −6.890220E−06 |
| c_4 | 1.393498E−01 | −1.081119E−03 | 5.630584E−05 |
| c_5 | −6.132301E−02 | 2.369462E−03 | −3.943474E−05 |
| c_6 | 1.754316E−02 | −7.828761E−04 | 2.360626E−05 |
| c_7 | −3.092526E−03 | 1.303717E−04 | −1.240929E−05 |
| c_8 | 3.425945E−04 | −1.751071E−05 | 5.590369E−06 |
| c_9 | −3.116494E−05 | 4.723900E−06 | −2.168381E−06 |
| c_10 | 6.158867E−06 | −3.453503E−07 | 7.392697E−07 |
| c_11 | −4.102954E−06 | −4.212053E−07 | −5.791994E−07 |
| c_12 | 2.883342E−06 | 2.888792E−07 | 5.165583E−07 |
| c_13 | −1.564131E−06 | −4.439872E−07 | −4.894456E−07 |
| c_14 | 6.434692E−07 | 1.155997E−07 | 3.813861E−07 |
| a_1 | 1.421335E+01 | 2.294401E+00 | 7.677410E−01 |
| a_2 | 1.986730E−01 | −1.370377E+01 | 6.172804E+00 |
| a_3 | −7.654275E−01 | −2.819924E+00 | −1.789049E−01 |
| a_4 | −3.293967E−01 | −1.077058E+00 | 4.092725E−02 |
| a_5 | 5.275930E−01 | 1.534291E+00 | −5.585124E−02 |
| a_6 | 5.228882E−01 | 3.412166E−01 | 3.780036E−03 |
| a_7 | 2.061684E−01 | 8.757462E−01 | −2.597912E−02 |
| a_8 | 3.184948E−01 | 2.037975E−01 | 2.102032E−03 |
| a_9 | −3.432753E−01 | −1.997061E−01 | 1.371954E−03 |
| a_10 | −3.677022E−01 | −1.342938E−01 | 4.328080E−06 |
| a_11 | 1.002533E−01 | −2.940720E−03 | 2.218467E−04 |
| a_12 | −1.398172E−01 | −1.878213E−01 | 6.628987E−04 |
| a_13 | −1.874453E−01 | −8.009168E−02 | −4.648575E−06 |
| a_14 | 2.374909E−01 | 3.144674E−02 | 2.450431E−05 |
| a_15 | 2.447395E−01 | 6.728538E−02 | −8.370931E−05 |
| a_16 | −4.220435E−02 | −1.158884E−01 | 1.195586E−04 |
| a_17 | −3.755194E−02 | −7.311691E−03 | −6.788899E−06 |
| a_18 | 7.808477E−02 | 3.064016E−02 | −1.599006E−06 |
| a_19 | 1.274928E−01 | 4.358393E−02 | −3.234125E−05 |
| a_20 | −1.462036E−01 | 3.435844E−04 | −4.993705E−05 |
| a_21 | −1.285777E−01 | −2.550074E−02 | 6.094581E−05 |
| a_22 | −1.966710E−02 | 4.978568E−02 | −1.108815E−06 |
| a_23 | −3.464992E−03 | 3.121269E−02 | −6.505193E−06 |
| a_24 | 2.225654E−02 | 1.447896E−02 | −3.980857E−06 |
| a_25 | −5.446500E−02 | −1.946769E−03 | −1.145070E−05 |
| a_26 | −7.076249E−02 | −1.720127E−02 | 2.244893E−05 |
| a_27 | 6.508122E−02 | −2.609865E−03 | 3.374514E−05 |
| a_28 | 4.606790E−02 | 6.214653E−03 | −3.857042E−05 |
| a_29 | 1.053412E−02 | 1.813609E−02 | −2.755841E−06 |
| a_30 | −8.810024E−03 | −1.067810E−02 | 9.008548E−07 |
| a_31 | −1.704756E−03 | −3.261422E−03 | 1.326961E−07 |
| a_32 | −1.798634E−02 | −7.754879E−03 | 2.591043E−06 |
| a_33 | 2.681180E−02 | −1.193155E−03 | 7.462431E−06 |
| a_34 | 2.569684E−02 | 4.112155E−03 | −1.316499E−05 |
| a_35 | −1.845461E−02 | 8.693325E−04 | −1.910645E−05 |
| a_36 | −1.026635E−02 | −8.986364E−04 | 2.119367E−05 |
| a_37 | 6.020963E−03 | −1.970398E−02 | 7.932468E−07 |
| a_38 | 4.867555E−03 | −3.153435E−03 | 1.107820E−06 |
| a_39 | 1.615480E−03 | −1.091939E−03 | −3.515096E−07 |
| a_40 | 4.100907E−03 | −1.744852E−04 | 2.155396E−07 |
| a_41 | 7.597546E−03 | 1.911343E−03 | −1.420791E−06 |
| a_42 | −7.548196E−03 | 4.337708E−04 | −3.730679E−06 |
| a_43 | −5.414037E−03 | −5.296658E−04 | 6.305242E−06 |
| a_44 | 3.070164E−03 | −1.320244E−04 | 9.302849E−06 |
| a_45 | 1.352514E−03 | 8.698032E−05 | −9.937162E−06 |
| a_46 | −2.374204E−03 | −1.423168E−03 | 6.806176E−07 |
| a_47 | 1.337578E−03 | 2.536338E−03 | −4.794094E−07 |
| a_48 | −8.534749E−04 | 1.113176E−04 | −5.482363E−08 |
| a_49 | 5.824871E−04 | 5.935874E−04 | −4.685278E−08 |
| a_50 | −1.420273E−03 | 1.195556E−04 | −2.586679E−08 |
| a_51 | −1.480159E−03 | −1.875432E−04 | 4.829800E−07 |
| a_52 | 1.069991E−03 | −5.695357E−05 | 1.360870E−06 |
| a_53 | 5.931885E−04 | 4.260241E−05 | −2.316847E−06 |
| a_54 | −2.899766E−04 | 1.157262E−05 | −3.445969E−06 |
| a_55 | −1.103742E−04 | −3.250850E−06 | 3.677681E−06 |
| a_56 | −6.320947E−04 | 2.774727E−03 | −3.648228E−07 |
| a_57 | −2.103667E−04 | 2.074225E−05 | −1.019315E−07 |
| a_58 | −1.543678E−04 | 9.577987E−05 | −6.173206E−09 |
| a_59 | −3.181862E−05 | 2.377927E−06 | −1.649193E−08 |
| a_60 | −1.388603E−04 | −3.477034E−05 | −1.069056E−09 |
| a_61 | 1.427996E−04 | −1.512550E−05 | −7.131849E−08 |
| a_62 | 1.052050E−04 | 8.122039E−06 | −1.057287E−07 |
| a_63 | −6.265772E−05 | 6.907446E−07 | −2.876281E−07 |
| a_64 | −2.865216E−05 | −1.524878E−06 | 5.104289E−07 |
| a_65 | 1.531862E−05 | −2.651112E−06 | 9.471970E−07 |
| a_66 | 5.953571E−06 | −5.885392E−07 | −1.091324E−06 |
| a_67 | 8.536208E−15 | 7.215436E−13 | −7.650839E−13 |
| a_68 | −1.964039E−13 | −3.475007E−13 | −3.271413E−12 |
| a_69 | 3.570166E−13 | −3.800635E−12 | −5.158039E−11 |
| a_70 | 1.209963E−13 | 1.184140E−12 | −5.683882E−11 |
| a_71 | −2.752279E−14 | 2.289836E−12 | −7.444441E−11 |
| a_72 | −4.664599E−14 | −1.178882E−12 | −8.374423E−11 |
| a_73 | −3.426503E−13 | 1.299103E−12 | −1.002586E−11 |
| a_74 | −2.725072E−13 | −1.204668E−13 | −1.212161E−10 |
| a_75 | −4.480156E−13 | −1.801958E−12 | 1.388963E−10 |
| a_76 | 6.874508E−14 | −5.038001E−13 | 3.175087E−11 |
| a_77 | −5.289906E−13 | −5.135357E−12 | −2.318256E−11 |
| a_78 | 1.023858E−12 | −5.397072E−12 | 7.237217E−12 |

Table 5 for FIG. 5

| Mirrors | Reflectivity |
|---|---|
| M1 | 66.4 |
| M2 | 79.7 |
| M3 | 66.2 |
| M4 | 81.8 |
| M5 | 65.3 |
| M6 | 67.0 |
| Overall | 12.5 |

In the projection optical unit 29 according to FIG. 5, the overall mirror area is 0.59 m², including a 20 mm polishing overrun.

The maximum overall polarisation rotation of linearly polarised imaging light 16 in the imaging beam path of the projection optical unit 29 between the object field 5 and the image field 11 is 5.97°.

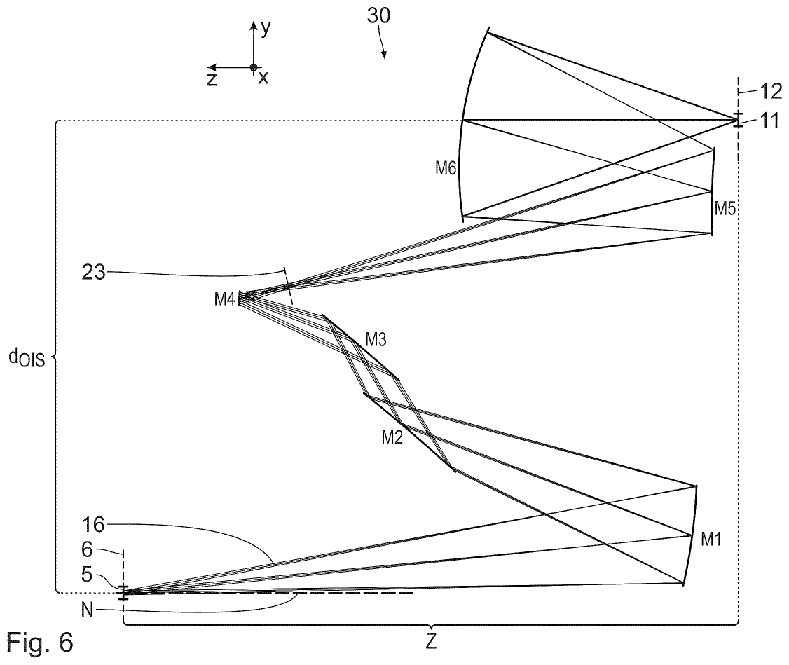

FIG. 6 shows a further embodiment of a projection optical unit or imaging optical unit 30, which can be used in the projection exposure apparatus 1 instead of the projection optical unit 10 of the embodiment according to FIG. 2. Components and functions corresponding to those which have already been explained above in conjunction with FIGS. 1 to 5, and for example in conjunction with FIGS. 2 to 5, are denoted by the same reference signs and are not discussed in detail again.

In terms of basic structure, the projection optical unit 30 according to FIG. 6 is similar to the projection optical unit 27 according to FIG. 3. A difference is that, in the projection optical unit 30, the mirrors M4, M5 and M6 each have a subtractive deflection effect for the chief ray of the central object field point so that, in the region of the mirrors M3 to M6, the beam path of the imaging light 16 is thus guided zigzag. For example, this leads to a component beam path between the mirrors M4 and M5 being located between the mirrors M1 and M6 in the projection optical unit 30.

In the projection optical unit 30, an intermediate image 23 in the yz-plane lies in the imaging beam path between the mirrors M4 and M5, near the reflection at the mirror M4. This leads to a small y-extent of the mirror M4.

The following tables summarise parameters and the optical design of the projection optical unit 30. In terms of their structure, these tables correspond to those already explained above in conjunction with FIG. 2.

Table 1 for FIG. 6

| Wavelength | 13.5 | nm |
|---|---|---|
| Image-side numerical aperture | 0.33 | |
| Image field size in the x- and y-directions | (26 × 2.5) mm | |
| Image field radius | 80 | mm |
| βx | −4 (without | |
| | intermediate image) | |
| βy | 4 (with | |
| | intermediate image) | |
| Chief ray angle | 5.75° | |
| Étendue | 7.08 | mm² |
| Mean wavefront aberration RMS | 7.1 | mλ |
| Overall transmission | 10.1% | |
| Position of the entrance pupil (x) | 6962 | mm |
| Position of the entrance pupil (y) | 1083 | mm |
| Object-image offset in the y-direction | 1168 | mm |
| Distance between M7 and image plane | 59 | mm |
| Distance between the object plane and image | 1519 | mm |

| | |
|---|---|
| plane | |
| Tilt between object plane and image plane | 0° |
| Installation space cuboid | (486 × 1364 × 1175) mm |

Table 2a for FIG. 6

| | M1 | M2 | M3 |
|---|---|---|---|
| Maximum angle of incidence [°] | 14.5 | 74.7 | 74.1 |
| Minimum angle of incidence [°] | 12.7 | 66.1 | 66.5 |
| Extent of the reflection surface in | 317.0 | 382.0 | 441.5 |
| the x-direction [mm] | | | |
| Extent of the reflection surface in | 244.7 | 293.4 | 256.9 |
| the y-direction [mm] | | | |
| Maximum mirror diameter [mm] | 317.1 | 385.5 | 442.4 |

Table 2b for FIG. 6

| | M4 | M5 | M6 |
|---|---|---|---|
| Maximum angle of incidence [°] | 21.6 | 22.8 | 12.7 |
| Minimum angle of incidence [°] | 11.5 | 5.3 | 4.0 |
| Extent of the reflection surface | 473.8 | 427.5 | 486.1 |
| in the x-direction [mm] | | | |
| Extent of the reflection surface | 37.6 | 205.1 | 466.2 |
| in the y-direction [mm] | | | |
| Maximum mirror diameter [mm] | 473.8 | 427.7 | 487.0 |

Table 3a for FIG. 6

| | x-distance [mm] | y-distance [mm] | z-distance [mm] |
|---|---|---|---|
| Object field | 0.00 | 1167.90 | 1518.79 |
| M1 | 0.00 | 1028.81 | 113.98 |
| M2 | 0.00 | 751.52 | 831.77 |
| M3 | 0.00 | 540.89 | 955.23 |
| M4 | 0.00 | 438.01 | 1232.58 |
| M5 | 0.00 | 177.43 | 64.74 |
| Stop (AS) | 0.00 | 177.43 | 64.74 |
| M6 | 0.00 | 0.00 | 681.08 |
| Image field | 0.00 | 0.00 | 0.00 |

Table 3b for FIG. 6

| | Tilt about the | Tilt about the y- | Tilt about the |
|---|---|---|---|
| | x-axis [degrees] | axis [degrees] | z-axis [degrees] |
| Object field | 0.00 | 0.00 | 0.00 |
| M1 | 7.73 | 180.00 | 0.00 |
| M2 | −49.63 | 0.00 | 0.00 |
| M3 | −50.01 | 180.00 | 0.00 |
| M4 | 3.89 | 0.00 | 0.00 |
| M5 | 1.74 | 180.00 | 0.00 |
| Stop (AS) | 1.74 | 180.00 | 0.00 |
| M6 | 8.03 | 0.00 | 0.00 |
| Image field | 0.00 | 0.00 | 0.00 |

Table 4a for FIG. 6

| | M1 | M2 | M3 |
|---|---|---|---|
| RDX | −8878.804186 | 1928.032259 | −4819.955403 |
| RDY | −1344.619812 | 4612.626893 | −4792.999475 |
| CCX | 0.000000 | 0.000000 | 0.000000 |
| CCY | 0.000000 | 0.000000 | 0.000000 |
| x**i * y**j | Coefficient | Coefficient | Coefficient |
| x**0 * y**1 | 6.755321E−04 | −1.503927E−03 | −4.275792E−03 |
| x**2 * y**0 | 0.000000E+00 | 0.000000E+00 | 0.000000E+00 |
| x**0 * y**2 | 0.000000E+00 | 0.000000E+00 | 0.000000E+00 |
| x**2 * y**1 | 4.633390E−08 | −1.037839E−07 | 1.335340E−07 |
| x**0 * y**3 | −1.956968E−09 | −3.150402E−08 | 8.485289E−08 |
| x**4 * y**0 | −6.869139E−12 | 2.432455E−11 | 3.117983E−11 |
| x**2 * y**2 | −9.220932E−12 | −2.252305E−10 | 1.193874E−10 |
| x**0 * y**4 | −5.790293E−11 | 4.775182E−11 | −1.361367E−10 |
| x**4 * y**1 | 1.302030E−15 | 2.792615E−13 | −8.981666E−14 |
| x**2 * y**3 | 8.629072E−14 | 9.038756E−15 | 6.787790E−14 |
| x**0 * y**5 | 7.002358E−14 | −9.538346E−14 | 2.830241E−13 |
| x**6 * y**0 | 1.210685E−17 | −1.539339E−16 | −1.217254E−17 |
| x**4 * y**2 | −9.309276E−17 | 8.755973E−16 | −5.630910E−16 |
| x**2 * y**4 | 1.785768E−17 | −2.079066E−16 | 9.426172E−17 |
| x**0 * y**6 | 1.563793E−17 | 1.834305E−16 | −7.146732E−16 |
| x**6 * y**1 | 2.127556E−19 | −1.832618E−18 | 2.680543E−19 |
| x**4 * y**3 | −4.200878E−19 | 6.216897E−19 | −2.139146E−19 |
| x**2 * y**5 | 3.768259E−19 | 2.405436E−19 | −1.640568E−18 |
| x**0 * y**7 | 7.062822E−18 | 6.472228E−20 | 1.233670E−18 |
| x**8 * y**0 | −7.563500E−22 | −7.931948E−21 | 6.074148E−21 |
| x**6 * y**2 | −2.150130E−21 | −1.371650E−21 | −3.782747E−21 |
| x**4 * y**4 | −6.313900E−21 | 1.837249E−21 | −1.199691E−20 |
| x**2 * y**6 | −4.732523E−21 | 2.234406E−21 | 2.092156E−21 |
| x**0 * y**8 | −4.232774E−20 | −7.036244E−21 | 2.724252E−20 |
| x**8 * y**1 | −2.894105E−24 | 2.000651E−23 | 7.622824E−24 |
| x**6 * y**3 | 3.284342E−23 | 4.703114E−23 | −2.296071E−23 |
| x**4 * y**5 | 3.548867E−23 | 4.348241E−23 | 5.354091E−23 |
| x**2 * y**7 | 1.288188E−23 | 4.737813E−23 | 2.775890E−22 |
| x**0 * y**9 | −8.162550E−22 | 8.531781E−24 | −1.889771E−22 |
| x**10 * y**0 | 8.622031E−26 | 3.457000E−25 | −1.861241E−25 |
| x**8 * y**2 | 4.647670E−25 | −2.507473E−25 | 3.181091E−25 |
| x**6 * y**4 | 8.326098E−25 | −9.020139E−26 | 9.045424E−25 |
| x**4 * y**6 | 9.646368E−25 | 3.756972E−25 | 9.406528E−25 |
| x**2 * y**8 | 1.747877E−25 | −2.051326E−25 | −2.487961E−24 |
| x**0 * y**10 | 2.900051E−24 | 3.987397E−25 | −2.600989E−24 |
| x**10 * y**1 | −1.853381E−28 | 7.770508E−28 | −8.126337E−28 |
| x**8 * y**3 | −1.331197E−27 | −5.175642E−27 | 2.862299E−27 |
| x**6 * y**5 | −4.183442E−27 | −6.173087E−27 | 3.371516E−27 |
| x**4 * y**7 | −2.022223E−27 | −7.459537E−27 | −1.090270E−26 |
| x**2 * y**9 | −1.553438E−27 | −6.722230E−27 | −1.609708E−26 |
| x**0 * y**11 | 7.023693E−26 | −1.038239E−27 | 2.734294E−26 |
| x**12 * y**0 | −4.866839E−30 | −7.700255E−30 | 2.442452E−30 |
| x**10 * y**2 | −3.670124E−29 | 1.346811E−29 | −1.109889E−29 |
| x**8 * y**4 | −6.952832E−29 | 1.432701E−29 | −4.082682E−29 |
| x**6 * y**6 | −1.071614E−28 | −2.217263E−29 | −7.759127E−29 |
| x**4 * y**8 | −6.017247E−29 | −2.810233E−29 | 1.167534E−29 |
| x**2 * y**10 | −4.492055E−30 | 4.244399E−29 | 2.447445E−28 |
| x**0 * y**12 | −1.005272E−28 | −6.948466E−30 | 6.175372E−29 |
| x**12 * y**1 | 9.746783E−33 | −3.478876E−32 | 1.276738E−32 |
| x**10 * y**3 | −5.791193E−33 | 2.338576E−31 | −1.565742E−31 |
| x**8 * y**5 | 1.266499E−31 | 3.718958E−31 | −3.894943E−31 |
| x**6 * y**7 | 1.842162E−31 | 4.652074E−31 | −2.497166E−31 |
| x**4 * y**9 | −2.149672E−32 | 5.522054E−31 | 5.478145E−31 |
| x**2 * y**11 | 1.689734E−31 | 2.334207E−31 | 1.492986E−31 |
| x**0 * y**13 | −2.979899E−30 | 5.411952E−34 | −1.414187E−30 |
| x**14 * y**0 | 1.378519E−34 | 6.572890E−35 | −3.509638E−36 |
| x**12 * y**2 | 1.304833E−33 | −2.128121E−34 | 7.958393E−35 |
| x**10 * y**4 | 2.845192E−33 | −1.728458E−34 | 3.728719E−34 |
| x**8 * y**6 | 4.863430E−33 | 2.805566E−34 | 1.028049E−33 |
| x**6 * y**8 | 5.218156E−33 | 1.857922E−33 | 1.581462E−33 |
| x**4 * y**10 | −3.270749E−34 | −1.513179E−34 | −4.011190E−33 |
| x**2 * y**12 | 1.612384E−34 | −2.147286E−33 | −8.240175E−33 |
| x**0 * y**14 | 8.570151E−34 | 6.415766E−35 | 2.581023E−33 |
| x**14 * y**1 | −1.570036E−37 | 4.284314E−37 | −3.371489E−38 |
| x**12 * y**3 | 1.266740E−36 | −3.831590E−36 | 2.668007E−36 |
| x**10 * y**5 | −7.178326E−37 | −7.242221E−36 | 9.333838E−36 |
| x**8 * y**7 | −2.463190E−36 | −1.099907E−35 | 1.650765E−35 |
| x**6 * y**9 | −1.180676E−36 | −1.259443E−35 | 5.689605E−36 |
| x**4 * y**11 | 2.120684E−36 | −1.154507E−35 | −3.995906E−36 |
| x**2 * y**13 | −5.830659E−36 | −1.427808E−37 | 1.052557E−35 |
| x**0 * y**15 | 5.153277E−35 | 8.113144E−37 | 1.829372E−35 |
| x**16 * y**0 | −1.577001E−39 | 1.105591E−40 | −1.457078E−40 |
| x**14 * y**2 | −1.731508E−38 | −1.894505E−42 | 1.440137E−39 |
| x**12 * y**4 | −4.045798E−38 | −6.944450E−39 | 8.956041E−39 |
| x**10 * y**6 | −8.699939E−38 | −6.886099E−39 | 3.041416E−38 |
| x**8 * y**8 | −9.987787E−38 | −3.010665E−38 | 2.339875E−38 |
| x**6 * y**10 | −5.378771E−38 | −2.826887E−38 | 5.131637E−38 |
| x**4 * y**12 | 8.305891E−38 | 2.458104E−38 | 7.797444E−38 |
| x**2 * y**14 | −1.810254E−38 | 2.036092E−38 | 5.368275E−38 |
| x**0 * y**16 | 1.647533E−38 | −2.970695E−39 | −5.889361E−38 |

Table 4b for FIG. 6

| | M4 | M5 | M6 |
|---|---|---|---|
| RDX | −4690.832237 | 20948.047014 | −1275.281464 |
| RDY | −2214.970033 | 1910.971537 | −861.803855 |
| CCX | 0.000000 | 0.000000 | 0.000000 |
| CCY | 0.000000 | 0.000000 | 0.000000 |
| x**i * y**j | Coefficient | Coefficient | Coefficient |
| x**0 * y**1 | 3.681296E−03 | 8.322362E−04 | −7.858516E−04 |
| x**2 * y**0 | 0.000000E+00 | 0.000000E+00 | 0.000000E+00 |
| x**0 * y**2 | 0.000000E+00 | 0.000000E+00 | 0.000000E+00 |
| x**2 * y**1 | −1.911232E−07 | 8.848585E−08 | 4.113575E−09 |
| x**0 * y**3 | −6.373185E−07 | 9.587036E−08 | 2.793794E−08 |
| x**4 * y**0 | 2.471227E−11 | 8.591456E−11 | −2.868168E−11 |
| x**2 * y**2 | 5.753102E−10 | 6.869834E−10 | −9.743570E−11 |
| x**0 * y**4 | 5.546172E−09 | 9.434248E−10 | −3.354404E−11 |
| x**4 * y**1 | −1.282803E−13 | 1.323884E−13 | 4.354945E−15 |
| x**2 * y**3 | −4.159856E−12 | 6.208640E−13 | 3.427323E−14 |
| x**0 * y**5 | −3.910704E−11 | 4.372061E−13 | 3.595439E−14 |
| x**6 * y**0 | 1.177704E−17 | 8.639694E−17 | −2.937909E−17 |
| x**4 * y**2 | 1.339831E−15 | 1.119877E−15 | −1.470920E−16 |
| x**2 * y**4 | 3.670002E−14 | 3.203387E−15 | −1.807253E−16 |
| x**0 * y**6 | 7.348347E−13 | 2.099135E−15 | −5.492995E−17 |
| x**6 * y**1 | −1.526405E−19 | 2.490205E−19 | −2.612095E−21 |
| x**4 * y**3 | −6.714613E−18 | 1.909169E−18 | 1.853693E−20 |
| x**2 * y**5 | 5.827315E−16 | 5.433263E−18 | 2.923055E−20 |
| x**0 * y**7 | −8.176912E−14 | −3.672616E−18 | 1.486550E−19 |
| x**8 * y**0 | −5.228833E−22 | 3.038663E−22 | −9.964874E−23 |
| x**6 * y**2 | 1.018704E−20 | 2.892289E−21 | −2.946672E−22 |
| x**4 * y**4 | 5.530882E−19 | 1.250630E−20 | −4.755670E−22 |
| x**2 * y**6 | −1.036558E−16 | −1.742366E−21 | −2.230509E−22 |
| x**0 * y**8 | 1.466585E−15 | −5.246570E−20 | 1.332154E−22 |
| x**8 * y**1 | −1.721228E−24 | −6.222869E−25 | 1.940187E−25 |
| x**6 * y**3 | −1.428584E−23 | −1.468239E−23 | 1.191794E−24 |
| x**4 * y**5 | −5.629423E−20 | −1.947770E−22 | 3.134084E−24 |
| x**2 * y**7 | −4.494432E−18 | −6.402330E−22 | 2.715455E−24 |
| x**0 * y**9 | 7.275134E−16 | 4.255464E−22 | −3.153971E−24 |
| x**10 * y**0 | 1.233542E−26 | −7.103954E−27 | 2.518615E−27 |
| x**8 * y**2 | −1.396315E−25 | −5.044798E−26 | 5.182849E−27 |
| x**6 * y**4 | −3.083912E−23 | −3.205006E−25 | 6.148801E−27 |
| x**4 * y**6 | 2.433246E−21 | −3.634020E−25 | 5.440836E−28 |
| x**2 * y**8 | 6.465728E−19 | 5.565912E−24 | −8.166699E−27 |
| x**0 * y**10 | −3.134968E−17 | 6.680615E−24 | −2.823094E−27 |
| x**10 * y**1 | 1.688666E−28 | −3.915857E−31 | −1.082036E−30 |
| x**8 * y**3 | 1.412407E−27 | 3.294202E−28 | −2.028225E−29 |
| x**6 * y**5 | 4.796608E−25 | 8.052133E−27 | −9.691551E−29 |
| x**4 * y**7 | 5.258580E−22 | 4.021668E−26 | −1.251334E−28 |
| x**2 * y**9 | 7.442061E−21 | 8.495551E−26 | −7.568095E−29 |
| x**0 * y**11 | −3.561256E−18 | −6.702106E−26 | 7.777386E−29 |
| x**12 * y**0 | −1.108069E−31 | 1.426219E−31 | −4.835577E−32 |
| x**10 * y**2 | 2.582085E−30 | 1.574202E−30 | −1.361942E−31 |
| x**8 * y**4 | 1.443414E−27 | 1.366033E−29 | −1.843267E−31 |
| x**6 * y**6 | 2.070875E−26 | 4.778249E−29 | −9.833370E−32 |
| x**4 * y**8 | −9.306876E−24 | −2.473533E−29 | 1.235813E−31 |
| x**2 * y**10 | −2.211772E−21 | −9.481366E−28 | 2.769412E−31 |
| x**0 * y**12 | 1.625976E−19 | −5.767185E−28 | −8.390897E−33 |
| x**12 * y**1 | −2.633752E−33 | 2.185253E−34 | −9.052680E−36 |
| x**10 * y**3 | 6.764940E−32 | −1.452181E−33 | 1.533288E−34 |
| x**8 * y**5 | 4.832866E−29 | −1.276619E−31 | 1.357311E−33 |
| x**6 * y**7 | −1.260869E−26 | −1.096127E−30 | 2.748845E−33 |
| x**4 * y**9 | −1.824712E−24 | −3.345951E−30 | 2.327308E−33 |
| x**2 * y**11 | 3.580354E−23 | −5.756826E−30 | 1.143700E−33 |
| x**0 * y**13 | 8.270553E−21 | 4.637998E−30 | −9.332143E−34 |
| x**14 * y**0 | −4.859567E−37 | −1.470222E−36 | 4.859827E−37 |
| x**12 * y**2 | −6.789123E−36 | −2.367109E−35 | 1.819611E−36 |
| x**10 * y**4 | −3.201206E−32 | −2.538298E−34 | 2.562707E−36 |
| x**8 * y**6 | −6.564906E−31 | −1.387381E−33 | 1.531613E−36 |
| x**6 * y**8 | −4.341880E−28 | −2.756793E−33 | −1.407108E−36 |
| x**4 * y**10 | −1.241171E−26 | 8.853461E−33 | −4.543747E−36 |
| x**2 * y**12 | 5.255062E−24 | 7.792542E−32 | −4.697056E−36 |
| x**0 * y**14 | −3.507224E−22 | 2.614329E−32 | 6.146747E−37 |
| x**14 * y**1 | 9.531765E−39 | −1.961212E−39 | 1.079423E−40 |
| x**12 * y**3 | −5.507650E−36 | −9.358930E−39 | −2.616141E−40 |
| x**10 * y**5 | −1.990549E−33 | 7.270695E−37 | −6.886650E−39 |
| x**8 * y**7 | 7.517617E−32 | 9.731074E−36 | −2.011952E−38 |
| x**6 * y**9 | 5.006857E−31 | 4.725334E−35 | −2.491546E−38 |
| x**4 * y**11 | 2.168804E−27 | 1.015590E−34 | −1.606685E−38 |
| x**2 * y**13 | −1.051339E−25 | 1.491113E−34 | −6.730002E−39 |
| x**0 * y**15 | −6.989774E−24 | −1.329837E−34 | 4.563694E−39 |
| x**16 * y**0 | 1.056111E−41 | 6.138681E−42 | −2.006615E−42 |
| x**14 * y**2 | −9.342375E−40 | 1.438731E−40 | −9.877552E−42 |
| x**12 * y**4 | −6.750185E−38 | 1.873722E−39 | −1.548845E−41 |
| x**10 * y**6 | −4.178881E−35 | 1.320669E−38 | −6.840092E−42 |
| x**8 * y**8 | 5.102820E−33 | 5.282716E−38 | 9.443857E−42 |
| x**6 * y**10 | −4.875441E−32 | 4.193142E−38 | 3.334984E−41 |
| x**4 * y**12 | 4.398760E−29 | −4.895399E−37 | 4.324575E−41 |
| x**2 * y**14 | −6.003840E−27 | −2.433145E−36 | 2.967019E−41 |
| x**0 * y**16 | 2.594303E−25 | −5.760208E−37 | −4.277436E−42 |

Table 5 for FIG. 6

| Mirrors | Reflectivity |
|---|---|
| M1 | 66.1 |
| M2 | 73.6 |
| M3 | 73.5 |
| M4 | 64.8 |
| M5 | 65.5 |
| M6 | 67.0 |
| Overall | 10.1 |

In the projection optical unit 30 according to FIG. 6, the overall mirror area including a 20 mm polishing overrun is 0.64 m².

The maximum overall polarisation rotation of linearly polarised imaging light 16 in the imaging beam path of the projection optical unit 30 between the object field 5 and the image field 11 is 5.38°.

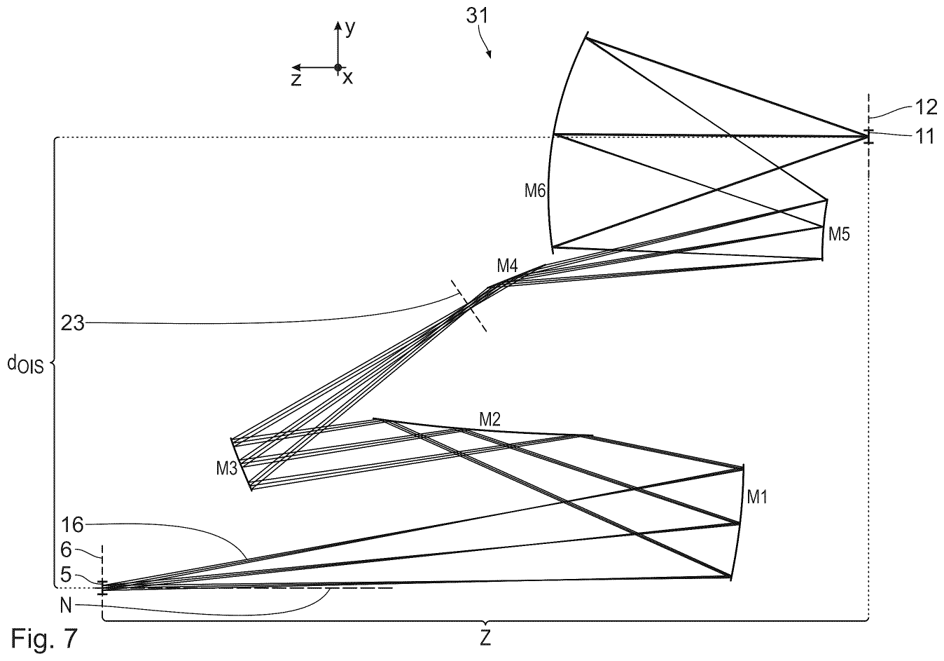

FIG. 7 shows a further embodiment of a projection optical unit or imaging optical unit 31, which can be used in the projection exposure apparatus 1 instead of the projection optical unit 10 of the embodiment according to FIG. 2. Components and functions corresponding to those which have already been explained above in conjunction with FIGS. 1 to 6, and for example in conjunction with FIGS. 2 to 6, are denoted by the same reference signs and are not discussed in detail again.

In terms of basic structure, the projection optical unit 31 according to FIG. 7 is similar to the projection optical units 28 and 29 according to FIGS. 4 and 5.

The following tables summarise parameters and the optical design of the projection optical unit 31. In terms of their structure, these tables correspond to those already explained above in conjunction with FIG. 2. Table 4 (Tables 4a/4b) describes the free-form surfaces of the mirrors M1 to M6 on the basis of the aforementioned Forbes free-form surface equation (2).

Table 1 for FIG. 7

| Wavelength | 13.5 | nm |
|---|---|---|
| Image-side numerical aperture | 0.33 | |
| Image field size in the x- and y- | (26 × 2.5) mm | |
| directions | | |
| βx | −4 (without | |
| | intermediate image) | |
| βy | 4 (with | |
| | intermediate image) | |
| Chief ray angle | 5.75° | |
| Étendue | 7.08 | mm² |
| Mean wavefront aberration RMS | 8.9 | mλ |
| Overall transmission | 12.6% | |
| Position of the entrance pupil (x) | −2317 | mm |
| Position of the entrance pupil (y) | 823 | mm |
| Object-image offset in the y-direction | 906 | mm |
| Distance between M7 and image plane | 83 | mm |
| Distance between the object plane and | 1539 | mm |

| | |
|---|---|
| image plane | |
| Tilt between object plane and image | 0° |
| plane | |
| Installation space cuboid | (450 × 1088 × 1197) mm |

Table 2a for FIG. 7

| | M1 | M2 | M3 |
|---|---|---|---|
| Maximum angle of incidence [°] | 13.0 | 80.0 | 15.5 |
| Minimum angle of incidence [°] | 10.9 | 73.2 | 10.5 |
| Extent of the reflection surface in | 374.7 | 340.7 | 286.6 |
| the x-direction [mm] | | | |
| Extent of the reflection surface in | 225.4 | 423.5 | 108.5 |
| the y-direction [mm] | | | |
| Maximum mirror diameter [mm] | 374.8 | 448.0 | 286.8 |

Table 2b for FIG. 7

| | M4 | M5 | M6 |
|---|---|---|---|
| Maximum angle of incidence [°] | 82.0 | 24.1 | 12.0 |
| Minimum angle of incidence [°] | 72.3 | 3.2 | 7.2 |
| Extent of the reflection surface in | 293.9 | 306.5 | 450.2 |
| the x-direction [mm] | | | |
| Extent of the reflection surface in | 123.1 | 119.3 | 431.0 |
| the y-direction [mm] | | | |
| Maximum mirror diameter [mm] | 297.3 | 306.5 | 450.7 |

Table 3a for FIG. 7

| | x-distance [mm] | y-distance [mm] | z-distance [mm] |
|---|---|---|---|
| Object field | 0.00 | 905.53 | 1538.80 |
| M1 | 0.00 | 774.35 | 258.11 |
| M2 | 0.00 | 585.29 | 824.15 |
| M3 | 0.00 | 651.81 | 1263.80 |
| M4 | 0.00 | 294.36 | 742.35 |
| M5 | 0.00 | 188.56 | 91.05 |
| Stop (AS) | 0.00 | 156.81 | 177.31 |
| M6 | 0.00 | −5.66 | 632.69 |
| Image field | 0.00 | 0.00 | 0.00 |

Table 3b for FIG. 7

| | Tilt about the x- | Tilt about the | Tilt about the |
|---|---|---|---|
| | axis [degrees] | y-axis [degrees] | z-axis [degrees] |
| Object field | 0.00 | 0.00 | 0.00 |
| M1 | 5.32 | 180.00 | 0.00 |
| M2 | 97.78 | 0.00 | 0.00 |
| M3 | −22.29 | 0.00 | 180.00 |
| M4 | 62.54 | 0.00 | 0.00 |
| M5 | 4.35 | 180.00 | 0.00 |
| Stop (AS) | −7.44 | 180.00 | 0.00 |
| M6 | 9.82 | 0.00 | 0.00 |
| Image field | 0.00 | 0.00 | 0.00 |

Table 4a for FIG. 7

| | M1 | M2 | M3 |
|---|---|---|---|
| RDY | −1569.250422 | −23983.284087 | −2408.651952 |
| CCY | 0.000000 | 0.000000 | 0.000000 |
| c_1/a_p | Coefficient | Coefficient | Coefficient |
| c_1 | 0.655151 | −0.019939 | 2.099374 |
| c_2 | −0.133734081 | 0.000330411 | −0.76936471 |
| c_3 | 4.154776E−02 | −2.149656E−06 | 2.478333E−01 |
| c_4 | −1.276484E−02 | 2.522461E−06 | −3.359998E−02 |
| c_5 | 4.033912E−03 | −1.418337E−06 | −6.975097E−03 |
| c_6 | −1.308097E−03 | 9.379501E−07 | 3.769309E−03 |
| c_7 | 4.102410E−04 | 9.245736E−08 | −5.562314E−04 |
| c_8 | −1.106613E−04 | 2.487443E−07 | 2.629886E−05 |
| c_9 | 2.832060E−05 | 1.350528E−07 | −1.116544E−06 |
| c_10 | −8.336357E−06 | 1.711168E−09 | 3.153340E−08 |
| c_11 | 3.514479E−06 | 2.822714E−09 | −1.097367E−08 |
| c_12 | −1.831931E−06 | 1.715900E−10 | −3.595830E−08 |
| c_13 | 8.071917E−07 | 7.806569E−12 | −1.482517E−08 |
| c_14 | −2.198922E−07 | 1.598127E−13 | −1.829131E−09 |
| a_1 | −2.213337E+00 | −7.495506E+00 | −3.013150E+00 |
| a_2 | 7.309341E+00 | −6.237966E+00 | 8.289606E+00 |
| a_3 | −1.503666E+00 | −8.073424E−02 | 1.535284E+00 |
| a_4 | −7.544668E−01 | −3.213671E−01 | 9.432788E−01 |
| a_5 | −6.894646E−01 | 2.016254E−02 | −2.426146E+00 |
| a_6 | 3.266912E−01 | 2.042111E−03 | −2.803020E−01 |
| a_7 | −4.807036E−01 | 1.939123E−02 | −1.850234E+00 |
| a_8 | 3.122348E−01 | 1.195529E−03 | −4.289164E−01 |
| a_9 | 1.794283E−01 | −3.027337E−04 | 1.098308E+00 |
| a_10 | −9.827957E−02 | −4.488682E−05 | −7.520225E−02 |
| a_11 | 2.031336E−01 | 3.679345E−04 | −5.118635E−01 |
| a_12 | 1.800433E−01 | −2.721543E−04 | 1.274492E+00 |
| a_13 | −8.389872E−02 | −4.030440E−05 | 6.659546E−03 |
| a_14 | −5.347381E−02 | 1.125945E−05 | −3.520022E−01 |
| a_15 | 3.404580E−02 | 8.084818E−07 | 1.476516E−01 |
| a_16 | 1.229434E−01 | 9.053275E−05 | 9.993713E−01 |
| a_17 | −7.575145E−02 | −2.644422E−05 | 1.626821E−01 |
| a_18 | −4.539675E−02 | 6.444923E−06 | −3.799222E−01 |
| a_19 | 2.713577E−02 | −1.878022E−07 | 9.878175E−02 |
| a_20 | 1.585966E−02 | −5.004769E−07 | 5.341082E−02 |
| a_21 | −1.229145E−02 | −2.218939E−06 | −8.469952E−02 |
| a_22 | −4.357161E−02 | 3.320617E−05 | 2.380608E−01 |
| a_23 | −4.382022E−02 | 5.712609E−06 | −4.652435E−01 |
| a_24 | 1.922003E−02 | 3.062813E−06 | 2.980992E−02 |
| a_25 | 1.160933E−02 | −2.250680E−06 | 6.828986E−02 |
| a_26 | −9.244655E−03 | −1.594885E−06 | −6.325040E−02 |
| a_27 | −4.686146E−03 | 4.141549E−07 | 6.746103E−03 |
| a_28 | 3.974218E−03 | 6.246187E−07 | 2.560090E−02 |
| a_29 | −2.971284E−02 | −6.949296E−06 | −3.529248E−01 |
| a_30 | 1.401903E−02 | 2.141669E−06 | −3.999353E−02 |
| a_31 | 8.383522E−03 | −3.058795E−06 | 8.441466E−02 |
| a_32 | −5.644870E−03 | −2.633592E−06 | −3.546640E−02 |
| a_33 | −2.792827E−03 | 9.807673E−07 | −1.239579E−04 |
| a_34 | 2.835357E−03 | −3.752950E−07 | 1.942248E−02 |
| a_35 | 1.428148E−03 | 6.625658E−07 | −4.461536E−03 |
| a_36 | −1.011492E−03 | −2.101918E−07 | −3.920066E−03 |
| a_37 | 6.385733E−03 | −3.847309E−06 | −6.542384E−02 |
| a_38 | 7.724562E−03 | −2.972746E−06 | 1.025780E−01 |
| a_39 | −2.950862E−03 | −2.381114E−06 | −1.147829E−02 |
| a_40 | −1.376030E−03 | 1.421634E−06 | −6.462951E−03 |
| a_41 | 1.529506E−03 | 7.689109E−07 | 1.171731E−02 |
| a_42 | 6.959253E−04 | −7.075006E−07 | −2.579007E−03 |
| a_43 | −6.765141E−04 | 7.034885E−08 | −2.896716E−03 |
| a_44 | −4.165075E−04 | −6.351183E−08 | 6.608987E−04 |
| a_45 | 1.899585E−04 | 1.413132E−07 | 2.270207E−04 |
| a_46 | 5.554470E−03 | 1.655332E−06 | 7.147577E−02 |
| a_47 | −1.575843E−03 | −1.951812E−06 | 3.996400E−03 |
| a_48 | −7.493023E−04 | 8.271621E−07 | −9.527569E−03 |
| a_49 | 6.324947E−04 | −3.378900E−07 | 5.292616E−03 |
| a_50 | 2.084645E−04 | 5.801600E−07 | −8.605693E−04 |
| a_51 | −3.128428E−04 | −2.521368E−07 | −1.657490E−03 |
| a_52 | −1.744940E−04 | 2.900542E−07 | 3.955657E−04 |
| a_53 | 1.168108E−04 | 1.933299E−07 | 1.522401E−04 |
| a_54 | 9.651109E−05 | −1.006620E−07 | −2.938556E−05 |
| a_55 | −2.255461E−05 | 4.508300E−08 | −3.592510E−06 |
| a_56 | −4.380817E−04 | −4.793326E−07 | 7.898951E−03 |
| a_57 | −7.422207E−04 | 1.367283E−06 | −1.018742E−02 |
| a_58 | 2.242465E−04 | 7.370470E−07 | 1.566138E−03 |
| a_59 | 1.986605E−05 | 1.512246E−08 | 5.730028E−05 |
| a_60 | −9.143499E−05 | 5.624247E−07 | −6.837961E−04 |
| a_61 | −4.245357E−05 | −2.981529E−07 | 1.616078E−04 |
| a_62 | 4.484279E−05 | −1.379155E−08 | 6.854767E−05 |
| a_63 | 3.041316E−05 | −7.934568E−08 | −1.409475E−05 |
| a_64 | −1.156311E−05 | −2.166535E−08 | −1.863705E−06 |
| a_65 | −1.711485E−05 | −4.568968E−08 | 1.096892E−06 |
| a_66 | 1.510491E−06 | −4.594285E−08 | −9.159141E−08 |
| a_67 | −6.147135E−04 | 3.994298E−07 | −6.076502E−03 |
| a_68 | 9.031953E−05 | 6.394633E−07 | 2.513569E−04 |
| a_69 | −1.061411E−05 | −2.136370E−07 | 1.966610E−04 |
| a_70 | −1.387823E−05 | −1.304746E−07 | −1.652475E−04 |
| a_71 | −4.350862E−06 | 3.908417E−08 | 3.554345E−05 |
| a_72 | 7.945716E−06 | −2.547514E−08 | 1.627843E−05 |
| a_73 | 4.183715E−06 | 7.971643E−08 | −3.375849E−06 |
| a_74 | −3.118335E−06 | 1.004178E−07 | −4.298187E−07 |
| a_75 | −3.052844E−06 | −8.467596E−08 | 3.203937E−07 |
| a_76 | 2.810558E−07 | −5.081537E−08 | −5.644636E−08 |
| a_77 | 1.812269E−06 | 2.117512E−08 | 6.162186E−09 |
| a_78 | −2.451154E−07 | 5.929002E−09 | 1.944636E−08 |

Table 4b for FIG. 7

| | M4 | M5 | M6 |
|---|---|---|---|
| RDY | −3213.926474 | 941.354023 | −811.431113 |
| CCY | 0.000000 | 0.000000 | 0.000000 |
| c_1/a_p | Coefficient | Coefficient | Coefficient |
| c_1 | −1.525627 | −1.630936 | 0.169282 |
| c_2 | 4.980035884 | −0.275597659 | −0.002705623 |
| c_3 | −4.661606E+00 | 4.250719E−01 | −2.022404E−04 |
| c_4 | 2.181675E+00 | −2.820909E−01 | 1.998787E−04 |
| c_5 | −5.324522E−01 | 1.241409E−01 | −1.331262E−04 |
| c_6 | 3.668513E−02 | −3.564835E−02 | 7.844468E−05 |
| c_7 | 1.067404E−02 | 6.158926E−03 | −4.153919E−05 |
| c_8 | −2.345109E−03 | −5.218581E−04 | 1.873461E−05 |
| c_9 | 1.721385E−04 | 1.404033E−05 | −6.966161E−06 |
| c_10 | −6.551650E−06 | 1.894610E−06 | 1.718651E−06 |
| c_11 | −2.805859E−09 | −1.123988E−07 | −5.122962E−07 |
| c_12 | 1.215791E−08 | −1.545734E−07 | 7.795118E−08 |
| c_13 | 4.567472E−08 | −1.141592E−07 | −4.478178E−08 |
| c_14 | 9.577642E−09 | −3.958790E−08 | 4.351929E−07 |
| a_1 | 9.251342E+00 | 1.910046E+00 | 6.736674E−01 |
| a_2 | 6.950382E+00 | −1.351079E+01 | 6.511270E+00 |
| a_3 | 3.138927E+00 | −3.224237E+00 | −2.527425E−01 |
| a_4 | 7.249785E+00 | −2.041544E+00 | 2.237632E−02 |
| a_5 | −1.089044E+00 | 1.595064E+00 | −6.735508E−02 |
| a_6 | 4.404682E+00 | 1.116520E+00 | 5.890161E−03 |
| a_7 | −7.162344E+00 | 1.355330E+00 | −3.503379E−02 |
| a_8 | −1.030859E−01 | 1.470691E+00 | 3.648644E−03 |
| a_9 | −5.121983E+00 | 2.446998E−01 | 1.447287E−03 |
| a_10 | −7.113998E+00 | −1.992809E−01 | 2.399082E−04 |
| a_11 | −6.132036E+00 | 1.348532E+00 | 9.285145E−04 |
| a_12 | −1.340581E−01 | −1.156856E−01 | 7.809310E−04 |
| a_13 | −4.226075E+00 | −4.080027E−01 | 1.401481E−04 |
| a_14 | 5.373874E+00 | −4.685753E−01 | 2.333718E−04 |
| a_15 | 4.694026E+00 | −2.029485E−01 | −3.144938E−04 |
| a_16 | 4.541445E+00 | −2.899001E−01 | 1.472110E−04 |
| a_17 | −7.398815E−02 | −7.636759E−01 | 6.539615E−05 |
| a_18 | 2.773852E+00 | −2.048698E−01 | 1.012391E−04 |
| a_19 | 3.297996E+00 | −5.758488E−02 | −1.721700E−04 |
| a_20 | −2.646181E+00 | 3.265805E−01 | −2.054906E−04 |
| a_21 | −1.637618E+00 | 1.962891E−01 | 2.173057E−04 |
| a_22 | 2.873205E+00 | −6.486268E−01 | 2.585067E−05 |
| a_23 | −2.460633E−02 | 4.630520E−03 | 4.176237E−05 |
| a_24 | 1.498323E+00 | 1.208455E−01 | −6.409204E−05 |
| a_25 | −1.666183E+00 | 1.745772E−01 | −8.395462E−05 |
| a_26 | −1.220155E+00 | 1.193617E−01 | 1.119459E−04 |
| a_27 | 6.596458E−01 | −1.448818E−01 | 1.325405E−04 |
| a_28 | 2.565485E−01 | −8.495126E−02 | −1.338078E−04 |
| a_29 | −1.534164E+00 | 2.192666E−02 | 1.433628E−05 |
| a_30 | −5.505286E−02 | 2.466802E−01 | −2.907517E−05 |
| a_31 | −6.637966E−01 | 4.936803E−02 | −2.591986E−05 |
| a_32 | −6.905800E−01 | 2.962465E−02 | 3.526859E−05 |
| a_33 | 4.513298E−01 | −8.158982E−02 | 4.909660E−05 |
| a_34 | 2.028339E−01 | −5.660149E−02 | −6.416018E−05 |
| a_35 | −5.014385E−02 | 4.166169E−02 | −7.557275E−05 |
| a_36 | 7.910566E−03 | 2.060321E−02 | 7.439443E−05 |
| a_37 | −6.705993E−01 | 1.632753E−01 | −1.411443E−05 |
| a_38 | 4.220007E−02 | 3.359432E−03 | −1.199849E−05 |
| a_39 | −2.382491E−01 | −2.566716E−02 | 1.060749E−05 |
| a_40 | 2.282871E−01 | −2.817430E−02 | 1.214670E−05 |
| a_41 | 1.293947E−01 | −2.437937E−02 | −1.663094E−05 |
| a_42 | −4.233444E−02 | 2.354730E−02 | −2.502191E−05 |
| a_43 | 9.907253E−04 | 1.373288E−02 | 3.298690E−05 |
| a_44 | −1.131507E−02 | −7.070503E−03 | 3.837932E−05 |
| a_45 | −8.032817E−03 | −2.663126E−03 | −3.597153E−05 |
| a_46 | 2.312764E−01 | 2.318417E−02 | −6.483496E−06 |
| a_47 | 1.874626E−02 | −4.109208E−02 | 6.202565E−06 |
| a_48 | 6.615101E−02 | −3.371675E−03 | 3.492377E−06 |
| a_49 | 5.752480E−02 | −4.036059E−03 | −2.883822E−06 |
| a_50 | −2.645566E−02 | 8.529758E−03 | −4.550441E−06 |
| a_51 | −4.016382E−03 | 6.215319E−03 | 7.204079E−06 |
| a_52 | −4.494012E−03 | −3.802576E−03 | 1.107179E−05 |
| a_53 | −4.598515E−03 | −1.657447E−03 | −1.424854E−05 |
| a_54 | 2.488925E−03 | 5.693155E−04 | −1.619491E−05 |
| a_55 | 9.329605E−04 | 1.708862E−04 | 1.453095E−05 |
| a_56 | 5.689363E−02 | −1.648647E−02 | 4.190112E−06 |
| a_57 | −5.392050E−03 | −1.769200E−03 | 2.415026E−06 |
| a_58 | 1.314102E−02 | 2.559158E−03 | −4.440430E−07 |
| a_59 | −9.913870E−03 | 1.310822E−03 | −3.993940E−07 |
| a_60 | −3.279202E−03 | 1.678149E−03 | 9.391850E−07 |
| a_61 | −5.783463E−04 | −1.290311E−03 | 1.515504E−06 |
| a_62 | −1.436304E−03 | −6.367669E−04 | −2.431552E−06 |
| a_63 | 1.015061E−03 | 2.536396E−04 | −3.776921E−06 |
| a_64 | 4.757356E−04 | 9.076403E−05 | 4.727970E−06 |
| a_65 | −1.654796E−04 | −1.445267E−05 | 5.511520E−06 |
| a_66 | −4.455468E−05 | −4.082240E−06 | −4.658713E−06 |
| a_67 | −8.457584E−03 | −6.434273E−03 | 1.482573E−06 |
| a_68 | −7.058916E−04 | 2.244925E−03 | −3.619098E−07 |
| a_69 | −1.498264E−03 | −2.680812E−04 | 5.392129E−08 |
| a_70 | −8.882475E−04 | 1.765896E−04 | 1.915110E−08 |
| a_71 | 1.282231E−04 | −2.175479E−04 | 7.542467E−08 |
| a_72 | −1.714405E−04 | −1.187065E−04 | −2.186125E−07 |
| a_73 | 1.795981E−04 | 5.287425E−05 | −2.901302E−07 |
| a_74 | 1.050956E−04 | 2.170838E−05 | 4.402382E−07 |
| a_75 | −4.500295E−05 | −4.782189E−06 | 9.110043E−07 |
| a_76 | −1.559427E−05 | −1.613054E−06 | −1.024004E−06 |
| a_77 | 4.805289E−06 | −1.411176E−06 | −1.136842E−06 |
| a_78 | 1.276585E−06 | −1.592420E−07 | 8.908593E−07 |

Table 5 for FIG. 7

| Mirrors | Reflectivity |
|---|---|
| M1 | 66.4 |
| M2 | 80.3 |
| M3 | 66.2 |
| M4 | 81.7 |
| M5 | 65.3 |
| M6 | 66.9 |
| Overall | 12.6 |

In the projection optical unit 31 according to FIG. 7, the overall mirror area including a 20 mm polishing overrun is 0.56 m².

The maximum overall polarisation rotation of linearly polarised imaging light 16 in the imaging beam path of the projection optical unit 31 between the object field 5 and the image field 11 is 6.04°.

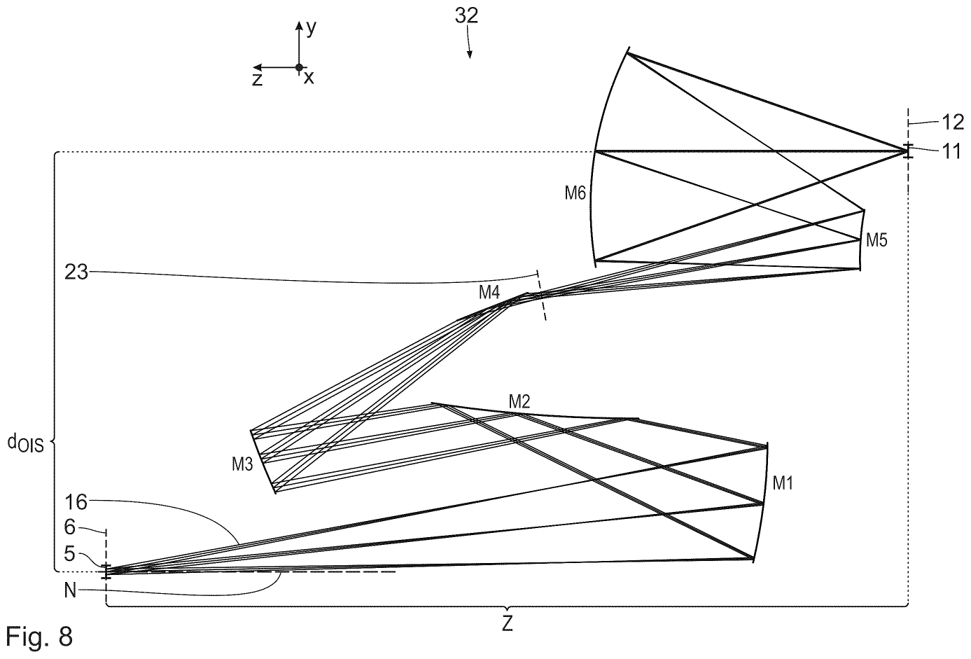

FIG. 8 shows a further embodiment of a projection optical unit or imaging optical unit 32, which can be used in the projection exposure apparatus 1 instead of the projection optical unit 10 of the embodiment according to FIG. 2. Components and functions corresponding to those which have already been explained above in conjunction with FIGS. 1 to 3, and for example in conjunction with FIGS. 2 and 3, are denoted by the same reference signs and are not discussed in detail again.

In terms of basic structure, the projection optical unit 32 according to FIG. 8 is similar to the projection optical units 28, 29 and 31 according to FIGS. 4, 5 and 7.

The following tables summarise parameters and the optical design of the projection optical unit 32. In terms of their structure, these tables correspond to those already explained above in conjunction with FIGS. 2 and 4.

Table 1 for FIG. 8

| Wavelength | 13.5 | nm |
|---|---|---|
| Image-side numerical aperture | 0.33 | |
| Image field size in the x- and y-directions | (26 × 2.5) mm | |
| βx | −4 (without | |
| | intermediate image) | |
| βy | 4 (with | |
| | intermediate image) | |
| Chief ray angle | 5.89° | |
| Étendue | 7.08 | mm² |
| Mean wavefront aberration RMS | 9.8 | mλ |
| Overall transmission | 12.5% | |
| Position of the entrance pupil (x) | −2428 | mm |
| Position of the entrance pupil (y) | 765 | mm |
| Object-image offset in the y-direction | 751 | mm |
| Distance between M7 and image plane | 78 | mm |
| Distance between the object plane and image | 1432 | mm |

| | |
|---|---|
| plane | |
| Tilt between object plane and image plane | 0° |
| Installation space cuboid | (400 × 909 × 1097) mm |

Table 2a for FIG. 8

| | M1 | M2 | M3 |
|---|---|---|---|
| Maximum angle of incidence [°] | 14.0 | 78.9 | 13.8 |
| Minimum angle of incidence [°] | 11.0 | 71.9 | 9.4 |
| Extent of the reflection surface | 350.0 | 329.4 | 275.0 |
| in the x-direction [mm] | | | |
| Extent of the reflection surface | 207.7 | 344.4 | 119.0 |
| in the y-direction [mm] | | | |
| Maximum mirror diameter [mm] | 350.0 | 379.2 | 275.4 |

Table 2b for FIG. 8

| | M4 | M5 | M6 |
|---|---|---|---|
| Maximum angle of incidence [°] | 83.5 | 24.6 | 11.9 |
| Minimum angle of incidence [°] | 73.0 | 2.8 | 7.1 |
| Extent of the reflection surface | 274.3 | 274.4 | 399.9 |
| in the x-direction [mm] | | | |
| Extent of the reflection surface | 125.0 | 103.4 | 380.2 |
| in the y-direction [mm] | | | |
| Maximum mirror diameter [mm] | 277.5 | 274.4 | 400.6 |

Table 3a for FIG. 8

| | x-distance [mm] | y-distance [mm] | z-distance [mm] |
|---|---|---|---|
| Object field | 0.00 | 750.82 | 1432.32 |
| M1 | 0.00 | 628.64 | 258.17 |
| M2 | 0.00 | 468.03 | 701.11 |
| M3 | 0.00 | 547.31 | 1156.88 |
| M4 | 0.00 | 271.46 | 726.91 |
| M5 | 0.00 | 160.80 | 84.59 |
| Stop (AS) | 0.00 | 166.44 | 149.24 |
| M6 | 0.00 | −3.68 | 558.53 |
| Image field | 0.00 | 0.00 | 0.00 |

Table 3b for FIG. 8

| | Tilt about the x- | Tilt about the y- | Tilt about the z- |
|---|---|---|---|
| | axis [degrees] | axis [degrees] | axis [degrees] |
| Object field | 0.00 | 0.00 | 0.00 |
| M1 | 6.62 | 180.00 | 0.00 |
| M2 | 109.21 | 0.00 | 0.00 |
| M3 | −22.04 | 0.00 | 180.00 |
| M4 | 40.30 | 0.00 | 0.00 |
| M5 | −5.59 | 180.00 | 0.00 |
| Stop (AS) | −8.12 | 180.00 | 0.00 |
| M6 | 11.29 | 0.00 | 0.00 |
| Image field | 0.00 | 0.00 | 0.00 |

Table 4a for FIG. 8

| | M1 | M2 | M3 |
|---|---|---|---|
| RDY | −1382.522157 | 28399.279936 | −2431.122447 |
| CCY | 0.000000 | 0.000000 | 0.000000 |
| c_1/a_p | Coefficient | Coefficient | Coefficient |
| c_1 | 0.641983 | −0.016551 | 0.053627 |
| c_2 | −0.100041799 | 0.000271015 | −0.023742494 |
| c_3 | 2.155011E−02 | −1.201745E−05 | 1.438957E−02 |
| c_4 | −3.501506E−03 | 8.097473E−07 | −5.183830E−03 |
| c_5 | 3.455993E−04 | 5.987281E−07 | 1.122135E−03 |
| c_6 | −3.033344E−05 | −9.609009E−08 | −9.472780E−05 |
| c_7 | 7.146713E−06 | 2.112782E−07 | −1.226959E−05 |
| c_8 | 2.232647E−06 | 8.661004E−08 | 2.601461E−06 |
| c_9 | −1.924683E−06 | 7.313024E−08 | −1.457485E−07 |
| c_10 | 4.857252E−07 | 4.695203E−08 | −4.203732E−08 |
| c_11 | −4.075565E−08 | 1.357606E−08 | −5.519135E−08 |
| c_12 | −5.130899E−08 | 1.910013E−09 | −2.184281E−08 |
| c_13 | 5.375916E−08 | 1.455292E−10 | −3.845144E−09 |
| c_14 | −1.430109E−08 | 4.605002E−12 | −2.550219E−10 |
| a_1 | 2.671493E−01 | −3.611614E+01 | −1.778875E+00 |
| a_2 | 7.461014E+00 | −6.619644E+00 | 5.218975E+00 |
| a_3 | −1.748203E+00 | 2.044666E−03 | 4.516487E−01 |
| a_4 | −9.330876E−01 | −1.843226E−01 | 9.662581E−02 |
| a_5 | −6.686126E−01 | 1.903549E−02 | −4.660724E−02 |
| a_6 | 2.985702E−01 | −2.045860E−04 | −3.675645E−02 |
| a_7 | −4.653591E−01 | 1.499363E−02 | −1.443334E−02 |
| a_8 | 2.911821E−01 | −3.856467E−04 | −3.286530E−02 |
| a_9 | 1.354694E−01 | −3.007410E−04 | 3.097518E−02 |
| a_10 | −6.591598E−02 | −2.245422E−05 | 2.679297E−02 |
| a_11 | 1.999945E−01 | 5.883177E−04 | −1.471700E−02 |
| a_12 | 1.405002E−01 | −3.303119E−04 | 2.607832E−02 |
| a_13 | −6.051176E−02 | −2.127414E−05 | 2.273721E−02 |
| a_14 | −2.878121E−02 | 5.549116E−06 | −1.843610E−02 |
| a_15 | 1.319454E−02 | 1.908394E−06 | −1.209191E−02 |
| a_16 | 9.966301E−02 | −3.137126E−04 | 1.003281E−02 |
| a_17 | −6.339884E−02 | −4.361154E−05 | 1.879223E−02 |
| a_18 | −2.701211E−02 | 1.818109E−05 | −1.468184E−02 |
| a_19 | 1.201511E−02 | 2.351452E−06 | −1.014565E−02 |
| a_20 | 4.686487E−03 | −1.750765E−06 | 6.713819E−03 |
| a_21 | −1.889496E−03 | 1.408704E−07 | 3.292281E−03 |
| a_22 | −4.365884E−02 | −5.989130E−05 | 7.928273E−03 |
| a_23 | −2.911728E−02 | 1.435255E−05 | −1.097661E−02 |
| a_24 | 1.115210E−02 | 3.318302E−06 | −7.712793E−03 |
| a_25 | 4.217405E−03 | −2.843102E−07 | 5.304341E−03 |
| a_26 | −1.744246E−03 | 3.944341E−07 | 2.754067E−03 |
| a_27 | −4.410751E−04 | −4.490096E−07 | −1.454740E−03 |
| a_28 | 8.823773E−05 | −4.605083E−07 | −4.487491E−04 |
| a_29 | −2.093260E−02 | 2.814901E−05 | −3.679146E−03 |
| a_30 | 1.145126E−02 | 1.013518E−05 | −5.562786E−03 |
| a_31 | 3.950734E−03 | −4.621483E−06 | 3.658132E−03 |
| a_32 | −1.580669E−03 | 1.761424E−07 | 2.062341E−03 |
| a_33 | −3.462271E−04 | −9.843985E−07 | −1.157673E−03 |
| a_34 | 1.145002E−04 | −4.600476E−07 | −3.807242E−04 |
| a_35 | 3.392570E−05 | 2.516266E−07 | 1.266423E−04 |
| a_36 | 5.548857E−05 | 1.843258E−07 | −2.295107E−06 |
| a_37 | 7.395977E−03 | 6.670230E−06 | −1.998932E−03 |
| a_38 | 4.334229E−03 | −2.800858E−06 | 2.172768E−03 |
| a_39 | −1.378848E−03 | −1.490548E−06 | 1.328668E−03 |
| a_40 | −2.720955E−04 | 4.393007E−08 | −7.983604E−04 |
| a_41 | 1.288732E−04 | −5.577376E−07 | −2.903625E−04 |
| a_42 | 1.285847E−05 | 2.286964E−07 | 1.083423E−04 |
| a_43 | 2.715174E−05 | 1.536501E−07 | 2.233723E−06 |
| a_44 | −9.725287E−06 | −1.635398E−07 | 1.428888E−05 |
| a_45 | −2.852425E−05 | −1.816779E−07 | 7.228768E−06 |
| a_46 | 3.180634E−03 | −7.529225E−06 | 4.027405E−04 |
| a_47 | −1.266350E−03 | −2.167316E−06 | 7.388724E−04 |
| a_48 | −2.493092E−04 | −6.138328E−08 | −4.362882E−04 |
| a_49 | 1.109139E−04 | −2.334292E−07 | −1.841491E−04 |
| a_50 | −5.881420E−06 | 2.234475E−07 | 8.152331E−05 |
| a_51 | 3.842775E−06 | 1.081267E−07 | 6.577969E−06 |
| a_52 | −6.841439E−06 | −1.717031E−07 | 7.992450E−06 |
| a_53 | −1.464617E−05 | −1.016739E−07 | 4.670216E−06 |
| a_54 | −1.522575E−06 | −1.064906E−08 | −2.945779E−06 |
| a_55 | 8.763747E−06 | −8.563727E−08 | −8.275088E−07 |
| a_56 | −6.518760E−04 | −3.231369E−06 | 1.868074E−04 |
| a_57 | −3.123268E−04 | 1.305541E−06 | −1.467620E−04 |
| a_58 | 7.813243E−05 | −2.869289E−07 | −8.464841E−05 |
| a_59 | −1.344027E−05 | 3.422604E−07 | 4.805972E−05 |
| a_60 | −3.116853E−06 | 1.344442E−07 | 6.485431E−06 |
| a_61 | −2.713658E−06 | −4.043214E−08 | 2.836010E−06 |
| a_62 | −3.815320E−06 | −2.994532E−08 | 1.922329E−06 |
| a_63 | 3.077901E−07 | −2.312970E−08 | −1.488414E−06 |
| a_64 | 3.856110E−06 | −4.418009E−08 | −4.868395E−07 |
| a_65 | 1.637660E−06 | 2.461811E−08 | 1.681147E−07 |
| a_66 | −1.877561E−06 | −1.733346E−09 | 4.195798E−08 |
| a_67 | −2.441170E−04 | 4.018295E−09 | 3.298295E−05 |
| a_68 | 4.520723E−05 | 1.186420E−06 | −1.981218E−05 |
| a_69 | −8.661903E−06 | −2.231582E−07 | 1.761540E−05 |
| a_70 | −2.276454E−06 | 1.158725E−07 | 2.950380E−06 |
| a_71 | −2.216141E−07 | −9.213816E−08 | 5.036504E−07 |
| a_72 | −5.845203E−07 | −2.314082E−08 | 4.023598E−07 |
| a_73 | 4.026179E−07 | −4.756893E−09 | −3.850451E−07 |
| a_74 | 5.633544E−07 | −7.034284E−09 | −1.400488E−07 |
| a_75 | 3.802754E−07 | −1.930023E−09 | 5.538308E−08 |
| a_76 | −6.110769E−07 | −7.051584E−09 | 1.481708E−08 |
| a_77 | −2.958845E−07 | 5.579796E−09 | −4.968298E−09 |
| a_78 | 1.221755E−07 | 2.162844E−09 | −1.784432E−10 |

Table 4b for FIG. 8

| | M4 | M5 | M6 |
|---|---|---|---|
| RDY | −14303.404169 | 822.487006 | −714.202599 |
| CCY | 0.000000 | 0.000000 | 0.000000 |
| c_1/a_p | Coefficient | Coefficient | Coefficient |
| c_1 | 2.601089 | −1.390703 | 0.150140 |
| c_2 | −1.413394088 | −0.077919891 | −0.00280602 |
| c_3 | 8.685634E−01 | 1.762100E−01 | 8.021431E−05 |
| c_4 | −4.291986E−01 | −1.085385E−01 | −6.229829E−06 |
| c_5 | 1.715941E−01 | 4.193591E−02 | 2.244697E−06 |
| c_6 | −5.144796E−02 | −1.034674E−02 | −8.974490E−07 |
| c_7 | 1.067534E−02 | 1.504236E−03 | −2.666365E−07 |
| c_8 | −1.275762E−03 | −9.661260E−05 | 5.990904E−07 |
| c_9 | 5.184867E−05 | 1.911109E−06 | −6.152592E−07 |
| c_10 | 3.301607E−07 | 1.129050E−06 | 4.284354E−07 |
| c_11 | −1.738810E−08 | −3.444256E−07 | −5.616966E−07 |
| c_12 | 2.053974E−07 | −5.579275E−08 | 4.719593E−07 |
| c_13 | 8.815357E−08 | 2.247387E−08 | −5.684409E−07 |
| c_14 | 1.094082E−08 | −1.675322E−08 | 1.593830E−07 |
| a_1 | 6.355805E+01 | −1.556384E+01 | −5.878749E+00 |
| a_2 | 2.231339E+00 | −1.182703E+01 | 6.110069E+00 |
| a_3 | 3.972543E+00 | −1.038260E+01 | −1.384672E−01 |
| a_4 | 2.193055E+00 | −7.004568E+00 | 9.649128E−02 |
| a_5 | −2.632784E+00 | 1.180139E+00 | −5.713852E−02 |
| a_6 | −2.965004E+00 | 5.475481E+00 | 9.454725E−04 |
| a_7 | −1.231958E+00 | 6.508338E−01 | −2.924790E−02 |
| a_8 | −2.463049E+00 | 5.901440E+00 | −1.954069E−05 |
| a_9 | 1.725273E+00 | 9.834283E−02 | 1.697798E−03 |
| a_10 | 1.898025E+00 | −2.232862E+00 | −1.407958E−05 |
| a_11 | −1.032435E+00 | 4.362887E+00 | −3.172938E−04 |
| a_12 | 1.199728E+00 | 1.028305E−01 | 9.843891E−04 |
| a_13 | 1.409102E+00 | −2.250630E+00 | −1.908705E−05 |
| a_14 | −1.021771E+00 | −2.109311E−01 | −7.351453E−05 |
| a_15 | −1.003470E+00 | 4.855703E−01 | 1.133890E−05 |
| a_16 | 3.781646E−01 | 1.911705E−01 | 2.584018E−04 |
| a_17 | 8.866327E−01 | −2.599006E+00 | −2.322792E−05 |
| a_18 | −6.190884E−01 | −1.516320E−01 | −5.402405E−05 |
| a_19 | −7.192025E−01 | 5.433553E−01 | 2.113601E−05 |
| a_20 | 5.055408E−01 | 1.291943E−01 | 1.430251E−05 |
| a_21 | 4.262689E−01 | 3.754100E−02 | −9.372194E−06 |
| a_22 | 2.496418E−01 | −1.796747E+00 | −5.793608E−06 |
| a_23 | −2.824711E−01 | −1.712233E−01 | −3.149146E−05 |
| a_24 | −3.887871E−01 | 6.358914E−01 | 1.918675E−05 |
| a_25 | 2.932186E−01 | 8.171601E−02 | 1.878643E−05 |
| a_26 | 2.972456E−01 | −1.364379E−02 | −1.592828E−05 |
| a_27 | −1.996887E−01 | −4.896084E−02 | −7.751988E−06 |
| a_28 | −1.405168E−01 | −6.138867E−02 | 6.194165E−06 |
| a_29 | −4.605647E−02 | −2.257215E−01 | −6.332592E−06 |
| a_30 | −1.643427E−01 | 7.244674E−01 | 7.853472E−06 |
| a_31 | 1.132505E−01 | 5.332064E−02 | 1.174804E−05 |
| a_32 | 1.495022E−01 | −7.550579E−02 | −1.385342E−05 |
| a_33 | −1.122621E−01 | −2.820450E−02 | −1.142703E−05 |
| a_34 | −9.503783E−02 | −3.857859E−02 | 1.009420E−05 |
| a_35 | 5.933078E−02 | 1.194275E−02 | 4.338370E−06 |
| a_36 | 3.385137E−02 | 1.802434E−02 | −3.561642E−06 |
| a_37 | −2.516568E−02 | 4.242476E−01 | −8.650681E−07 |
| a_38 | 2.388911E−02 | 7.301180E−02 | 2.788827E−06 |
| a_39 | 5.148823E−02 | −1.077359E−01 | −5.770511E−06 |
| a_40 | −4.058090E−02 | −1.208475E−02 | −7.027930E−06 |
| a_41 | −4.439535E−02 | −1.235892E−02 | 8.580785E−06 |
| a_42 | 3.208445E−02 | 6.467983E−03 | 6.488448E−06 |
| a_43 | 2.200577E−02 | 1.210790E−02 | −5.326911E−06 |
| a_44 | −1.206820E−02 | −1.702533E−03 | −1.509116E−06 |
| a_45 | −5.303986E−03 | −2.364781E−03 | 1.703267E−06 |
| a_46 | 3.447193E−05 | 9.350964E−02 | −1.605485E−06 |
| a_47 | 1.181626E−02 | −1.088640E−01 | −9.974551E−07 |
| a_48 | −7.049989E−03 | −7.072786E−03 | −1.650514E−06 |
| a_49 | −1.304192E−02 | 3.817016E−03 | 3.481179E−06 |
| a_50 | 1.076610E−02 | 2.080558E−03 | 3.947632E−06 |
| a_51 | 9.350385E−03 | 5.592794E−03 | −4.238956E−06 |
| a_52 | −6.123858E−03 | −8.793900E−04 | −2.772911E−06 |
| a_53 | −3.243249E−03 | −1.473865E−03 | 2.242256E−06 |
| a_54 | 1.393303E−03 | 1.011929E−04 | 3.967165E−07 |
| a_55 | 4.143855E−04 | 1.651288E−04 | −9.113637E−07 |
| a_56 | 4.231398E−04 | −4.345757E−02 | 5.112551E−07 |
| a_57 | 5.114067E−04 | −1.237686E−02 | 5.664976E−07 |
| a_58 | −1.999423E−03 | 7.988252E−03 | 8.407360E−07 |
| a_59 | 1.667169E−03 | 1.189403E−04 | 1.058769E−06 |
| a_60 | 2.226605E−03 | 1.587177E−03 | −1.361618E−06 |
| a_61 | −1.792046E−03 | −2.803522E−04 | −1.594208E−06 |
| a_62 | −1.184822E−03 | −5.691714E−04 | 1.629816E−06 |
| a_63 | 6.238566E−04 | 3.951435E−05 | 8.851193E−07 |
| a_64 | 2.228459E−04 | 8.742129E−05 | −8.245116E−07 |
| a_65 | −5.052006E−05 | −2.082539E−06 | 1.457585E−07 |
| a_66 | −5.951173E−06 | −3.986828E−06 | 2.790564E−07 |
| a_67 | −6.823229E−05 | −1.496142E−02 | 8.675975E−07 |
| a_68 | −1.726936E−04 | 5.768783E−03 | 7.845116E−08 |
| a_69 | −4.515723E−05 | −1.796744E−04 | 1.681307E−07 |
| a_70 | 1.761033E−04 | 1.964414E−04 | −2.085082E−07 |
| a_71 | −2.012702E−04 | −4.330816E−05 | −2.906244E−07 |
| a_72 | −1.957644E−04 | −1.076616E−04 | 3.426040E−07 |
| a_73 | 1.323620E−04 | 6.096719E−06 | 4.339931E−07 |
| a_74 | 5.554380E−05 | 2.102406E−05 | −4.551112E−07 |
| a_75 | −1.449909E−05 | −7.433114E−07 | −1.198749E−07 |
| a_76 | −1.893206E−06 | −1.471127E−06 | 1.796757E−07 |
| a_77 | −5.032400E−07 | −8.672123E−07 | 1.080489E−08 |
| a_78 | −3.699341E−07 | −2.405628E−07 | −2.287237E−07 |

Table 5 for FIG. 8

| Mirrors | Reflectivity |
|---|---|
| M1 | 66.2 |
| M2 | 78.3 |
| M3 | 66.6 |
| M4 | 83.3 |
| M5 | 65.3 |
| M6 | 66.9 |
| Overall | 12.5 |

In the projection optical unit 32 according to FIG. 8, the overall mirror area including a 20 mm polishing overrun is 0.48 m².

The maximum overall polarisation rotation of linearly polarised imaging light 16 in the imaging beam path of the projection optical unit 32 between the object field 5 and the image field 11 is 6.04°.

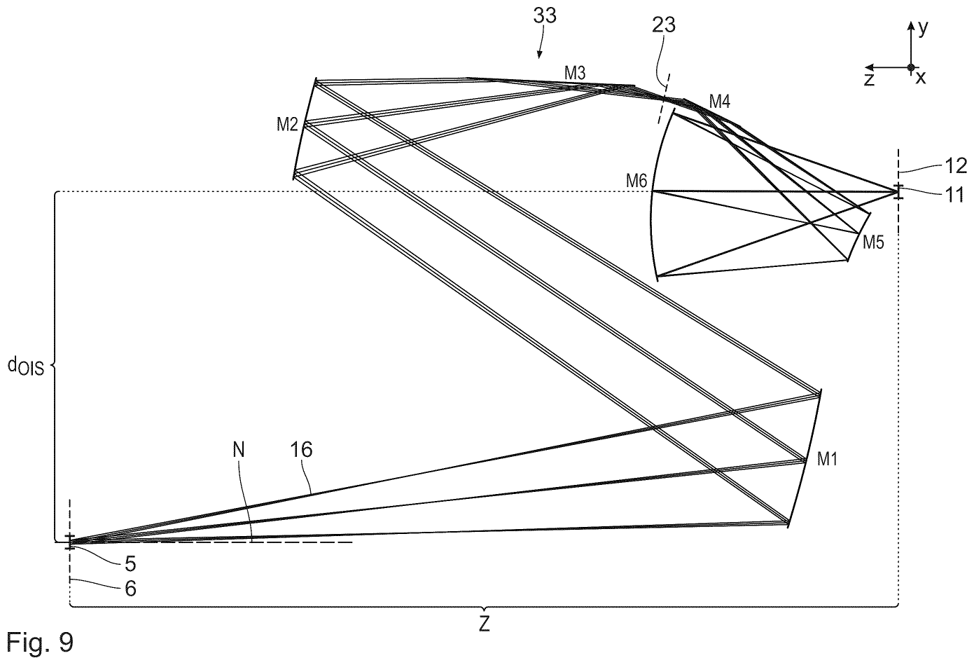

FIG. 9 shows a further embodiment of a projection optical unit or imaging optical unit 33, which can be used in the projection exposure apparatus 1 instead of the projection optical unit 10 of the embodiment according to FIG. 2. Components and functions corresponding to those which have already been explained above in conjunction with FIGS. 1 to 8, and for example in conjunction with FIGS. 2 to 8, are denoted by the same reference signs and are not discussed in detail again.

With regards to the guidance of the imaging beam path around the last mirror M6, the embodiment according to the projection optical unit 33 according to FIG. 9 is similar to that of the projection optical unit 27 according to FIG. 3.

In the projection optical unit 33, the mirrors M3 and M4 are embodied as GI mirrors. These mirrors M3 and M4 add in terms of their deflection effect for a chief ray of the central object field point.

Subsequent mirrors M5 and M6 also add in terms of their deflection effect for the chief ray of the central object field point, leading to a crossing of the component imaging beam paths between firstly the mirrors M4 and M5 and secondly the mirror M6 and the image field 11. The mirror M4 on the one hand and M5 on the other hand are on opposite sides of a last component imaging beam path between the mirror M6 and the image field 11.

The two NI mirrors M1 and M2 have a subtractive deflection effect for the chief ray of the central field point. There, this chief ray is guided zigzag.

In the projection optical unit 33, a yz-intermediate image 23 lies in the imaging beam path between the mirrors M3 and M4, near the reflection at these two GI mirrors. This leads to a small y-extent, especially for the mirror M4.

The following tables summarise parameters and the optical design of the projection optical unit 33. In terms of their structure, these tables correspond to those already explained above in conjunction with FIG. 2.

Table 1 for FIG. 9

| Wavelength | 13.5 | nm |
|---|---|---|
| Image-side numerical aperture | 0.33 | |
| Image field size in the x- and y-directions | (26 × 2.5) mm | |
| βx | −4 (without | |
| | intermediate image) | |
| βy | 4 (with | |
| | intermediate image) | |
| Chief ray angle | 6.3° | |
| Étendue | 7.08 | mm² |
| Mean wavefront aberration RMS | 8.5 | mλ |
| Overall transmission | 12.0% | |
| Position of the entrance pupil (x) | −19868 | mm |
| Position of the entrance pupil (y) | 803 | mm |
| Object-image offset in the y-direction | 900 | mm |
| Distance between M7 and image plane | 74 | mm |
| Distance between the object plane and image | 2130 | mm |

| | |
|---|---|
| plane | |
| Tilt between object plane and image plane | 0° |
| Installation space cuboid | (467 × 1149 × 1482) mm |

Table 2a for FIG. 9

| | M1 | M2 | M3 |
|---|---|---|---|
| Maximum angle of incidence [°] | 21.6 | 25.2 | 86.4 |
| Minimum angle of incidence [°] | 18.1 | 16.3 | 72.6 |
| Extent of the reflection surface in | 428.9 | 467.5 | 446.3 |
| the x-direction [mm] | | | |
| Extent of the reflection surface in | 351.7 | 257.2 | 424.8 |
| the y-direction [mm] | | | |
| Maximum mirror diameter [mm] | 430.6 | 467.7 | 513.3 |

Table 2b for FIG. 9

| | M4 | M5 | M6 |
|---|---|---|---|
| Maximum angle of incidence [°] | 83.1 | 25.3 | 12.0 |
| Minimum angle of incidence [°] | 70.6 | 2.8 | 3.9 |
| Extent of the reflection surface | 437.7 | 438.0 | 451.1 |
| in the x-direction [mm] | | | |
| Extent of the reflection surface | 151.8 | 130.6 | 428.4 |
| in the y-direction [mm] | | | |
| Maximum mirror diameter [mm] | 438.4 | 438.1 | 451.5 |

Table 3a for FIG. 9

| | x-distance [mm] | y-distance [mm] | z-distance [mm] |
|---|---|---|---|
| Object field | 0.00 | 900.00 | 2130.31 |
| M1 | 0.00 | 692.45 | 237.56 |
| M2 | 0.00 | −176.71 | 1526.57 |
| M3 | 0.00 | −277.48 | 788.13 |
| M4 | 0.00 | −211.84 | 496.38 |
| M5 | 0.00 | 111.89 | 102.68 |
| Stop (AS) | 0.00 | 111.89 | 102.68 |
| M6 | 0.00 | 0.00 | 632.88 |
| Image field | 0.00 | 0.00 | 0.00 |

Table 3b for FIG. 9

| | Tilt about the | Tilt about the | Tilt about the |
|---|---|---|---|
| | x-axis [degrees] | y-axis [degrees] | z-axis [degrees] |
| Object field | 0.00 | 0.00 | 0.00 |
| M1 | 13.87 | 180.00 | 0.00 |
| M2 | 13.11 | 0.00 | 0.00 |
| M3 | −87.55 | 180.00 | 0.00 |
| M4 | 116.06 | 0.00 | 0.00 |
| M5 | 25.67 | 180.00 | 0.00 |
| Stop (AS) | 25.67 | 180.00 | 0.00 |
| M6 | 5.96 | 0.00 | 0.00 |
| Image field | 0.00 | 0.00 | 0.00 |

Table 4a for FIG. 9

| | M1 | M2 | M3 |
|---|---|---|---|
| RDX | −29699.598255 | −4814.903615 | 773.721432 |
| RDY | −2880.803450 | 446.862705 | −2812.916884 |
| CCX | 0.000000 | 0.000000 | 0.000000 |
| CCY | 0.000000 | 0.000000 | 0.000000 |
| x**i * y**j | Coefficient | Coefficient | Coefficient |
| x**0 * y**1 | −2.766301E−04 | 8.017825E−04 | −1.121404E−03 |
| x**2 * y**0 | −7.345834E−05 | 7.315169E−05 | −6.552420E−04 |
| x**0 * y**2 | 7.826327E−06 | −1.311113E−03 | 1.995992E−04 |
| x**2 * y**1 | 1.887453E−08 | 2.967980E−09 | −4.015108E−08 |
| x**0 * y**3 | 3.984514E−08 | −4.560333E−08 | 6.536072E−08 |
| x**4 * y**0 | −2.433599E−12 | 4.712967E−12 | −1.931273E−10 |
| x**2 * y**2 | −6.871024E−12 | 1.431688E−10 | −6.809282E−11 |
| x**0 * y**4 | −2.133305E−11 | −1.287868E−09 | 2.129726E−10 |
| x**4 * y**1 | 7.472796E−16 | 2.072165E−15 | 3.648312E−14 |
| x**2 * y**3 | −7.987711E−15 | −2.057763E−14 | −3.955507E−13 |
| x**0 * y**5 | 8.444905E−14 | −6.550688E−13 | 8.118550E−13 |
| x**6 * y**0 | 4.655969E−19 | −2.432422E−18 | −1.866233E−16 |
| x**4 * y**2 | −2.577478E−18 | −5.870226E−20 | 1.457159E−16 |
| x**2 * y**4 | −1.360252E−18 | 4.996452E−16 | −1.683187E−15 |
| x**0 * y**6 | −2.107397E−16 | −4.539104E−16 | 3.414007E−15 |
| x**6 * y**1 | 2.272748E−21 | −8.602485E−22 | −1.455971E−19 |
| x**4 * y**3 | 6.487300E−20 | −3.412894E−19 | 1.000845E−18 |
| x**2 * y**5 | 2.058644E−20 | −1.928155E−18 | −7.305916E−18 |
| x**0 * y**7 | 1.585921E−18 | −1.913469E−17 | 1.480112E−17 |
| x**8 * y**0 | −4.063248E−25 | −3.994706E−23 | 1.194055E−22 |
| x**6 * y**2 | −8.570852E−23 | −1.403447E−22 | 4.851480E−21 |
| x**4 * y**4 | −1.151804E−22 | 2.553270E−21 | 8.882313E−21 |
| x**2 * y**6 | 4.187515E−23 | 1.571181E−20 | −3.183979E−20 |
| x**0 * y**8 | 2.695746E−21 | 8.851463E−20 | 7.081246E−20 |
| x**8 * y**1 | −3.214568E−25 | 1.056030E−24 | −9.736106E−25 |
| x**6 * y**3 | −4.240708E−24 | 1.720137E−23 | −2.062277E−24 |
| x**4 * y**5 | −1.074221E−23 | 7.572145E−23 | 1.382730E−23 |
| x**2 * y**7 | −4.128103E−24 | 4.346762E−23 | −1.776681E−22 |
| x**0 * y**9 | −7.948679E−23 | −3.140137E−22 | 4.057692E−22 |
| x**10 * y**0 | −4.946453E−28 | 1.544765E−27 | 7.399198E−28 |
| x**8 * y**2 | 4.412496E−27 | 9.500670E−27 | −2.290492E−25 |
| x**6 * y**4 | 1.572690E−26 | −1.174306E−25 | −2.447947E−25 |
| x**4 * y**6 | 1.095283E−26 | −7.574919E−25 | −1.221680E−26 |
| x**2 * y**8 | −7.028022E−27 | −9.184375E−25 | −1.242514E−24 |
| x**0 * y**10 | 5.720057E−28 | −1.010917E−25 | 2.366281E−24 |
| x**10 * y**1 | 1.111221E−29 | −3.985416E−29 | 1.607841E−28 |
| x**8 * y**3 | 1.329429E−28 | −4.680315E−28 | 9.650303E−29 |
| x**6 * y**5 | 4.690069E−28 | −2.497065E−27 | 1.832506E−28 |
| x**4 * y**7 | 6.929564E−28 | −5.683706E−27 | 2.045871E−27 |
| x**2 * y**9 | 1.199664E−28 | −2.601705E−27 | −7.730621E−27 |
| x**0 * y**11 | 2.587527E−27 | 5.852751E−28 | 1.106994E−26 |
| x**12 * y**0 | 1.271716E−32 | −1.987458E−32 | −2.350444E−31 |
| x**10 * y**2 | −6.919605E−32 | −2.656384E−31 | 4.985601E−30 |
| x**8 * y**4 | −5.056081E−31 | 1.821808E−30 | 7.380390E−30 |
| x**6 * y**6 | −7.123686E−31 | 2.187942E−29 | 3.303083E−30 |
| x**4 * y**8 | −3.482326E−31 | 7.717864E−29 | 1.755552E−29 |
| x**2 * y**10 | 3.839601E−31 | 6.360290E−29 | −3.490917E−29 |
| x**0 * y**12 | −1.888298E−30 | 1.552490E−28 | 3.632919E−29 |
| x**12 * y**1 | −1.724105E−34 | 6.443116E−34 | −3.576498E−33 |
| x**10 * y**3 | −1.962120E−33 | 6.723165E−33 | −7.354061E−33 |
| x**8 * y**5 | −8.885122E−33 | 3.775479E−32 | 1.725234E−33 |
| x**6 * y**7 | −1.947481E−32 | 8.012878E−32 | −2.876478E−32 |
| x**4 * y**9 | −2.009489E−32 | 2.911405E−32 | 5.728998E−32 |
| x**2 * y**11 | −9.694523E−34 | −2.302599E−31 | −1.018927E−31 |
| x**0 * y**13 | −3.628557E−32 | −2.302357E−30 | 7.690633E−32 |
| x**14 * y**0 | −9.548015E−38 | 7.885164E−38 | 2.947876E−36 |
| x**12 * y**2 | 2.712087E−37 | 2.404676E−36 | −4.053156E−35 |
| x**10 * y**4 | 5.066882E−36 | −7.698130E−36 | −8.666403E−35 |
| x**8 * y**6 | 1.026101E−35 | −1.828532E−34 | −3.017717E−35 |
| x**6 * y**8 | 1.123828E−35 | −1.159381E−33 | −1.663284E−34 |
| x**4 * y**10 | 3.903766E−36 | −2.576857E−33 | 8.386400E−35 |
| x**2 * y**12 | −6.542148E−36 | 3.597660E−34 | −1.685025E−34 |
| x**0 * y**14 | 2.648712E−35 | 1.312800E−32 | 9.384425E−35 |
| x**14 * y**1 | 1.194643E−39 | −4.177690E−39 | 2.757238E−38 |
| x**12 * y**3 | 1.025467E−38 | −4.079824E−38 | 1.203461E−37 |
| x*10 * y**5 | 6.423176E−38 | −2.445432E−37 | 2.773303E−38 |
| x**8 * y**7 | 1.608885E−37 | −1.515841E−37 | 9.732498E−38 |
| x**6 * y**9 | 2.833288E−37 | 2.736169E−36 | −2.237783E−37 |
| x**4 * y**11 | 2.181736E−37 | 7.225945E−36 | 4.549203E−38 |
| x**2 * y**13 | −1.092018E−38 | −1.045822E−36 | −1.187185E−37 |
| x**0 * y**15 | 1.268430E−37 | −2.681563E−35 | 5.007303E−38 |

Table 4b for FIG. 9

| | M4 | M5 | M6 |
|---|---|---|---|
| RDX | 659.809672 | −2569.570372 | −944.464207 |
| RDY | −2317.941864 | 390.024011 | −653.500906 |
| CCX | 0.000000 | 0.000000 | 0.000000 |
| CCY | 0.000000 | 0.000000 | 0.000000 |
| x**i * y**j | Coefficient | Coefficient | Coefficient |
| x**0 * y**1 | 1.950009E−04 | −2.264424E−03 | 7.726755E−04 |
| x**2 * y**0 | −6.928941E−04 | 1.558564E−04 | 1.506686E−04 |
| x**0 * y**2 | 1.685854E−04 | −6.299652E−04 | 5.060606E−05 |
| x**2 * y**1 | 1.486564E−08 | 1.942055E−07 | −3.212404E−08 |
| x**0 * y**3 | −1.134667E−07 | 3.939876E−07 | −8.013210E−09 |
| x**4 * y**0 | −3.350304E−10 | 8.026097E−11 | 5.214614E−11 |
| x**2 * y**2 | 1.398318E−10 | 1.212965E−09 | 1.062534E−10 |
| x**0 * y**4 | −3.889857E−10 | 2.011606E−09 | 4.034930E−11 |
| x**4 * y**1 | 7.070883E−15 | 3.430410E−13 | −3.458122E−14 |
| x**2 * y**3 | −1.025021E−13 | 2.366134E−12 | −7.215633E−14 |
| x**0 * y**5 | −1.504000E−12 | 6.651710E−12 | −5.890659E−14 |
| x**6 * y**0 | −4.167893E−16 | 9.177185E−17 | 2.792127E−17 |
| x**4 * y**2 | 4.978050E−17 | 1.625862E−15 | 9.804166E−17 |
| x**2 * y**4 | −1.307722E−15 | 6.911528E−15 | 1.377212E−16 |
| x**0 * y**6 | −3.998268E−15 | 2.338549E−14 | 7.440150E−17 |
| x**6 * y**1 | 2.017419E−19 | 3.023990E−19 | 1.085321E−21 |
| x**4 * y**3 | 1.250837E−18 | 7.838548E−19 | −7.769249E−20 |
| x**2 * y**5 | 1.453835E−17 | 5.428672E−18 | −1.779373E−19 |
| x**0 * y**7 | 2.571127E−17 | −4.486863E−16 | 1.766347E−19 |
| x**8 * y**0 | 2.451806E−23 | −4.798456E−23 | 8.642656E−23 |
| x**6 * y**2 | 1.467709E−20 | −2.069123E−21 | 3.679540E−22 |
| x**4 * y**4 | 1.481942E−19 | −3.039312E−20 | 5.170898E−22 |
| x**2 * y**6 | 5.213263E−19 | −7.954851E−19 | 5.285801E−22 |
| x**0 * y**8 | −2.121790E−19 | 8.214642E−20 | −3.985370E−22 |
| x**8 * y**1 | −1.676340E−24 | 4.688701E−24 | −1.224784E−24 |
| x**6 * y**3 | 2.079038E−23 | 2.023980E−22 | −4.812473E−24 |
| x**4 * y**5 | −1.131430E−21 | 3.011011E−21 | −6.565021E−24 |
| x**2 * y**7 | −9.933907E−21 | 1.917464E−20 | −4.248409E−24 |
| x**0 * y**9 | −1.928777E−20 | 3.348995E−19 | −1.627616E−23 |
| x**10 * y**0 | −3.778492E−26 | 6.469956E−27 | −2.598854E−27 |
| x**8 * y**2 | −5.863308E−25 | 1.892437E−25 | −1.087021E−26 |
| x**6 * y**4 | −9.215629E−24 | 2.732363E−24 | −1.742649E−26 |
| x**4 * y**6 | −7.767568E−23 | 2.929523E−23 | −1.582751E−26 |
| x**2 * y**8 | −2.382732E−22 | 4.848921E−22 | −1.409786E−26 |
| x**0 * y**10 | −3.798781E−23 | 1.258784E−21 | −9.654230E−27 |
| x**10 * y**1 | 7.787157E−30 | −3.367906E−29 | 2.322794E−29 |
| x**8 * y**3 | −3.998492E−27 | −4.996143E−27 | 1.359268E−28 |
| x**6 * y**5 | −2.192346E−26 | −1.257240E−25 | 2.746707E−28 |
| x**4 * y**7 | 2.784275E−25 | −1.083334E−24 | 2.051114E−28 |
| x**2 * y**9 | 1.609587E−24 | −4.018338E−24 | 8.674879E−29 |
| x**0 * y**11 | 4.601267E−24 | −6.295957E−23 | 2.877274E−28 |
| x**12 * y**0 | 7.583428E−31 | −9.814102E−32 | 3.952133E−32 |
| x**10 * y**2 | 1.089724E−29 | −3.124254E−30 | 1.876441E−31 |
| x**8 * y**4 | 2.281609E−28 | −5.708087E−29 | 3.876200E−31 |
| x**6 * y**6 | 2.923822E−27 | −7.264042E−28 | 4.667228E−31 |
| x**4 * y**8 | 1.965758E−26 | −6.552663E−27 | 3.718922E−31 |
| x**2 * y**10 | 4.777267E−26 | −1.070709E−25 | 3.118092E−31 |
| x**0 * y**12 | 2.999581E−26 | −2.533309E−25 | 3.611311E−31 |
| x**12 * y**1 | −1.080033E−33 | 7.509129E−36 | −2.637880E−34 |
| x**10 * y**3 | 1.168761E−31 | 6.244750E−32 | −1.956339E−33 |
| x**8 * y**5 | 2.005733E−30 | 2.131830E−30 | −5.227314E−33 |
| x**6 * y**7 | 1.074071E−29 | 3.389486E−29 | −6.524182E−33 |
| x**4 * y**9 | 2.408741E−29 | 1.871358E−28 | −3.359007E−33 |
| x**2 * y**11 | −1.304054E−29 | 5.701707E−28 | −1.408080E−33 |
| x**0 * y**13 | −4.685747E−28 | 5.459970E−27 | −2.175924E−33 |
| x**14 * y**0 | −5.895124E−36 | 5.969803E−37 | −2.285099E−37 |
| x**12 * y**2 | −7.507090E−35 | 1.985682E−35 | −1.187255E−36 |
| x**10 * y**4 | −1.975037E−33 | 4.251659E−34 | −3.026028E−36 |
| x**8 * y**6 | −3.398994E−32 | 7.491351E−33 | −4.616914E−36 |
| x**6 * y**8 | −3.566024E−31 | 7.410707E−32 | −4.646330E−36 |
| x**4 * y**10 | −1.955940E−30 | 6.334016E−31 | −3.314382E−36 |
| x**2 * y**12 | −3.966191E−30 | 9.456364E−30 | −2.627850E−36 |
| x**0 * y**14 | −6.102513E−30 | 1.658520E−29 | −3.171819E−36 |
| x**14 * y**1 | 1.584275E−38 | 1.748677E−39 | 1.276503E−39 |
| x**12 * y**3 | −1.049969E−36 | −2.990389E−37 | 1.105014E−38 |
| x**10 * y**5 | −2.643829E−35 | −1.286749E−35 | 3.602020E−38 |
| x**8 * y**7 | −3.105057E−34 | −2.879939E−34 | 6.181759E−38 |
| x**6 * y**9 | −2.298961E−33 | −3.044988E−33 | 5.119708E−38 |
| x**4 * y**11 | −1.049895E−32 | −1.221203E−32 | 2.160542E−38 |
| x**2 * y**13 | −1.761168E−32 | −3.498402E−32 | 8.539295E−39 |
| x**0 * y**15 | −1.947885E−32 | −7.495924E−32 | 4.321776E−40 |

Table 5 for FIG. 9

| Mirrors | Reflectivity |
|---|---|
| M1 | 63.3 |
| M2 | 62.7 |
| M3 | 85.2 |
| M4 | 80.9 |
| M5 | 65.3 |
| M6 | 67.2 |
| Overall | 12.0 |

In the projection optical unit 33 according to FIG. 9, the overall mirror area including a 20 mm polishing overrun is 0.77 m².

The maximum overall polarisation rotation of linearly polarised imaging light 16 in the imaging beam path of the projection optical unit 33 between the object field 5 and the image field 11 is 4.80°.

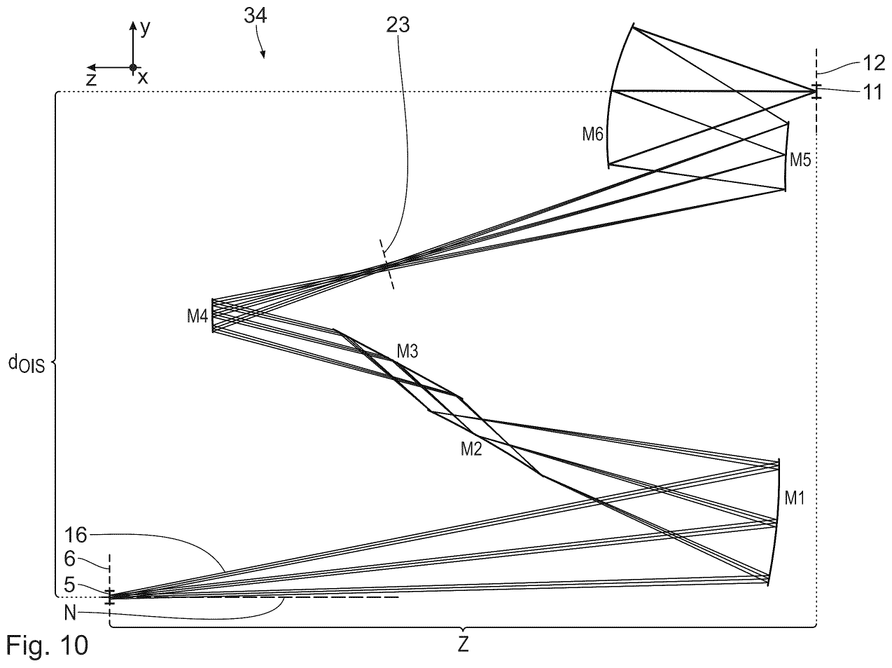

FIG. 10 shows a further embodiment of a projection optical unit or imaging optical unit 34, which can be used in the projection exposure apparatus 1 instead of the projection optical unit 10 of the embodiment according to FIG. 2. Components and functions corresponding to those which have already been explained above in conjunction with FIGS. 1 to 9, and for example in conjunction with FIGS. 2 to 9, are denoted by the same reference signs and are not discussed in detail again.

In terms of basic structure, the projection optical unit 34 according to FIG. 10 is similar to the projection optical unit 30 according to FIG. 6.

In comparison with the projection optical unit 30, the projection optical unit 34 has a greater distance Z between the object plane 6 and the image plane 12. For example, the surfaces of the mirrors M5 and M6 are significantly smaller in the case of the projection optical unit 34 than in the case of the projection optical unit 30.

The following tables summarise parameters and the optical design of the projection optical unit 34. In terms of their structure, these tables correspond to those already explained above in conjunction with FIG. 2.

In the case of the projection optical unit 34 according to FIG. 10, both entrance pupil positions, in the meridional plane and also in the sagittal plane perpendicular thereto, are located at approximately the same distance upstream of the object field in the imaging light beam path. In this case, the distance of this common entrance pupil position is approximately 2.4 m upstream of the object field 5. An accessible pupil can be created there within the illumination optical unit 4. For example, the pupil facet mirror 21 can then be arranged there. Then, there is no need to arrange any further component of the illumination optical unit guiding the illumination light 16 between the last facet mirror of the illumination optical unit 4 and the object field 5, and this avoids an attenuation of the available illumination light due to reflection losses. For example, an arrangement according to FIG. 1 is possible, where the illumination light 16, which is reflected at the pupil facets 22 of the pupil facet mirror 21, is guided directly to the object field 5.

Table 1 for FIG. 10

| Wavelength | 13.5 | nm |
|---|---|---|
| Image-side numerical aperture | 0.33 | |
| Image field size in the x- and y-directions | (26 × 2.5) mm | |
| Image field radius | 80 | mm |
| βx | −4 (without | |
| | intermediate image) | |
| βy | 4 (with | |
| | intermediate image) | |
| Chief ray angle | 6.33° | |
| Etendue | 7.08 | mm² |
| Mean wavefront aberration RMS | 10.8 | mλ |
| Overall transmission | 12.1% | |
| Position of the entrance pupil (x) | −2406 | mm |
| Position of the entrance pupil (y) | −2343 | mm |
| Object-image offset in the y-direction | 1353 | mm |
| Distance between M7 and image plane | 75 | mm |
| Distance between the object plane and image | 1893 | mm |

| | |
|---|---|
| plane | |
| Tilt between object plane and image plane | 0° |
| Installation space cuboid | (479 × 1498 × 1543) mm |

Table 2a for FIG. 10

| | M1 | M2 | M3 |
|---|---|---|---|
| Maximum angle of incidence [°] | 13.6 | 81.9 | 77.3 |
| Minimum angle of incidence [°] | 9.7 | 73.2 | 75.4 |
| Extent of the reflection surface in | 478.5 | 418.8 | 406.4 |
| the x-direction [mm] | | | |
| Extent of the reflection surface in | 333.1 | 355.7 | 395.1 |
| the y-direction [mm] | | | |
| Maximum mirror diameter [mm] | 479.9 | 426.3 | 430.3 |

Table 2b for FIG. 10

| | M4 | M5 | M6 |
|---|---|---|---|
| Maximum angle of incidence [°] | 17.7 | 25.9 | 14.1 |
| Minimum angle of incidence [°] | 12.2 | 9.2 | 6.1 |
| Extent of the reflection surface | 402.6 | 311.0 | 395.4 |
| in the x-direction [mm] | | | |
| Extent of the reflection surface | 91.7 | 176.0 | 378.4 |
| in the y-direction [mm] | | | |
| Maximum mirror diameter [mm] | 402.6 | 311.1 | 396.2 |

Table 3a for FIG. 10

| | x-distance [mm] | y-distance [mm] | z-distance [mm] |
|---|---|---|---|
| Object field | 0.00 | 1352.69 | 1892.98 |
| M1 | 0.00 | 1154.60 | 105.30 |
| M2 | 0.00 | 917.89 | 911.62 |
| M3 | 0.00 | 727.50 | 1119.71 |
| M4 | 0.00 | 599.71 | 1617.99 |
| M5 | 0.00 | 178.55 | 82.21 |
| Stop (AS) | 0.00 | 166.39 | 114.04 |
| M6 | 0.00 | 0.00 | 549.44 |
| Image field | 0.00 | 0.00 | 0.00 |

Table 3b for FIG. 10

| | Tilt about the | Tilt about the | Tilt about the |
|---|---|---|---|
| | x-axis [degrees] | y-axis [degrees] | z-axis [degrees] |
| Object field | 0.00 | 0.00 | 0.00 |
| M1 | 5.02 | 180.00 | 0.00 |
| M2 | −60.59 | 0.00 | 0.00 |
| M3 | −61.58 | 180.00 | 0.00 |
| M4 | −0.48 | 0.00 | 0.00 |
| M5 | 2.79 | 180.00 | 0.00 |
| Stop (AS) | −2.04 | 180.00 | 0.00 |
| M6 | 10.46 | 0.00 | 0.00 |
| Image field | 0.00 | 0.00 | 0.00 |

Table 4a for FIG. 10

| | M1 | M2 | M3 |
|---|---|---|---|
| RDX | −3339.074876 | 4848.199490 | 7683.186707 |
| RDY | −1398.337888 | 2084.475024 | −9872.792637 |
| CCX | 0.000000 | 0.000000 | 0.000000 |
| CCY | 0.000000 | 0.000000 | 0.000000 |
| x**i * y**j | Coefficient | Coefficient | Coefficient |
| x**0 * y**1 | 2.410029E−04 | −1.871046E−03 | 1.088964E−03 |
| x**2 * y**0 | 0.000000E+00 | 0.000000E+00 | 0.000000E+00 |
| x**0 * y**2 | 0.000000E+00 | 0.000000E+00 | 0.000000E+00 |
| x**2 * y**1 | 1.766858E−08 | 1.358721E−08 | −1.032312E−08 |
| x**0 * y**3 | −5.084148E−08 | −1.705636E−07 | 1.289262E−08 |
| x**4 * y**0 | −3.614537E−12 | −1.839818E−11 | 4.168032E−11 |
| x**2 * y**2 | −3.862826E−12 | −5.727542E−11 | 3.777632E−11 |
| x**0 * y**4 | −6.269329E−11 | 7.710720E−11 | 3.382789E−11 |
| x**4 * y**1 | 1.856900E−15 | 7.009542E−14 | −6.373203E−14 |
| x**2 * y**3 | 8.550620E−15 | −5.805360E−14 | 1.451274E−13 |
| x**0 * y**5 | −1.047568E−13 | −1.422467E−13 | 4.620871E−14 |
| x**6 * y**0 | −1.895887E−19 | −1.788364E−16 | 2.115662E−16 |
| x**4 * y**2 | −1.283070E−17 | 2.479272E−16 | 4.804544E−17 |
| x**2 * y**4 | −5.585645E−18 | 2.736717E−16 | 2.963797E−17 |
| x**0 * y**6 | −1.989144E−16 | 4.212382E−16 | −3.651524E−17 |
| x**6 * y**1 | −1.746038E−20 | −5.636770E−19 | 4.103862E−19 |
| x**4 * y**3 | −5.894109E−20 | 5.373158E−19 | −2.643343E−19 |
| x**2 * y**5 | 1.447140E−20 | −6.416300E−19 | 1.887430E−19 |
| x**0 * y**7 | −5.584909E−19 | −1.747820E−18 | −4.631439E−21 |
| x**8 * y**0 | 1.733994E−22 | −5.324966E−21 | 5.441457E−21 |
| x**6 * y**2 | 2.537915E−22 | −1.394228E−21 | 1.694309E−21 |
| x**4 * y**4 | −1.360221E−23 | 2.784942E−21 | −3.037414E−21 |
| x**2 * y**6 | 2.911594E−22 | −1.033179E−21 | −1.139589E−21 |
| x**0 * y**8 | 8.872387E−23 | 1.059371E−20 | −8.916016E−22 |
| x**8 * y**1 | 2.192530E−24 | −1.538637E−23 | −2.167821E−23 |
| x**6 * y**3 | 4.672533E−24 | −5.545122E−23 | 1.416410E−23 |
| x**4 * y**5 | −1.828461E−24 | 3.226365E−23 | −5.459073E−23 |
| x**2 * y**7 | −3.341825E−24 | 4.403141E−23 | −4.111517E−23 |
| x**0 * y**9 | 8.894526E−24 | 5.486962E−23 | −2.565961E−25 |
| x**10 * y**0 | −6.604020E−27 | 2.857951E−25 | −3.123069E−25 |
| x**8 * y**2 | −6.126134E−27 | −2.388587E−25 | 5.672944E−27 |
| x**6 * y**4 | −1.111487E−27 | −5.242938E−25 | 1.702849E−25 |
| x**4 * y**6 | −2.394676E−26 | −4.952486E−26 | 1.469301E−25 |
| x**2 * y**8 | −2.015413E−26 | 3.296615E−26 | 9.582043E−26 |
| x**0 * y**10 | −7.814019E−26 | −1.107841E−24 | 4.892240E−26 |
| x**10 * y**1 | −1.033072E−28 | 1.552968E−27 | 5.668741E−28 |
| x**8 * y**3 | −3.033018E−28 | 5.617952E−27 | −2.790156E−27 |
| x**6 * y**5 | −4.934225E−29 | 5.638402E−28 | 2.331156E−27 |
| x**4 * y**7 | 2.447902E−28 | −4.122863E−27 | 4.485123E−27 |
| x**2 * y**9 | 3.129998E−28 | −3.391215E−27 | 2.221150E−27 |
| x**0 * y**11 | −6.587071E−28 | 1.773678E−27 | −8.364095E−29 |
| x**12 * y**0 | 1.141894E−31 | −4.762404E−30 | 5.085010E−30 |
| x**10 * y**2 | 1.444916E−31 | 9.813851E−30 | 2.716377E−30 |
| x**8 * y**4 | −4.325365E−32 | 3.244764E−29 | −2.377198E−30 |
| x**6 * y**6 | 7.664639E−31 | 2.323218E−29 | −9.129008E−30 |
| x**4 * y**8 | 1.154117E−30 | 3.184161E−30 | −5.005704E−30 |
| x**2 * y**10 | 7.699832E−31 | 1.010734E−29 | −6.154398E−30 |
| x**0 * y**12 | 2.086233E−30 | 4.921153E−29 | −1.063368E−30 |
| x**12 * y**1 | 2.655727E−33 | −6.357654E−32 | 1.056435E−32 |
| x**10 * y**3 | 1.048645E−32 | −2.603120E−31 | 1.483933E−31 |
| x**8 * y**5 | 7.299385E−33 | −1.772079E−31 | −7.543280E−33 |
| x**6 * y**7 | −3.801404E−33 | 7.801171E−32 | −1.930829E−31 |
| x**4 * y**9 | −1.914227E−32 | 2.017826E−31 | −1.611860E−31 |
| x**2 * y**11 | −1.094906E−32 | 8.752300E−32 | −6.292578E−32 |
| x**0 * y**13 | 2.562439E−32 | −3.008223E−31 | 3.415568E−33 |
| x**14 * y**0 | −9.202141E−37 | 1.734020E−35 | −1.169566E−35 |
| x**12 * y**2 | −2.071968E−36 | −1.440507E−34 | −1.795724E−34 |
| x**10 * y**4 | 7.228306E−37 | −8.797272E−34 | −6.861025E−35 |
| x**8 * y**6 | −1.902432E−36 | −1.186158E−33 | 2.014130E−34 |
| x**6 * y**8 | −3.989101E−35 | −5.712368E−34 | 1.535162E−34 |
| x**4 * y**10 | −1.389805E−35 | −5.939759E−34 | 1.973142E−34 |
| x**2 * y**12 | −1.771451E−35 | −4.902178E−34 | 1.689491E−34 |
| x**0 * y**14 | −2.414265E−35 | −1.467227E−34 | 1.325749E−35 |
| x*14 * y**1 | −3.503339E−38 | 1.213271E−36 | −6.379317E−37 |
| x**12 * y**3 | −1.799780E−37 | 5.803037E−36 | −3.445995E−36 |
| x**10 * y**5 | −2.282286E−37 | 7.043866E−36 | −1.493015E−36 |
| x**8 * y**7 | 2.985262E−38 | 2.407863E−36 | 3.203587E−36 |
| x**6 * y**9 | 9.516212E−38 | −2.093767E−36 | 4.479308E−36 |
| x**4 * y**11 | 8.078302E−37 | −3.109753E−36 | 3.004995E−36 |
| x**2 * y**13 | 3.127577E−38 | −3.305710E−37 | 1.014152E−36 |
| x**0 * y**15 | −5.320924E−37 | 7.010383E−36 | −5.619244E−38 |
| x**16 * y**0 | 2.569560E−42 | 1.793379E−40 | −2.624720E−40 |
| x**14 * y**2 | 1.163653E−41 | 5.768036E−40 | 2.827215E−39 |
| x**12 * y**4 | 8.330847E−42 | 9.094774E−39 | 1.380878E−39 |
| x**10 * y**6 | −1.333934E−40 | 1.770865E−38 | −1.020540E−39 |
| x**8 * y**8 | 4.452177E−40 | 1.369639E−38 | −1.876239E−39 |
| x**6 * y**10 | 8.560376E−41 | 1.226083E−38 | −2.247810E−39 |
| x**4 * y**12 | 1.813494E−40 | 1.742617E−38 | −2.960263E−39 |
| x**2 * y**14 | 4.974222E−41 | 6.743315E−39 | −1.734739E−39 |
| x**0 * y**16 | −3.185407E−41 | −2.467043E−38 | −8.081252E−41 |

Table 4b for FIG. 10

| | M4 | M5 | M6 |
|---|---|---|---|
| RDX | −15691.467982 | 5286.649143 | −928.692011 |
| RDY | −1207.934466 | 1414.721529 | −700.360584 |
| CCX | 0.000000 | 0.000000 | 0.000000 |
| CCY | 0.000000 | 0.000000 | 0.000000 |
| x**i * y**j | Coefficient | Coefficient | Coefficient |
| x**0 * y**1 | −6.151372E−04 | 2.899848E−03 | −1.366826E−03 |
| x**2 * y**0 | 0.000000E+00 | 0.000000E+00 | 0.000000E+00 |
| x**0 * y**2 | 0.000000E+00 | 0.000000E+00 | 0.000000E+00 |
| x**2 * y**1 | −2.030925E−07 | 1.971077E−07 | 7.376075E−09 |
| x**0 * y**3 | 1.729642E−07 | 4.107325E−07 | 2.167629E−08 |
| x**4 * y**0 | −1.248818E−11 | 3.332522E−10 | −8.594273E−11 |
| x**2 * y**2 | 2.794916E−10 | 1.674108E−09 | −1.848293E−10 |
| x**0 * y**4 | 6.044883E−10 | 2.157453E−09 | −8.552635E−11 |
| x**4 * y**1 | 3.924782E−14 | 6.336130E−13 | 1.989287E−14 |
| x**2 * y**3 | −5.124191E−13 | 3.124434E−12 | 5.992750E−14 |
| x**0 * y**5 | −3.756379E−12 | 4.125283E−12 | 3.386807E−14 |
| x**6 * y**0 | −2.634845E−17 | 6.801408E−16 | −1.407716E−16 |
| x**4 * y**2 | −2.012591E−16 | 5.653170E−15 | −5.182908E−16 |
| x**2 * y**4 | −1.107283E−15 | 1.541690E−14 | −5.985352E−16 |
| x**0 * y**6 | 2.498670E−14 | 1.402669E−14 | −2.025903E−16 |
| x**6 * y**1 | −1.046210E−19 | 1.997678E−18 | 3.989749E−20 |
| x**4 * y**3 | 3.394429E−19 | 1.379220E−17 | 2.349266E−19 |
| x**2 * y**5 | −7.726927E−17 | 3.296782E−17 | 3.145005E−19 |
| x**0 * y**7 | −1.128303E−16 | −6.404556E−18 | 1.752348E−19 |
| x**8 * y**0 | −1.653708E−22 | 1.204196E−21 | −4.717190E−23 |
| x**6 * y**2 | 5.946529E−21 | 1.787800E−20 | −9.901914E−22 |
| x**4 * y**4 | 3.727630E−19 | 8.971425E−20 | −1.645112E−21 |
| x**2 * y**6 | 4.436431E−18 | −1.764688E−20 | 6.423763E−24 |
| x**0 * y**8 | 1.211903E−17 | −5.965840E−19 | 6.548957E−22 |
| x**8 * y**1 | 1.226101E−23 | 1.058926E−23 | 5.278101E−25 |
| x**6 * y**3 | −2.998326E−22 | 3.248726E−22 | −5.164103E−24 |
| x**4 * y**5 | 7.995392E−21 | 1.948252E−21 | −1.798406E−23 |
| x**2 * y**7 | 1.524261E−19 | 3.419003E−21 | −1.217442E−23 |
| x**0 * y**9 | −3.206314E−19 | 5.636214E−21 | −1.171335E−24 |
| x**10 * y**0 | 8.175747E−27 | 4.572999E−26 | −1.053323E−26 |
| x**8 * y**2 | −4.355077E−25 | 4.612404E−25 | −1.086487E−26 |
| x**6 * y**4 | −2.928633E−23 | 2.132905E−25 | 3.012882E−27 |
| x**4 * y**6 | −7.229473E−22 | 4.466206E−24 | −1.118168E−25 |
| x**2 * y**8 | −5.522486E−21 | 6.160126E−23 | −1.519190E−25 |
| x**0 * y**10 | −9.391661E−21 | 1.583267E−22 | −4.562581E−26 |
| x**10 * y**1 | −4.987834E−28 | 2.212428E−28 | −5.515682E−29 |
| x**8 * y**3 | 3.759717E−26 | −1.474312E−26 | 1.252242E−28 |
| x**6 * y**5 | −1.587510E−25 | −1.568425E−25 | 1.138336E−27 |
| x**4 * y**7 | −1.784144E−23 | −6.559587E−25 | 1.919580E−27 |
| x**2 * y**9 | −1.594830E−22 | −7.826287E−25 | 8.987497E−28 |
| x**0 * y**11 | 3.242310E−22 | 5.000237E−26 | −5.391851E−29 |
| x**12 * y**0 | 8.266776E−32 | −2.163056E−30 | 3.623760E−31 |
| x**10 * y**2 | 6.971619E−30 | −2.819840E−29 | 4.733808E−31 |
| x**8 * y**4 | 9.267438E−28 | −4.324453E−29 | −1.374363E−30 |
| x**6 * y**6 | 4.264827E−26 | 1.646311E−28 | 1.066855E−30 |
| x**4 * y**8 | 5.977559E−25 | −1.785353E−27 | 8.697604E−30 |
| x**2 * y**10 | 3.658707E−24 | −9.826570E−27 | 6.419197E−30 |
| x**0 * y**12 | 3.299566E−24 | −1.332694E−26 | 3.680200E−31 |
| x**12 * y**1 | 6.451834E−33 | −2.129304E−32 | 2.314026E−33 |
| x**10 * y**3 | −1.654419E−30 | 4.307487E−31 | 1.514563E−33 |
| x**8 * y**5 | −7.878114E−30 | 7.271015E−30 | −2.802270E−32 |
| x**6 * y**7 | 7.873026E−28 | 4.435435E−29 | −8.857888E−32 |
| x**4 * y**9 | 1.509852E−26 | 1.353231E−28 | −9.834327E−32 |
| x**2 * y**11 | 8.437998E−26 | 1.299293E−28 | −3.436048E−32 |
| x**0 * y**13 | −1.703032E−25 | −4.653887E−29 | 3.144963E−33 |
| x**14 * y**0 | −5.920456E−36 | 5.715927E−35 | −6.498589E−36 |
| x**12 * y**2 | 1.619021E−34 | 9.975365E−34 | −1.197757E−35 |
| x**10 * y**4 | −1.143895E−32 | 4.451513E−33 | 3.917020E−35 |
| x**8 * y**6 | −1.040817E−30 | −2.698690E−33 | 6.112799E−35 |
| x**6 * y**8 | −2.359977E−29 | −2.056789E−34 | −1.254024E−34 |
| x**4 * y**10 | −2.366965E−28 | 3.515621E−31 | −2.991340E−34 |
| x**2 * y**12 | −1.165059E−27 | 8.826383E−31 | −1.313298E−34 |
| x**0 * y**14 | −5.018437E−28 | 7.432061E−31 | 3.527978E−36 |
| x**14 * y**1 | 6.173113E−38 | 7.909408E−37 | −4.750446E−38 |
| x**12 * y**3 | 3.328557E−35 | −1.460997E−36 | −1.157351E−37 |
| x**10 * y**5 | 3.682651E−34 | −1.456723E−34 | 2.169195E−37 |
| x**8 * y**7 | −1.626102E−32 | −1.255047E−33 | 1.516451E−36 |
| x**6 * y**9 | −4.992043E−31 | −5.685484E−33 | 3.034106E−36 |
| x**4 * y**11 | −5.639802E−30 | −1.325070E−32 | 2.495353E−36 |
| x**2 * y**13 | −2.188750E−29 | −9.328049E−33 | 6.463229E−37 |
| x**0 * y**15 | 4.781083E−29 | 5.103706E−33 | −7.015957E−38 |
| x**16 * y**0 | 5.737204E−41 | −5.910543E−40 | 4.631215E−41 |
| x**14 * y**2 | −4.347148E−39 | −1.338157E−38 | 1.113666E−40 |
| x**12 * y**4 | 2.971593E−38 | −1.002316E−37 | −3.601607E−40 |
| x**10 * y**6 | 8.443786E−36 | −1.944633E−37 | −1.214949E−39 |
| x**8 * y**8 | 3.165282E−34 | 3.918361E−37 | −2.310387E−40 |
| x**6 * y**10 | 4.509233E−33 | −1.903289E−36 | 2.700388E−39 |
| x**4 * y**12 | 3.503933E−32 | −2.093709E−35 | 3.628916E−39 |
| x**2 * y**14 | 1.455317E−31 | −2.718901E−35 | 9.706137E−40 |
| x**0 * y**16 | 1.570190E−32 | −2.092572E−35 | −4.563192E−41 |

Table 5 for FIG. 10

| Mirrors | Reflectivity |
|---|---|
| M1 | 66.6 |
| M2 | 81.2 |
| M3 | 79.6 |
| M4 | 65.6 |
| M5 | 63.9 |
| M6 | 66.6 |
| Overall | 12.0 |

In the projection optical unit 34 according to FIG. 10, the overall mirror area including a 20 mm polishing overrun is 0.73 m².

The maximum overall polarisation rotation of linearly polarised imaging light 16 in the imaging beam path of the projection optical unit 34 between the object field 5 and the image field 11 is 5.05°.

The above-described projection optical units 10 and 27 to 34 each have an image-side numerical aperture of at least 0.3. These described projection optical units each have an image-side numerical aperture of less than 0.5 and, for example, less than 0.4.

Depending on the embodiment of the above-described projection optical units, these may also have a different number of NI mirrors and/or GI mirrors, for example precisely one GI mirrors or else precisely three GI mirrors. Fewer or more than four NI mirrors are also possible, for example two, three or five NI mirrors.

In order to produce a microstructured or nanostructured component, the projection exposure apparatus 1 is used as follows: First, the reflection mask 7 or the reticle and the substrate or the wafer 13 are provided. Subsequently, a structure on the reticle 7 is projected onto a light-sensitive layer of the wafer 13 with the aid of the projection exposure apparatus 1. Then, a microstructure or nanostructure on the wafer 13, and hence the microstructured component, is produced by developing the light-sensitive layer.

What is claimed is:

1. An imaging EUV optical unit configured to image an object field into an image field, the EUV optical unit comprising:
a plurality of mirrors configured to guide EUV imaging light along an imaging beam path from the object field towards the image field,
wherein:
the imaging EUV optical unit an image-side numerical aperture of at least 0.3;
the imaging EUV optical unit has an overall transmission of the plurality of mirrors of greater than 10%;
the imaging EUV optical unit has an overall mirror surface, which represents a sum of all used mirror surfaces of the plurality of mirrors, of less than 1.5 square meters (m²); and
the EUV imaging light has a wavelength of less than 30 nanometers (nm).

2. The imaging EUV optical unit of claim 1, wherein, for at least one mirror of the plurality of mirrors:
the mirror has a reflection surface comprising a used reflection surface and a polishing overrun edge enclosing the used reflection surface;
during use of the imaging EUV optical unit, the used reflection surface reflects the EUV imaging light, and the polishing overrun edge does not reflect the EUV imaging light; and
the polishing overrun edge projects beyond the used reflection surface by at least 10 millimeters along an entire circumference of the reflection surface.

3. The imaging EUV optical unit of claim 1, wherein, for each mirror of the plurality of mirrors:
the mirror has a reflection surface comprising a used reflection surface and a polishing overrun edge enclosing the used reflection surface;
during use of the imaging EUV optical unit, the used reflection surface reflects the EUV imaging light, and the polishing overrun edge does not reflect the EUV imaging light; and
the polishing overrun edge projects beyond the used reflection surface by at least 10 millimeters along an entire circumference of the reflection surface.

4. The imaging EUV optical unit of claim 1, wherein a maximum extent of the image field is at least 26 millimeters along a maximum field extension direction.

5. The imaging EUV optical unit of claim 1, wherein a scanning extent of the image field is at least 2 millimeters along a scanning field extension direction.

6. The imaging EUV optical unit of claim 1, wherein a wavefront aberration RMS of the imaging EUV optical unit is less than 50 mλ over the entire image field.

7. The imaging EUV optical unit of claim 1, wherein, when the EUV imaging light is polarized, an overall number of the plurality of mirrors leads to a maximum overall polarisation rotation of no more than 10° along the imaging beam path.

8. The imaging EUV optical unit of claim 1, wherein, for at least one sectional plane, the image field represents a first field region in the imaging beam path downstream of the object field.

9. The imaging EUV optical unit of claim 1, wherein the plurality of mirrors comprises at least five mirrors.

10. The imaging EUV optical unit of claim 9, wherein the plurality of mirrors comprises at least one grazing incidence mirror.

11. The imaging EUV optical unit of claim 10, wherein the plurality of mirrors comprises exactly four normal incidence mirrors.

12. The imaging EUV optical unit of claim 1, wherein the plurality of mirrors comprises at least one grazing incidence mirror.

13. The imaging EUV optical unit of claim 1, wherein the plurality of mirrors comprises exactly four normal incidence mirrors.

14. The imaging EUV optical unit of claim 1, wherein, for at least one mirror of the plurality of mirrors:
the mirror has a reflection surface comprising a used reflection surface and a polishing overrun edge enclosing the used reflection surface;
during use of the imaging EUV optical unit, the used reflection surface reflects the EUV imaging light, and the polishing overrun edge does not reflect the EUV imaging light; and
the polishing overrun edge projects beyond the used reflection surface by at least 10 millimeters along an entire circumference of the reflection surface, and
wherein a maximum extent of the image field is at least 26 millimeters along a maximum field extension direction.

15. The imaging EUV optical unit of claim 1, wherein, for at least one mirror of the plurality of mirrors:
the mirror has a reflection surface comprising a used reflection surface and a polishing overrun edge enclosing the used reflection surface;
during use of the imaging EUV optical unit, the used reflection surface reflects the EUV imaging light, and the polishing overrun edge does not reflect the EUV imaging light; and
the polishing overrun edge projects beyond the used reflection surface by at least 10 millimeters along an entire circumference of the reflection surface, and
wherein a scanning extent of the image field is at least 2 millimeters along a scanning field extension direction.

16. The imaging EUV optical unit of claim 1, wherein, for at least one mirror of the plurality of mirrors:
the mirror has a reflection surface comprising a used reflection surface and a polishing overrun edge enclosing the used reflection surface;
during use of the imaging EUV optical unit, the used reflection surface reflects the EUV imaging light, and the polishing overrun edge does not reflect the EUV imaging light; and
the polishing overrun edge projects beyond the used reflection surface by at least 10 millimeters along an entire circumference of the reflection surface, and
wherein a wavefront aberration RMS of the imaging EUV optical unit is less than 50 mλ over the entire image field.

17. The imaging EUV optical unit of claim 1, wherein a polishing overrun edge, which encloses a reflection mirror surface used for reflection, is incorporated in used mirror surfaces of the plurality of mirrors, and wherein, on an edge, projects beyond the reflection mirror surface by at least 10 millimeters along an entire circumference of the reflection surface.

18. An optical system, comprising:
an imaging optical unit according to claim 1; and
an illumination optical unit configured to illuminate the object field with the imaging light.

19. An apparatus, comprising:
an EUV light source;
an imaging optical unit according to claim 1; and
an illumination optical unit configured to illuminate the object field with the imaging light,
wherein the apparatus is a projection exposure apparatus.

20. A method of using a projection exposure apparatus comprising an illumination optical unit and an imaging optical unit, the method comprising:
using the illumination optical unit to illuminate a reticle in an object plane of the imaging optical unit; and
using the imaging optical unit to image the illuminated reticle into an image plane of the imaging optical unit,
wherein the imaging optical unit is an imaging EUV optical unit according to claim 1.
